(19) United States
(12) Patent Application Publication
(10) Pub. No.: US 2013/0101936 A1
(43) Pub. Date: Apr. 25, 2013

(54) POSITIVE RESIST COMPOSITION AND PATTERNING PROCESS

(71) Applicants: Ryosuke Taniguchi, Joetsu-shi (JP); Tomohiro Kobayashi, Joetsu-shi (JP); Jun Hatakeyama, Joetsu-shi (JP); Kenji Funatsu, Joetsu-shi (JP); Masahiro Kanayama, Joetsu-shi (JP)

(72) Inventors: Ryosuke Taniguchi, Joetsu-shi (JP); Tomohiro Kobayashi, Joetsu-shi (JP); Jun Hatakeyama, Joetsu-shi (JP); Kenji Funatsu, Joetsu-shi (JP); Masahiro Kanayama, Joetsu-shi (JP)

(73) Assignee: SHIN-ETSU CHEMICAL CO., LTD., Tokyo (JP)

(21) Appl. No.: 13/616,317

(22) Filed: Sep. 14, 2012

(30) Foreign Application Priority Data
Oct. 25, 2011 (JP) 2011-233564

(51) Int. Cl. G03F 7/004; G03F 7/20

(52) U.S. Cl. 430/280.1; 430/326

(57) ABSTRACT

A positive resist composition comprising (A) a polymer comprising recurring units containing an acid labile group, recurring units having a lactone ring, and recurring units having an oxirane ring, the polymer being adapted to increase alkaline dissolution under the action of an acid, (B) a photoacid generator, and (C) a solvent forms a fine pattern with improved LWR, improved MEF, rectangular profile, and collapse resistance.

### CROSS-REFERENCE TO RELATED APPLICATION

This non-provisional application claims priority under 35 U.S.C. §119(a) on Patent Application No. 2011-233564 filed in Japan on Oct. 25, 2011, the entire contents of which are hereby incorporated by reference.

### TECHNICAL FIELD

This invention relates to a positive resist composition and a pattern forming process using the composition. The positive resist composition lends itself to lithography using ArF excimer laser with wavelength 193 nm for micropatterning in the fabrication of semiconductor devices, especially immersion lithography where water is interposed between a projection lens and a wafer.

### BACKGROUND ART

In the recent drive for higher integration densities and operating speeds in LSI devices, the pattern rule is made drastically finer. The photolithography which is currently on widespread use in the art is approaching the essential limit of resolution determined by the wavelength of a light source.

As the light source used in the lithography for resist pattern formation, g-line (436 nm) or i-line (365 nm) from a mercury lamp was widely used in the past. Reducing the wavelength of exposure light was believed effective as the means for further reducing the feature size. For the mass production process of 64 MB dynamic random access memories (DRAM, processing feature size 0.25 μm or less) and later ones, the exposure light source of i-line (365 nm) was replaced by a KrF excimer laser having a shorter wavelength of 248 nm.

However, for the fabrication of DRAM with a degree of integration of 256 MB and 1 GB or more requiring a finer patterning technology (processing feature size 0.2 μm or less), a shorter wavelength light source was required. Photolithography using ArF excimer laser light (193 nm) has been under active investigation over the decade.

It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices.

For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the F₂ lithography was postponed and instead, the early introduction of ArF immersion lithography was advocated (see Proc. SPIE Vol. 4690 xxix).

In the ArF immersion lithography, water is held between the projection lens and the wafer. Since water has a refractive index of 1.44 at 193 nm, pattern formation is possible even using a lens with NA of 1.0 or greater. Theoretically the NA of lens can be increased to 1.35. The resolution is improved by an increment of NA. A combination of a lens having NA of at least 1.2 with strong super-resolution technology suggests a way to the 45-nm node (see Proc. SPIE Vol. 5040, p 724, 2003).

However, as the circuit line width is reduced, the influence of contrast being degraded by acid diffusion becomes more serious for the resist material. The reason is that the pattern feature size is approaching the diffusion length of acid, and this causes a lowering of mask fidelity (known as mask error factor (MEF)), a degradation of pattern rectangularity, and unevenness of fine line pattern (known as line width roughness (LWR)). Accordingly, to gain more benefits from a reduction of exposure light wavelength and an increase of lens NA, the resist material is required to increase a dissolution contrast or restrain acid diffusion, as compared with the prior art materials.

Another problem which becomes more serious as the pattern feature size is reduced is pattern collapse. The pattern is more likely to collapse, not only due to the influence of degraded contrast, but also because the critical dimension is reduced so that the area of contact with the substrate becomes narrower.

The behavior during the development step that affects pattern collapse is a swell phenomenon. This phenomenon is accounted for by a random distribution of hydrophobic and hydrophilic portions on a pattern sidewall. The developer penetrates into the hydrophilic portions, but the hydrophobic portions are not dissolved, and consequently the pattern is swollen. Because of stresses thus generated, the pattern collapses. Particularly ArF resist materials often use carboxylic acid (carboxylic acid protected with an acid labile group in the case of positive resist material) as the alkali-soluble group in the base polymer and tend to undergo a noticeable swell as compared with KrF resist materials based on weaker acidity polyhydroxystyrene (PHS).

As the means for avoiding swell, an investigation was made to introduce a phenol structure into the base polymer in the ArF resist material. It was proposed to introduce naphthol units which are relatively transparent to ArF radiation of wavelength 193 nm (see Jap. J. Appl. Phys. Vol. 33 (12B), p. 7028 (1994)). This proposal failed to provide a high transparency necessary to prevent a fine pattern from being tapered.

Also an alkali-soluble group having an acidity approximate to phenol units was proposed. Specifically, a resin possessing an alcohol having a plurality of fluorine atoms substituted at α- and α′-positions (e.g., having a partial structure: —C(CF₃)₂OH) as the alkali-soluble functional group was proposed (G. Wallraff et al., “Active Fluororesists for 157 nm Lithography,” 2nd International Symposium on 157 nm Lithography, May 14-17, 2001). This proposal is effective in solving the swell problem to some extent without detracting from transparency to ArF radiation.

When acidic units are introduced into a base polymer in a positive resist material, however, they may function to increase the alkali dissolution rate of unexposed portions and reduce the dissolution contrast, with the function depending on their content. This may invite a shortage of resolution and lead to a top-loss profile.

In many examples proposed thus far, non-acidic hydroxyl-containing units as typified by 3-hydroxy-1-adamantyl (meth)acrylate are introduced. These units are effective for improving exposure dose dependency due to their acid diffusion restraining effect and also avoid a drop of dissolution contrast unlike acidic hydroxyl groups. Due to the high hydrophilicity of hydroxyl groups, these units facilitate penetration of developer or rinse water, but not dissolution. Therefore, these units are ineffective for mitigating swell and may sometimes serve to promote swell.

### CITATION LIST

Patent Document 1: JP-A 2008-133448 (U.S. Pat. No. 7,569,326)
Patent Document 2: JP-A 2010-155824
Patent Document 3: JP 3912767
Patent Document 4: JP-A 2009-244859
Non-Patent Document 1: Proc. SPIE Vol. 4690 xxix
Non-Patent Document 2: Proc. SPIE Vol. 5040 p. 724
Non-Patent Document 3: Jap. J. Appl. Phys. Vol. 33 (12B), p. 7028 (1994)
Non-Patent Document 4: G. Wallraff et al., “Active Fluororesists for 157 nm Lithography,” 2nd International Symposium on 157 nm Lithography, May 14-17, 2001

### DISCLOSURE OF INVENTION

An object of the invention is to provide a positive resist composition comprising a polymer capable of forming a fine size pattern having rectangular profile, minimal LWR, improved MEF and collapse resistance; and a pattern forming process using the composition.

The inventors have found that a positive resist composition comprising a polymer comprising recurring units (a1) containing an acid labile group, recurring units (a2) having a cyclic hydrocarbon group containing at least one ester, ether, carbonate or sulfonate radical within the ring, and recurring units (a3) having an oxirane ring, the polymer being adapted to increase alkaline dissolution under the action of an acid, a photoacid generator, and a solvent can form a fine size pattern having a fully rectangular profile, improved MEF and collapse resistance.

It is believed that the exclusion of acidic hydroxyl groups prevents a pattern top loss, and the exclusion of non-acidic hydroxyl groups which tend to invite swell is in favor of pattern collapse resistance. However, MEF and LWR are exacerbated because more acid diffusion is allowed. Then the specific polymer is used to formulate a positive resist composition which meets both the requirements to prevent pattern collapse and to control acid diffusion. In the exposed region, the polymer is crosslinked with oxirane ring, which serves to control acid diffusion and to prevent penetration of developer or rinse liquid whereby pattern collapse due to swell is avoided.

In one aspect, the invention provides a positive resist composition comprising (A) a polymer comprising recurring units (a1) containing an acid labile group, recurring units (a2) having a cyclic hydrocarbon group containing at least one of ester, ether, carbonate, and sulfonate radicals within the ring, and recurring units (a3) having an oxirane ring, the polymer being adapted to increase alkaline dissolution under the action of an acid, (B) a photoacid generator, and (C) a solvent.

When a resist pattern is formed from the resist composition via steps of coating, exposure and development, the polymer in the exposed region is crosslinked with oxirane ring, which serves to control acid diffusion and improve resolution, and also serves to prevent penetration of developer or rinse liquid whereby pattern collapse due to swell is avoided. The inventive polymer can meet both the requirements to control acid diffusion and to prevent pattern collapse, which could never be met by the prior art polymers comprising non-acidic hydroxyl-containing units, typically 3-hydroxy-1-adamantyl (meth)acrylate, as the acid diffusion control unit.

In a preferred embodiment, the recurring unit (a1) has the general formula (1).

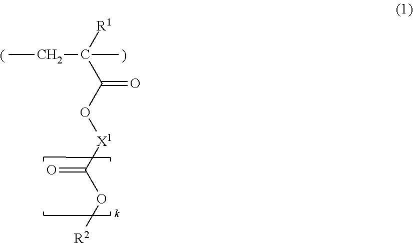

Herein R¹ is hydrogen or methyl, R² is an acid labile group, k is 0 or 1, X¹ is a single bond when k=0, and X¹ is a divalent, straight, branched or cyclic C₁-C₁₅ hydrocarbon group which may contain a heteroatom when k=1. The polymer comprising recurring units (a1) having formula (1) exhibits more alkaline dissolution under the action of an acid, leading to better pattern profile.

Preferably, the recurring unit (a2) has a lactone ring. The polymer comprising recurring units (a2) having a lactone ring affords improved adhesion between the resist film and the substrate and is effective for forming a resist pattern of better profile.

In a preferred embodiment, the recurring unit (a3) has the general formula (2) or (3).

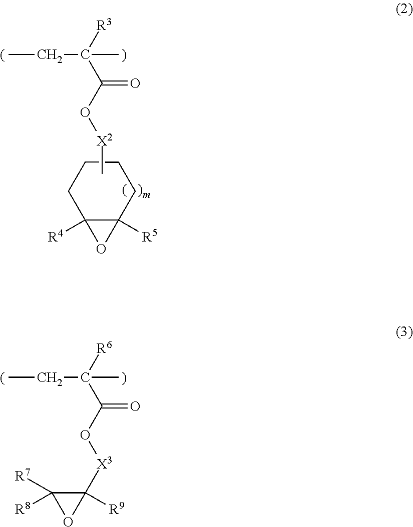

Herein R³ and R⁶ each are hydrogen or methyl, X² and X³ each are a single bond or a divalent hydrocarbon group which may contain an ester or ether bond, R⁴, R⁵, R⁷ to R⁹ each are hydrogen or a straight or branched C₁-C₅ alkyl group, and m is 0 or 1. On use of the polymer comprising recurring units (a3) having formula (2) or (3), better LWR is available.

In a further preferred embodiment, the polymer (A) may further comprise recurring units (a4) having the general formula (10).

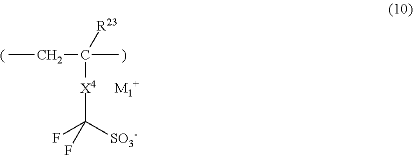

Herein R²³ is hydrogen or methyl, X⁴ is a straight or branched C₁-C₂₀ alkylene group, —O—R²⁴—, or —C(═O)—X⁵—R²⁴—, the hydrogen atom bonded to a carbon atom in the alkylene group being optionally substituted by fluorine, X⁵ is oxygen or NH, R²⁴ is a straight, branched or cyclic C₁-C₂₅ alkylene group which may contain a carbonyl, ester or ether radical and in which a carbon-bonded hydrogen atom may be substituted by fluorine, and M₁⁺ is a sulfonium or iodonium cation having a substituent group.

In a still further preferred embodiment, the polymer (A) may further comprise recurring units having a hydroxyl, carboxyl, fluoroalkyl or α-trifluoromethyl alcohol group.

In another preferred embodiment, the photoacid generator (B) is a compound capable of generating an α-position fluorinated sulfonic acid having the general formula (4) upon light exposure.

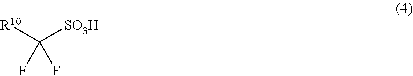

Herein R¹⁰ is a monovalent, straight, branched or cyclic C₁-C₃₅ hydrocarbon group which may contain a heteroatom and in which at least one carbon-bonded hydrogen atom may be substituted by fluorine. In the embodiment wherein the photoacid generator (B) is capable of generating an α-position fluorinated sulfonic acid having formula (4) upon light exposure, a resist pattern of better profile may be formed.

In a further preferred embodiment, the photoacid generator (B) is a sulfonium salt having the general formula (5).

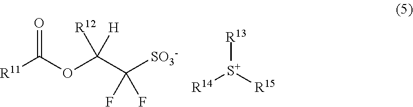

Herein R¹¹ is a substituted or unsubstituted, straight, branched or cyclic C₁-C₃₀ alkyl group which may contain a heteroatom, or a substituted or unsubstituted C₆-C₃₀ aryl group, R¹² is hydrogen or trifluoromethyl, R¹³, R¹⁴, and R¹⁵ are each independently a substituted or unsubstituted, straight or branched C₁-C₁₀ alkyl, alkenyl or oxoalkyl group, or a substituted or unsubstituted C₆-C₁₈ aryl, aralkyl or aryloxoalkyl group, or at least two of R¹³, R¹⁴, and R¹⁵ may bond together to form a ring with the sulfur atom. In the embodiment wherein component (B) is a sulfonium salt having formula (5), better MEF is available.

In a preferred embodiment, the resist composition may further comprise (D) an onium salt of sulfonic acid or carboxylic acid having the general formula (6) or (7).

R¹⁶—SO₃⁻M₂⁺ (6)

R¹⁷—COO⁻M₂⁺ (7)

Herein R¹⁶ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of sulfonic acid; R¹⁷ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of carboxylic acid; and M₂⁺ is a counter cation having a substituent group, which is a sulfonium, iodonium or ammonium cation.

When a compound of formula (6) or (7) is contained as additional component (D), more effective improvements in LWR and MEF are achievable. The following reason is presumed. The acid generated by component (B) upon light exposure undergoes salt exchange with the onium salt of α-position non-fluorinated sulfonic acid or carboxylic acid as component (D), yielding an α-position non-fluorinated sulfonic acid or carboxylic acid. The α-position non-fluorinated sulfonic acid or carboxylic acid resulting from the salt exchange has a lower acid strength and makes a less contribution to the acid-catalyzed elimination reaction of the polymer. Namely, the onium salt of α-position non-fluorinated sulfonic acid or carboxylic acid as component (D) functions as a quencher for component (B), to effectively control diffusion of the acid generated, eventually leading to improvements in LWR and MEF.

More preferably, component (D) is an onium salt having the general formula (8) or (9).

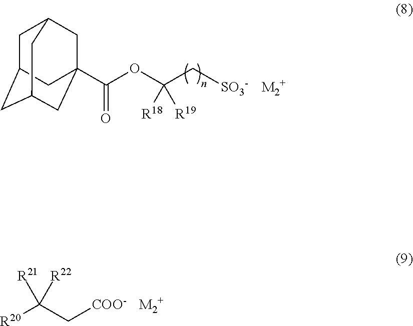

Herein R¹⁸, R¹⁹, R²¹, and R²² each are hydrogen or trifluoromethyl, R²⁰ is hydrogen, hydroxyl, a substituted or unsubstituted, straight, branched or cyclic C₁-C₂₀ alkyl group, or a substituted or unsubstituted C₆-C₃₀ aryl group, n is an integer of 1 to 3, and M₂⁺ is a counter cation having a substituent group, which is a sulfonium, iodonium or ammonium cation. Where component (D) is an onium salt having formula (8) or (9), improvements in LWR and MEF may be more effectively achievable.

In a preferred embodiment, component (D) may be present in an amount of 0.5 to 15 parts by weight per 100 parts by weight of component (A). In this range, the advantages of the invention are fully obtainable.

In a preferred embodiment, component (B) may be present in an amount of 3 to 25 parts by weight per 100 parts by weight of component (A). In this range, the advantages of the invention are fully obtainable.

The resist composition may further comprise a basic compound whereby a pattern of better profile is obtainable. In a preferred embodiment, the basic compound may be present in an amount of 0.1 to 3 parts by weight per 100 parts by weight of component (A). In this range, the advantages of the invention are fully obtainable.

In another aspect, the invention provides a pattern forming process comprising the steps of coating the positive resist composition defined above onto a substrate, baking, exposing the resulting resist film to high-energy radiation, and developing in a developer. The process ensures to form a fine resist pattern of rectangular profile having improved LWR and MEF and collapse resistance.

Preferably, the high-energy radiation has a wavelength in the range of 180 to 250 nm. Also preferably, the exposing step includes exposing the resist film to high-energy radiation while interposing water between the resist film and a projection lens according to the immersion lithography.

### ADVANTAGEOUS EFFECTS OF INVENTION

The resist composition ensures that a fine resist pattern of rectangular profile is formed. The pattern has better LWR and MEF as well as collapse resistance.

### DESCRIPTION OF PREFERRED EMBODIMENTS

As used herein, the singular forms “a,” an and the include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group.

The acronym “PAG” stands for photoacid generator, “PEB” for post-exposure bake, “LWR” for line width roughness, and “MEF” for mask error factor.

The term “high-energy radiation” is intended to encompass ultraviolet (UV) radiation, deep UV, electron beam (EB), x-ray, excimer laser, γ-ray and synchrotron radiation.

The inventors have found that a positive resist composition comprising (A) a polymer comprising recurring units (a1) containing an acid labile group, recurring units (a2) having a cyclic hydrocarbon group containing at least one of ester, ether, carbonate, and sulfonate radicals within the ring, and recurring units (a3) having an oxirane ring as a base resin, the polymer being adapted to increase alkaline dissolution under the action of an acid, (B) a photoacid generator, and (C) a solvent is effective in forming a pattern of fully rectangular profile which has improved LER and MEF and is resistant to pattern collapse.

One embodiment of the invention is a positive resist composition comprising (A) a polymer comprising recurring units (a1) containing an acid labile group, recurring units (a2) having a cyclic hydrocarbon group containing at least one of ester, ether, carbonate, and sulfonate radicals within the ring, and recurring units (a3) having an oxirane ring as a base resin, the polymer being adapted to increase alkaline dissolution under the action of an acid, (B) a photoacid generator, and (C) a solvent.

Below the positive resist composition is described in detail.

Component (A) is a polymer or resin comprising recurring units (a1) containing an acid labile group. The recurring unit (a1) containing an acid labile group is a recurring unit of the structure having an acidic group of carboxylic acid, phenol, fluoroalcohol or the like protected with an acid labile group. This unit undergoes deprotection under the action of an acid to increase its solubility in alkaline developer. Notably, the acid labile group-containing recurring units (a1) of more than one type may be contained in the polymer.

The acid labile group may be selected from a variety of such groups. Specifically, suitable acid labile groups include alkoxyalkyl groups of the general formula (L1), tertiary alkyl groups of the general formulae (L2) to (L8), and alkoxycarbonyl or alkoxycarbonylalkyl groups of the general formula (L9), shown below, but are not limited thereto.

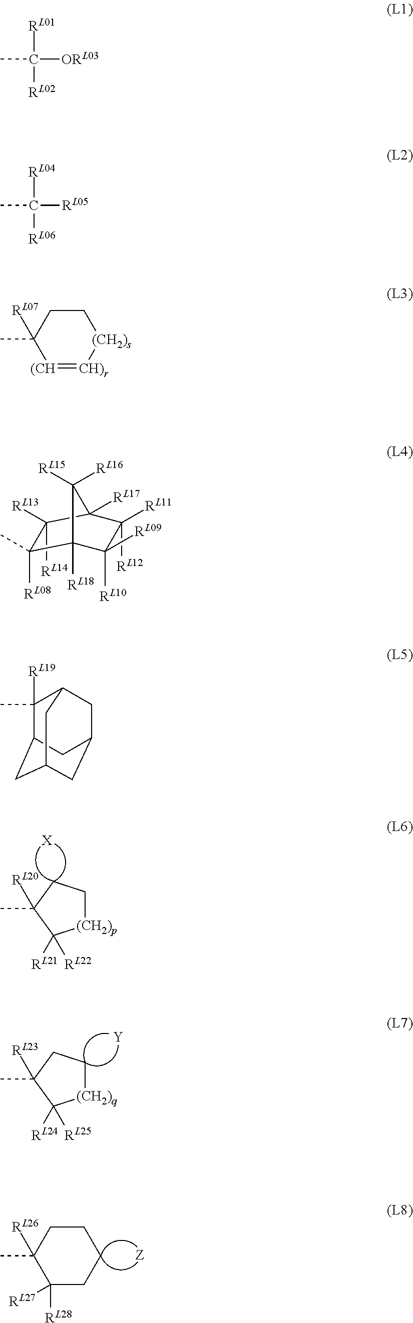

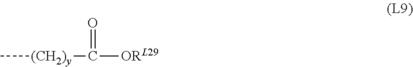

Herein and throughout the specification, the broken line denotes a valence bond.

In formula (L1), R^{L01} and R^{L02} each are hydrogen or a straight, branched or cyclic alkyl group of 1 to 18 carbon atoms, preferably 1 to 10 carbon atoms, examples of which include methyl, ethyl, propyl, isopropyl, n-butyl, sec-butyl, tert-butyl, cyclopentyl, cyclohexyl, 2-ethylhexyl, n-octyl, and adamantyl. R^{L03} is a monovalent hydrocarbon group of 1 to 18 carbon atoms, preferably 1 to 10 carbon atoms, which may contain a heteroatom such as oxygen, examples of which include straight, branched or cyclic alkyl groups and substituted forms of these groups in which some hydrogen atoms are replaced by hydroxyl, alkoxy, oxo, amino, alkylamino or the like. Suitable straight, branched or cyclic alkyl groups are as exemplified for R^{L01} and R^{L02}. Exemplary substituted alkyl groups are illustrated below.

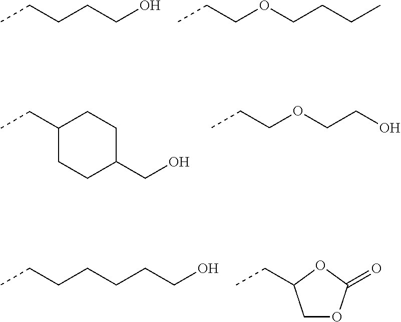

A pair of R^{L01} and R^{L02}, R^{L01} and R^{L03}, or R^{L02} and R^{L03} may bond together to form a ring with the carbon and oxygen atoms to which they are attached. Each of R^{L01}, R^{L02}, and R^{L03} represents a straight or branched alkylene group of 1 to 18 carbon atoms, preferably 1 to 10 carbon atoms when they form a ring.

In formula (L2), R^{L04}, R^{L05}, and R^{L06} are each independently a straight, branched or cyclic C₁-C₁₅ alkyl group. Suitable alkyl groups include methyl, ethyl, propyl, isopropyl, n-butyl, sec-butyl, tert-butyl, cyclopentyl, cyclohexyl, 2-ethylhexyl, n-octyl, 1-adamantyl, and 2-adamantyl.

In formula (L3), R^{L07} is an optionally substituted, straight, branched or cyclic C₁-C₁₀ alkyl group or optionally substituted C₆-C₂₀ aryl group. Examples of the optionally substituted alkyl groups include straight, branched or cyclic ones such as methyl, ethyl, propyl, isopropyl, n-butyl, sec-butyl, tert-butyl, tert-amyl, n-pentyl, n-hexyl, cyclopentyl, cyclohexyl, and bicyclo[2.2.1]heptyl; and substituted forms of the foregoing in which some hydrogen atoms are replaced by hydroxyl, alkoxy, carboxyl, alkoxycarbonyl, oxo, amino, alkylamino, cyano, mercapto, alkylthio, sulfo or other groups or in which one or more methylene moiety is replaced by an oxygen or sulfur atom. Exemplary optionally substituted aryl groups are phenyl, methylphenyl, naphthyl, anthryl, phenanthryl, and pyrenyl. In formula (L3), r is 0 or 1, s is 0, 1, 2 or 3, and 2r+s is equal to 2 or 3.

In formula (L4), R^{L08} is an optionally substituted, straight, branched or cyclic C₁-C₁₀ alkyl group or optionally substituted C₆-C₂₀ aryl group. Examples are as exemplified for R^{L07}. R^{L09} to R^{L18} each independently denote hydrogen or a monovalent C₁-C₁₅ hydrocarbon group. Exemplary hydrocarbon groups are straight, branched or cyclic alkyl groups such as methyl, ethyl, propyl, isopropyl, n-butyl, sec-butyl, tert-butyl, tert-amyl, n-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl and cyclohexylbutyl, and substituted forms of the foregoing in which some hydrogen atoms are replaced by hydroxyl, alkoxy, carboxyl, alkoxycarbonyl, oxo, amino, alkylamino, cyano, mercapto, alkylthio, sulfo or other groups. Alternatively, a pair of R^{L09} to R^{L18} (e.g., R^{L09} and R^{L10}, R^{L09} and R^{L11}, R^{L10} and R^{L12}, R^{L11} and R^{L12}, R^{L13} and R^{L14}, or R^{L15} and R^{L16}) may bond together to form a ring. Each of R^{L09} to R^{L18} represents a divalent C₁-C₁₅ hydrocarbon group when they form a ring, examples of which are those exemplified above for the monovalent hydrocarbon groups, with one hydrogen atom being eliminated. Also a pair of R^{L09} to R^{L18} (e.g., R^{L09} and R^{L11}, R^{L11}, and R^{L17}, or R^{L15} and R^{L17}) which are attached to vicinal carbon atoms may bond together directly to form a double bond.

In formula (L5), R^{L19} is an optionally substituted, straight, branched or cyclic C₁-C₁₀ alkyl group or optionally substituted C₆-C₂₀ aryl group. Examples are as exemplified for R^{L07}.

In formula (L6), R^{L20} is an optionally substituted, straight, branched or cyclic C₁-C₁₀ alkyl group or optionally substituted C₆-C₂₀ aryl group. Examples are as exemplified for R^{L07}. X is a divalent group that forms an optionally substituted cyclopentane, cyclohexane or norbornane ring with the carbon atom to which it is attached. R^{L21} and R^{L22} are each independently hydrogen or a straight, branched or cyclic, monovalent hydrocarbon group of 1 to 10 carbon atoms. R^{L21} and R^{L22} may bond together to form a ring with the carbon atom to which they are attached, and in this case, R^{L21} and R^{L22} taken together represent a divalent group that forms an optionally substituted cyclopentane or cyclohexane ring. The subscript p is 1 or 2.

In formula (L7), R^{L23} is an optionally substituted, straight, branched or cyclic C₁-C₁₀ alkyl group or optionally substituted C₆-C₂₀ aryl group. Examples are as exemplified for R^{L07}. Y is a divalent group that forms an optionally substituted cyclopentane, cyclohexane or norbornane ring with the carbon atom to which it is attached. R^{L24} and R^{L25} are each independently hydrogen or a straight, branched or cyclic, monovalent hydrocarbon group of 1 to 10 carbon atoms. R^{L24} and R^{L25} may bond together to form a ring with the carbon atom to which they are attached, and in this case, R^{L24} and R^{L25} taken together represent a divalent group that forms an optionally substituted cyclopentane or cyclohexane ring. The subscript q is 1 or 2.

In formula (L8), R^{L26} is an optionally substituted, straight, branched or cyclic C₁-C₁₀ alkyl group or optionally substituted C₆-C₂₀ aryl group. Examples are as exemplified for R^{L07}. Z is a divalent group that forms an optionally substituted cyclopentane, cyclohexane or norbornane ring with the carbon atom to which it is attached. R^{L27} and R^{L28} are each independently hydrogen or a straight, branched or cyclic, monovalent hydrocarbon group of 1 to 10 carbon atoms. R^{L27} and R^{L28} may bond together to form a ring with the carbon atom to which they are attached, and in this case, R^{L27} and R^{L28} taken together represent a divalent group that forms an optionally substituted cyclopentane or cyclohexane ring.

In formula (L9), R^{L29} is a tertiary alkyl group of 4 to 20 carbon atoms, preferably 4 to 15 carbon atoms, a trialkylsilyl group in which each alkyl moiety has 1 to 6 carbon atoms, a C₄-C₂₀ oxoalkyl group or a group of above formula (L1). Suitable tertiary alkyl groups include tert-butyl, tert-amyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Suitable trialkylsilyl groups include trimethylsilyl, triethylsilyl, and dimethyl-tert-butylsilyl. Suitable oxoalkyl groups include 3-oxocyclohexyl, 4-methyl-2-oxooxan-4-yl, and 5-methyl-2-oxooxolan-5-yl. The subscript y is an integer of 0 to 3.

Examples of the acid labile group of formula (L1) are shown below.

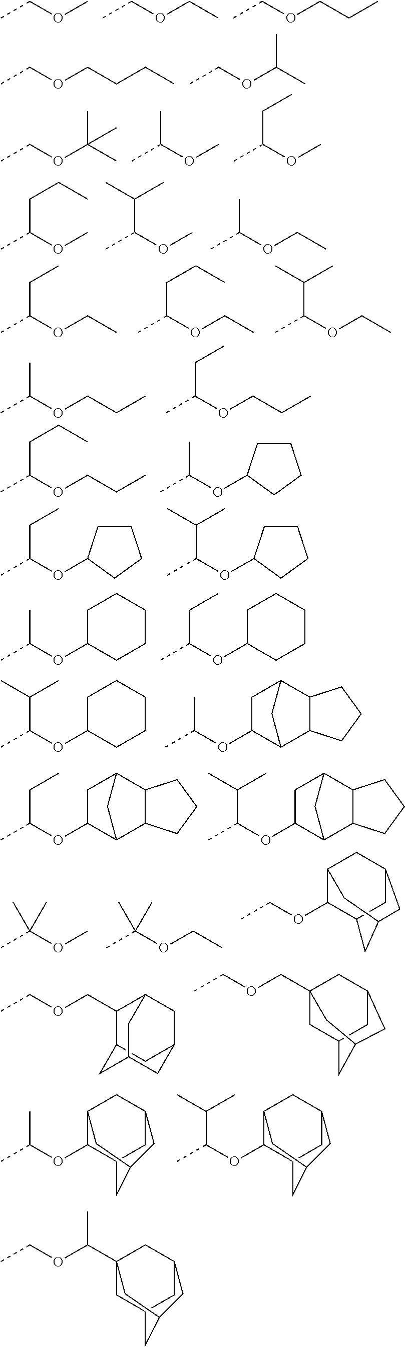

Of the acid labile groups of formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile group of formula (L2) include tert-butyl, tert-amyl, and the groups shown below.

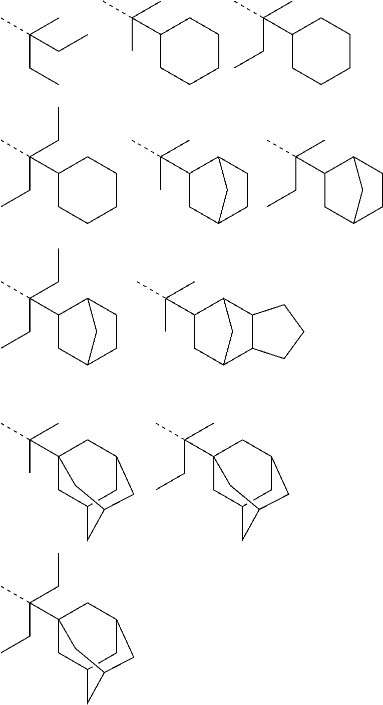

Examples of the acid labile group of formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxy-n-butyl)cyclopentyl, 1-(bicyclo[2.2.1]heptan-2-yl)cyclopentyl, 1-(7-oxabicyclo[2.2.1]heptan-2-yl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl.

Of the acid labile groups of formula (L4), those groups of the following formulae (L4-1) to (L4-4) are more preferred.

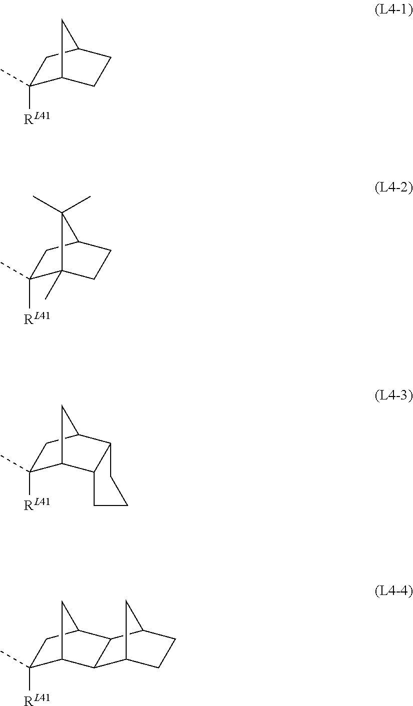

In formulae (L4-1) to (L4-4), the broken line denotes a bonding site and direction. R^{L41} is each independently selected from monovalent hydrocarbon groups, typically straight, branched or cyclic C₁-C₁₀ alkyl groups, for example, methyl, ethyl, propyl, isopropyl, n-butyl, sec-butyl, tert-butyl, tert-amyl, n-pentyl, n-hexyl, cyclopentyl, and cyclohexyl.

For formulas (L4-1) to (L4-4), there can exist enantiomers and diastereomers. Each of formulae (L4-1) to (L4-4) collectively represents all such stereoisomers. Such stereoisomers may be used alone or in admixture.

For example, the general formula (L4-3) represents one or a mixture of two selected from groups having the following general formulas (L4-3-1) and (L4-3-2).

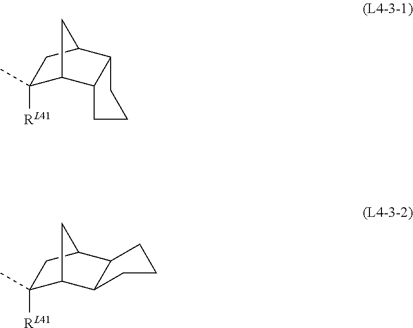

Herein R^{L41} is as defined above.

Similarly, the general formula (L4-4) represents one or a mixture of two or more selected from groups having the following general formulas (L4-4-1) to (L4-4-4).

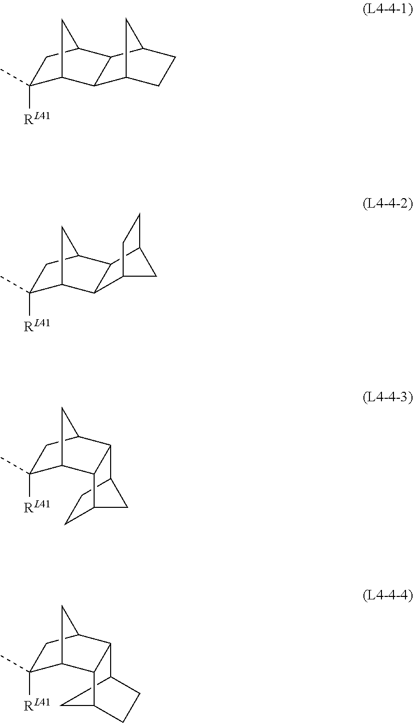

Herein R^{L41} is as defined above.

Each of formulas (L4-1) to (L4-4), (L4-3-1) and (L4-3-2), and (L4-4-1) to (L4-4-4) collectively represents an enantiomer thereof and a mixture of enantiomers.

It is noted that in the above formulas (L4-1) to (L4-4), (L4-3-1) and (L4-3-2), and (L4-4-1) to (L4-4-4), the bond direction is on the exo side relative to the bicyclo[2.2.1]heptane ring, which ensures high reactivity for acid-catalyzed elimination reaction (see JP-A 2000-336121).

In preparing these monomers having a tertiary exo-alkyl group of bicyclo[2.2.1]heptane skeleton as a substituent group, there may be contained monomers substituted with an endo-alkyl group as represented by the following formulas (L4-1-endo) to (L4-4-endo). For good reactivity, an exo proportion of at least 50 mol % is preferred, with an exo proportion of at least 80 mol % being more preferred.

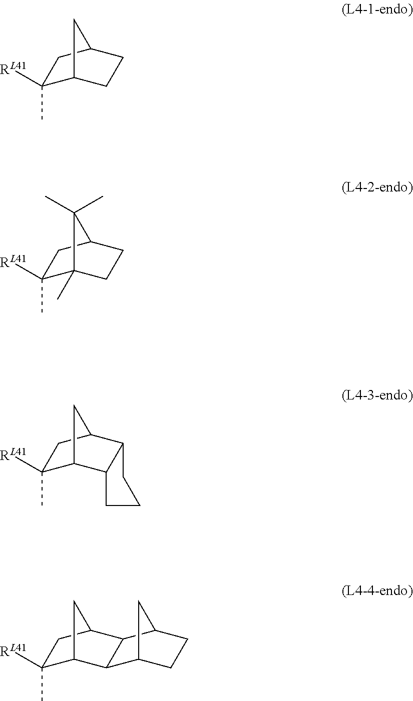

Herein R^{L41} is as defined above.

Illustrative examples of the acid labile group of formula (L4) are given below, but not limited thereto.

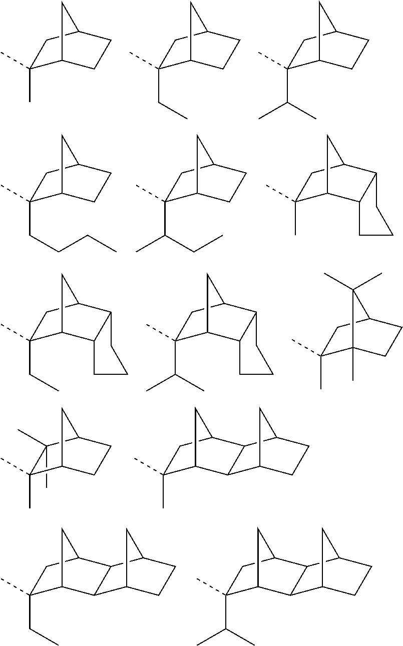

Examples of the acid labile group of formula (L5) are shown below.

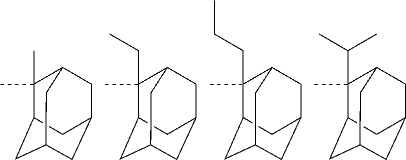

Examples of the acid labile group of formula (L6) are shown below.

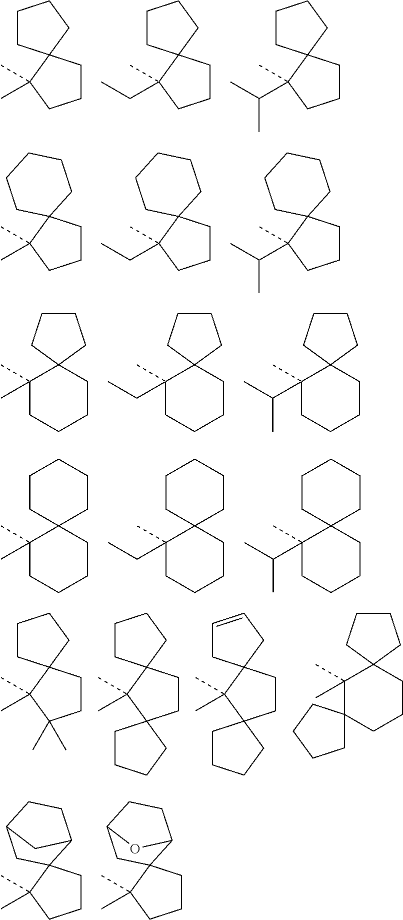

Examples of the acid labile group of formula (L7) are shown below.

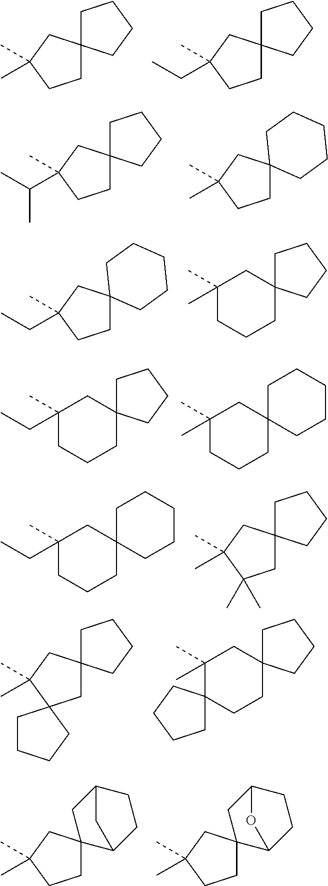

Examples of the acid labile group of formula (L8) are shown below.

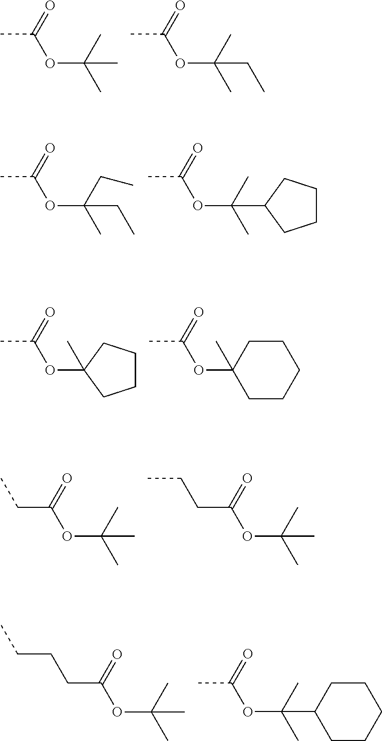

Examples of the acid labile group of formula (L9) are shown below.

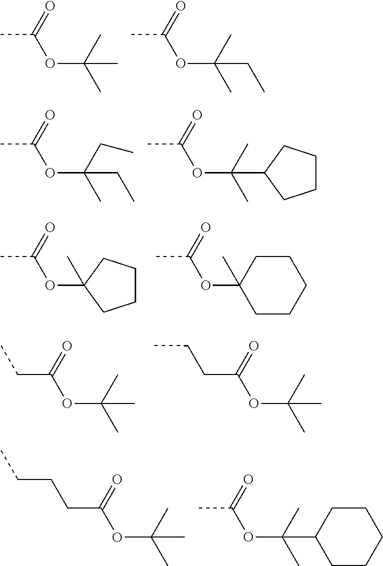

Illustrative, non-limiting examples of the recurring unit having an acid labile group are shown below.

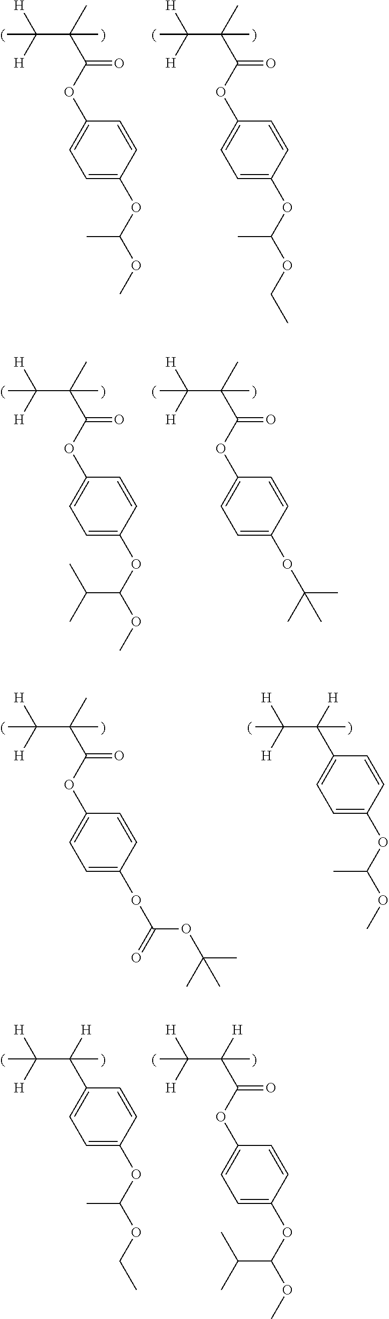

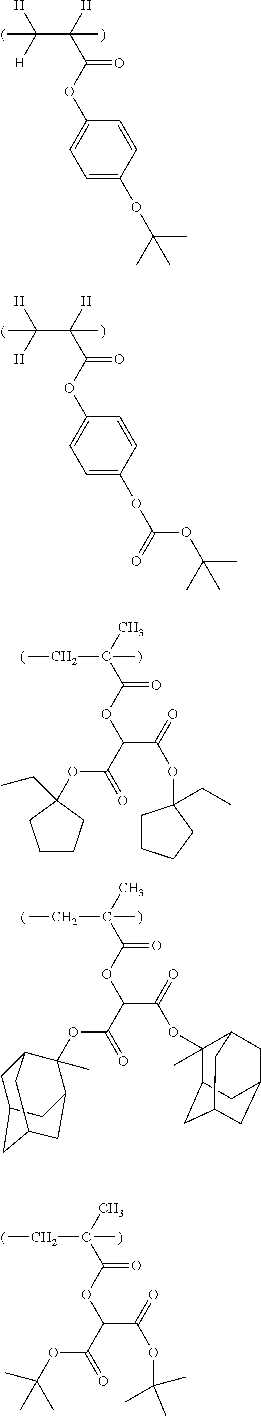

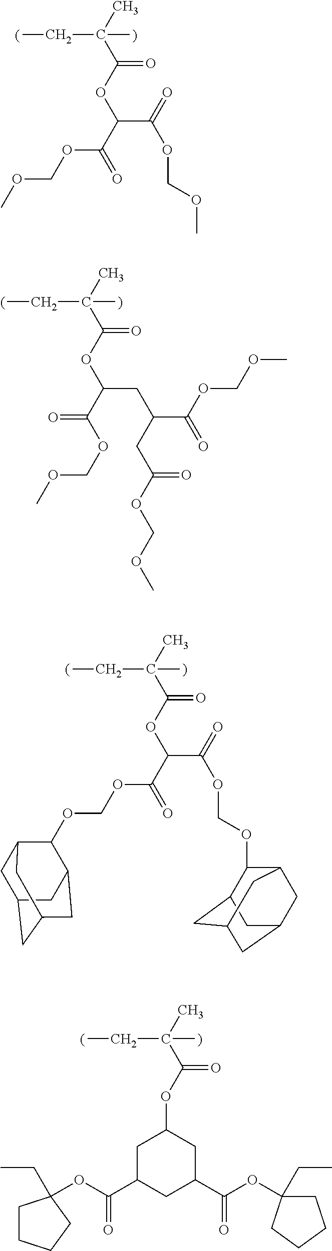

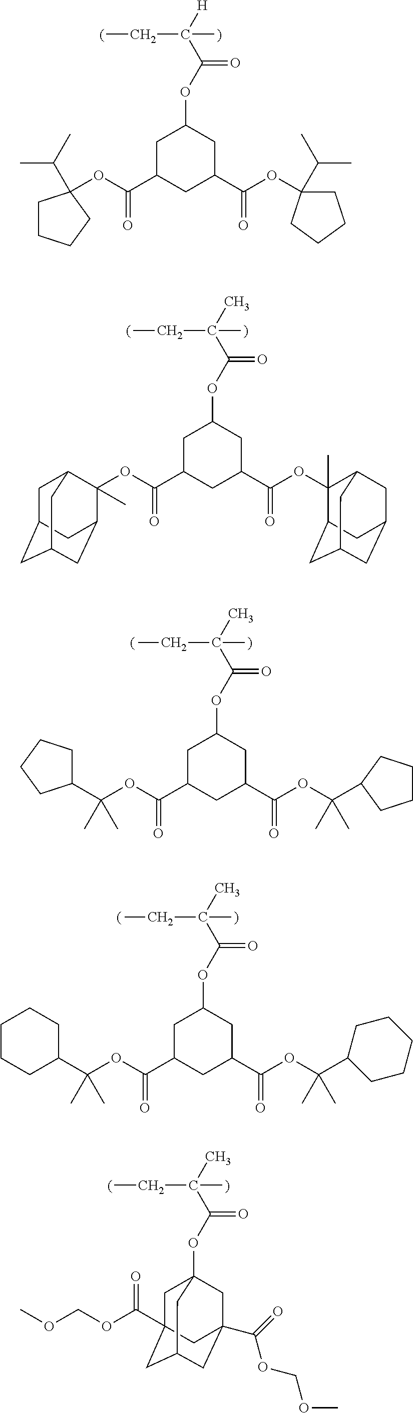

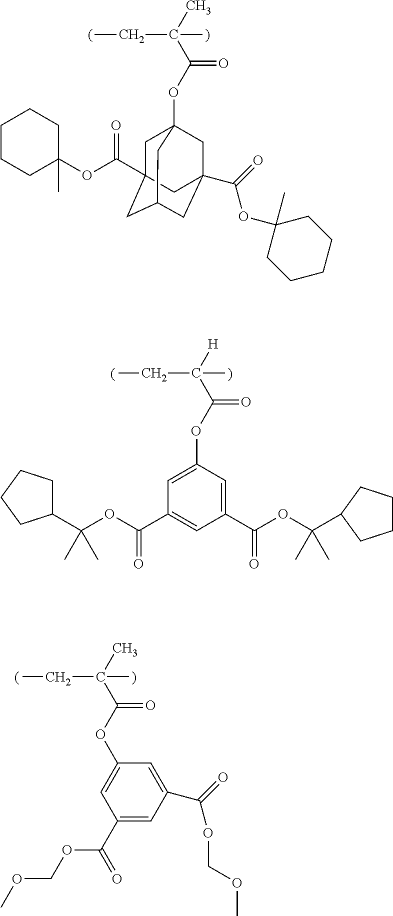

More preferably, the recurring unit (a1) having an acid labile group in polymer (A) is a recurring unit of the structure having the general formula (1).

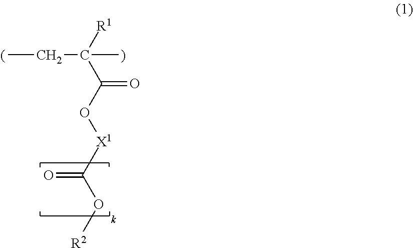

Herein R¹ is hydrogen or methyl, R² is an acid labile group, k is 0 or 1, X¹ is a single bond when k=0, and X¹ is a divalent, straight, branched or cyclic C₁-C₁₅ hydrocarbon group which may contain a heteroatom when k=1.

Illustrative, non-limiting examples of the recurring unit (a1) having an acid labile group of formula (1) are shown below.

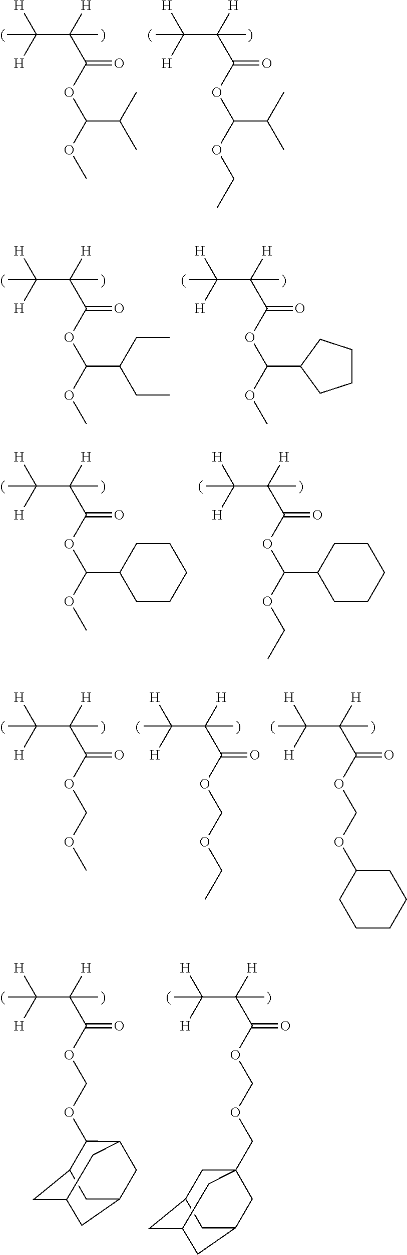

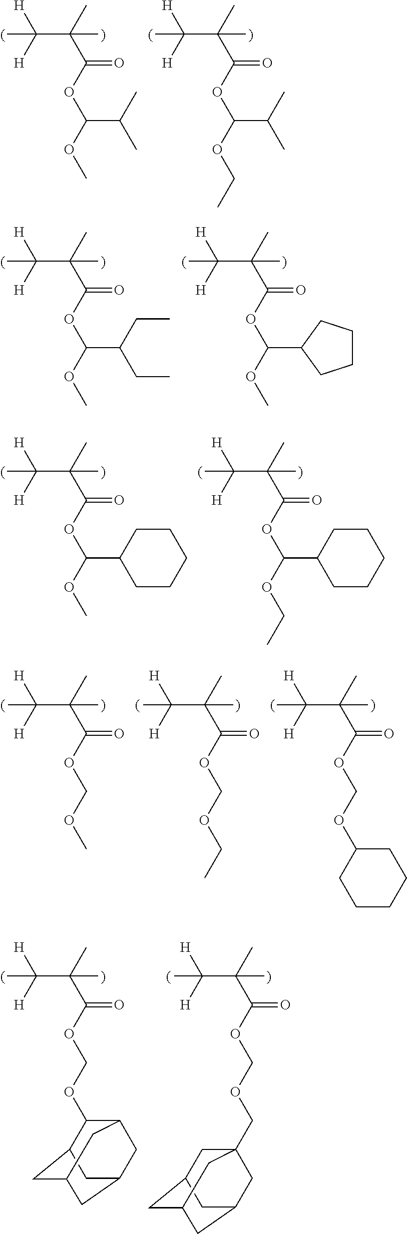

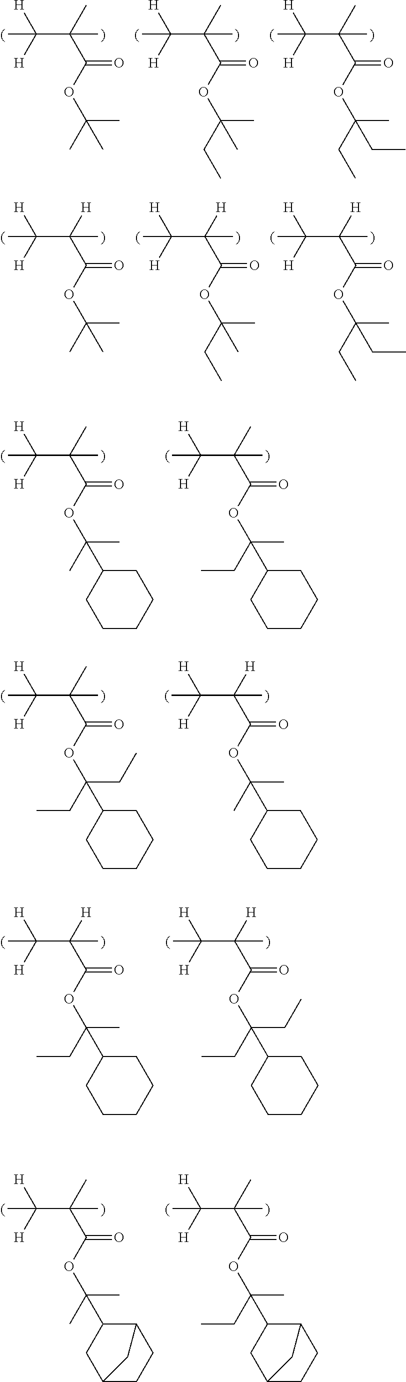

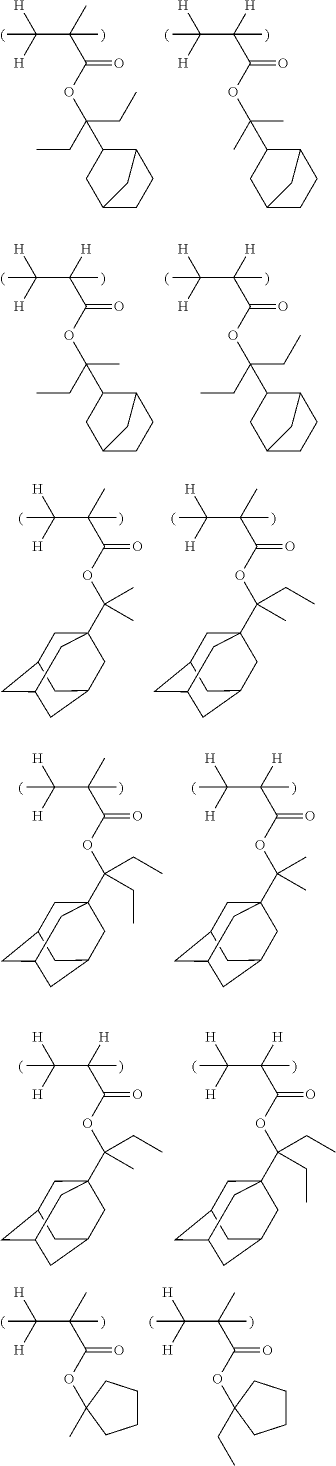

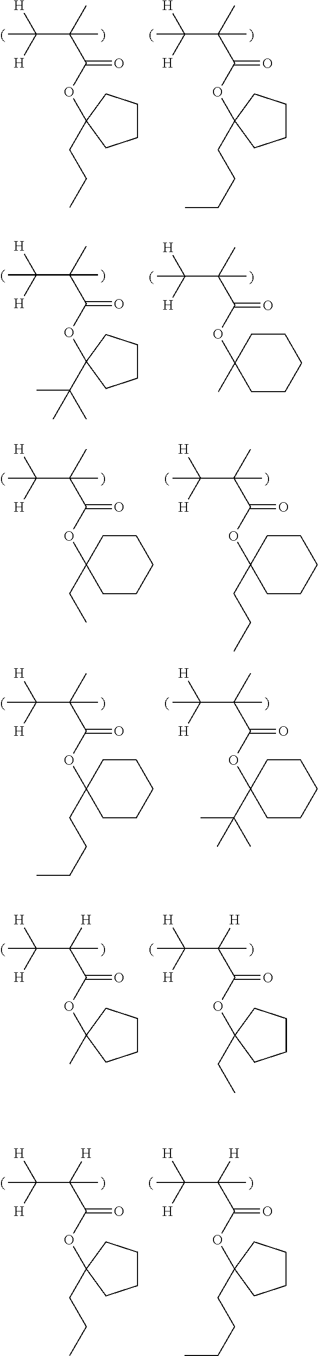

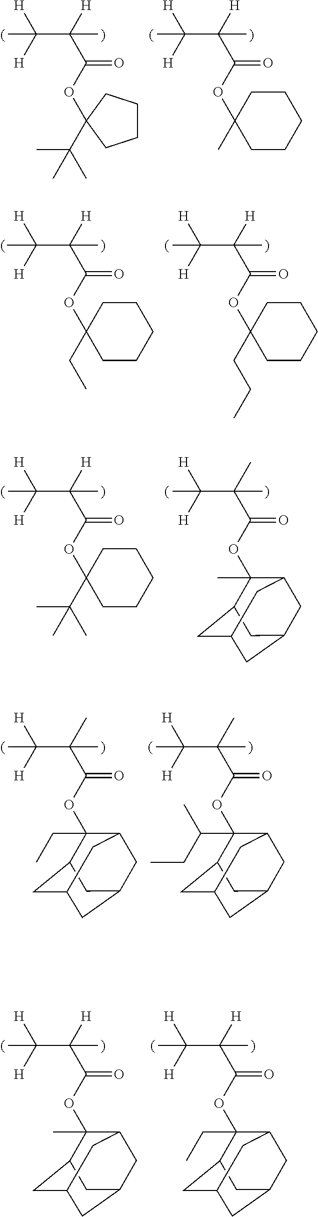

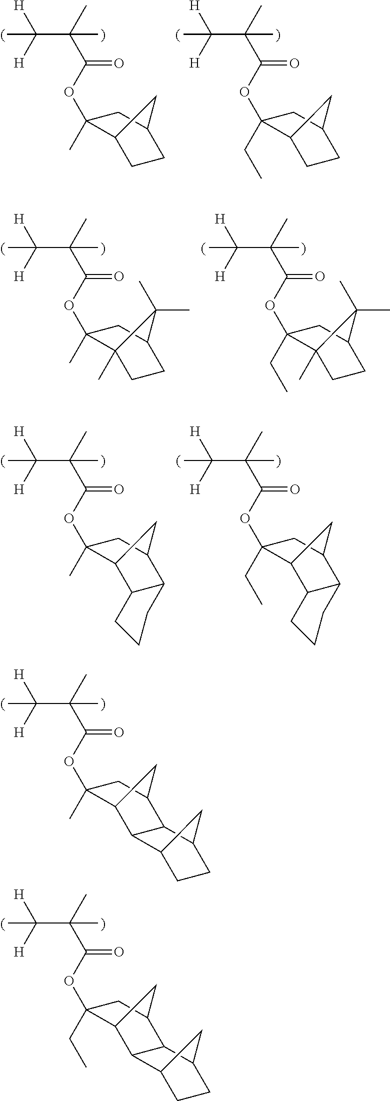

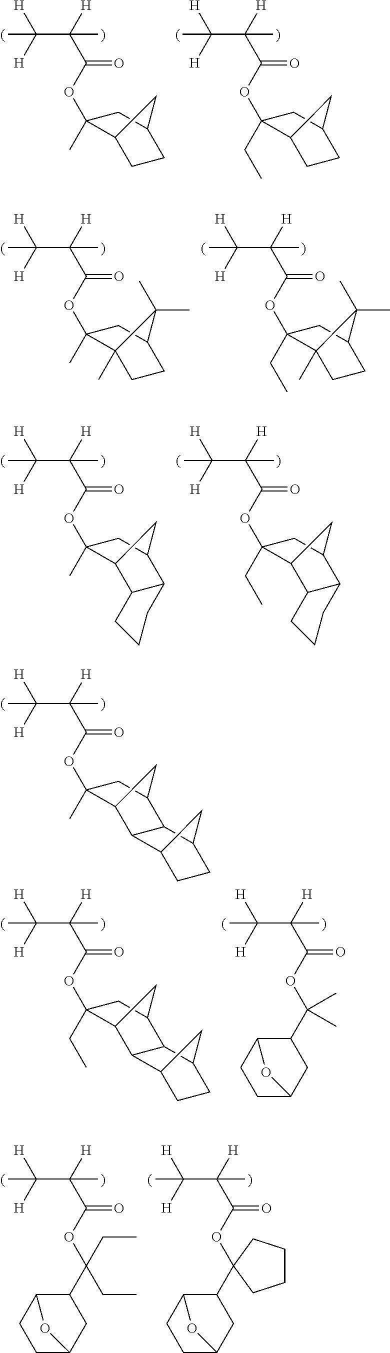

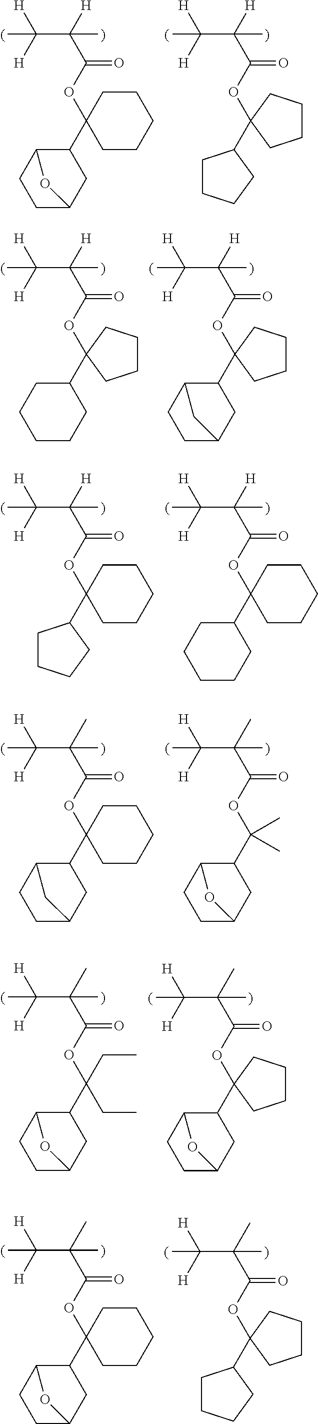

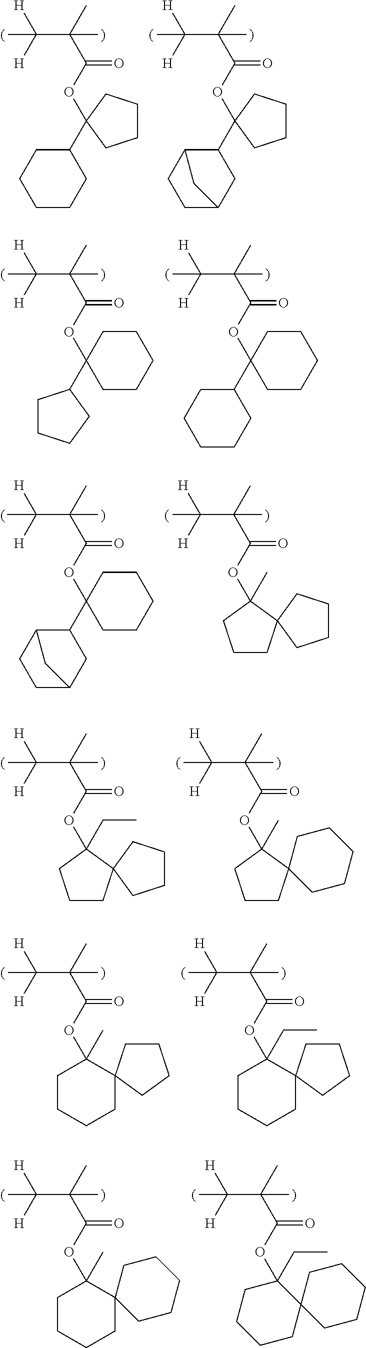

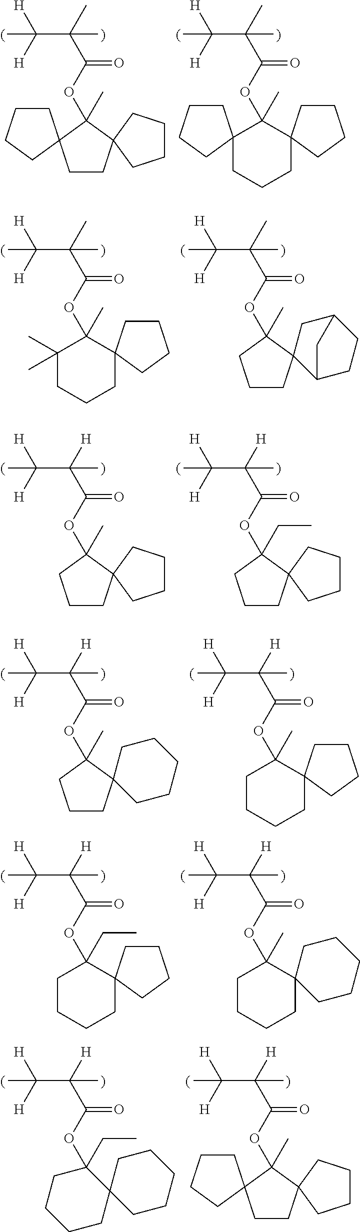

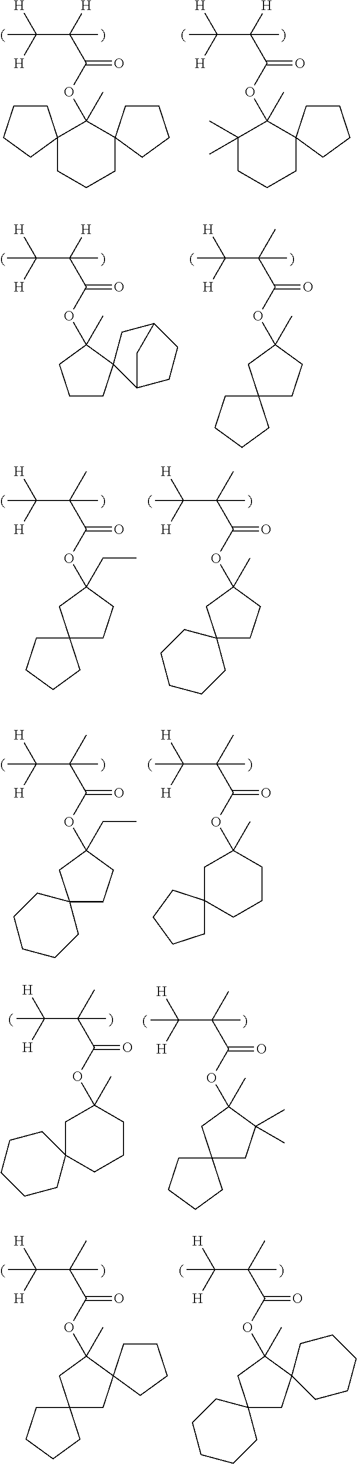

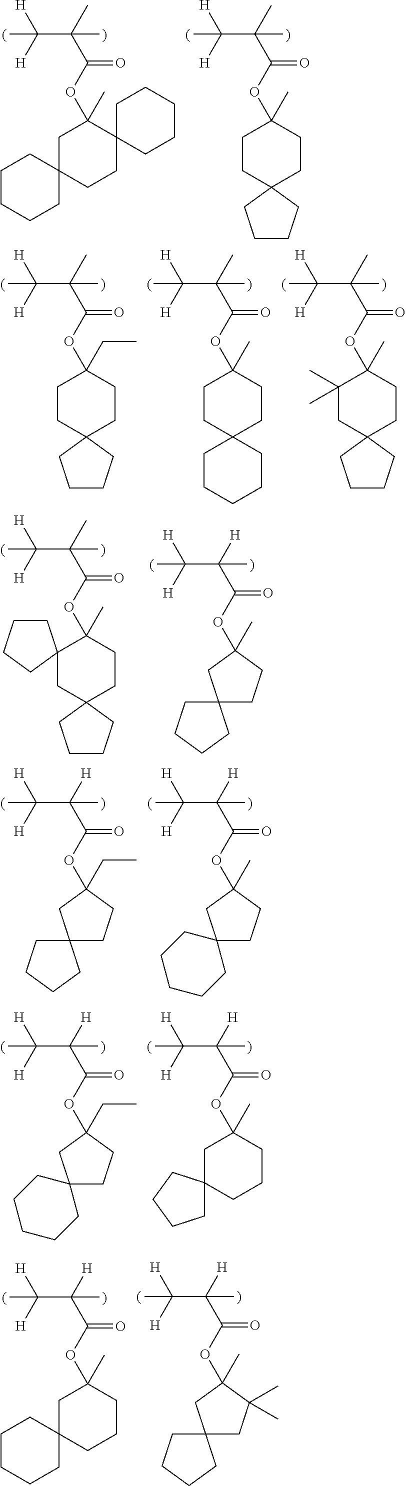

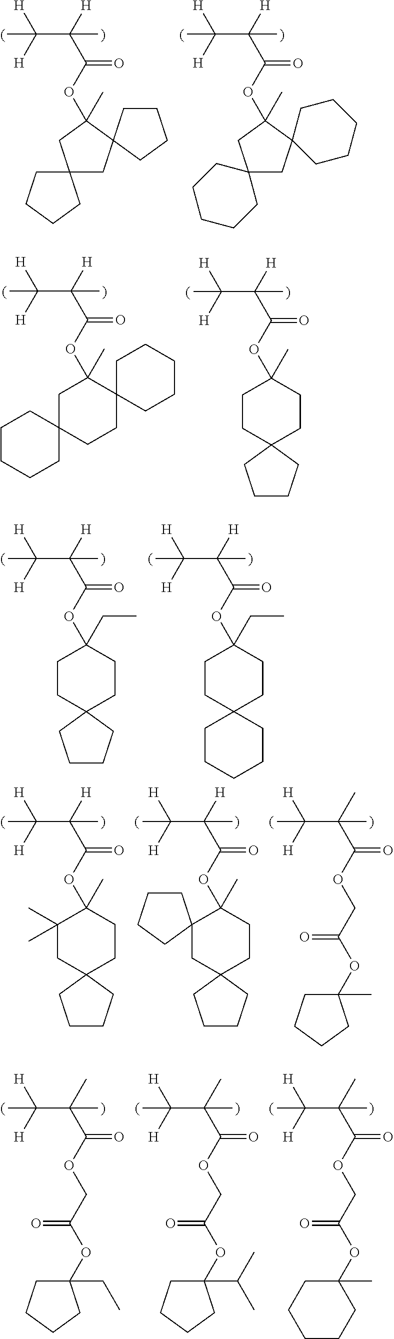

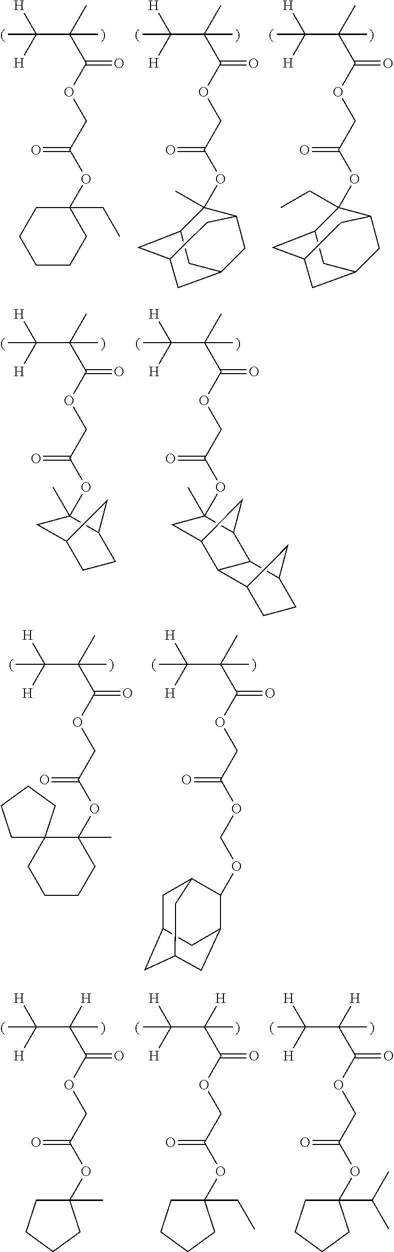

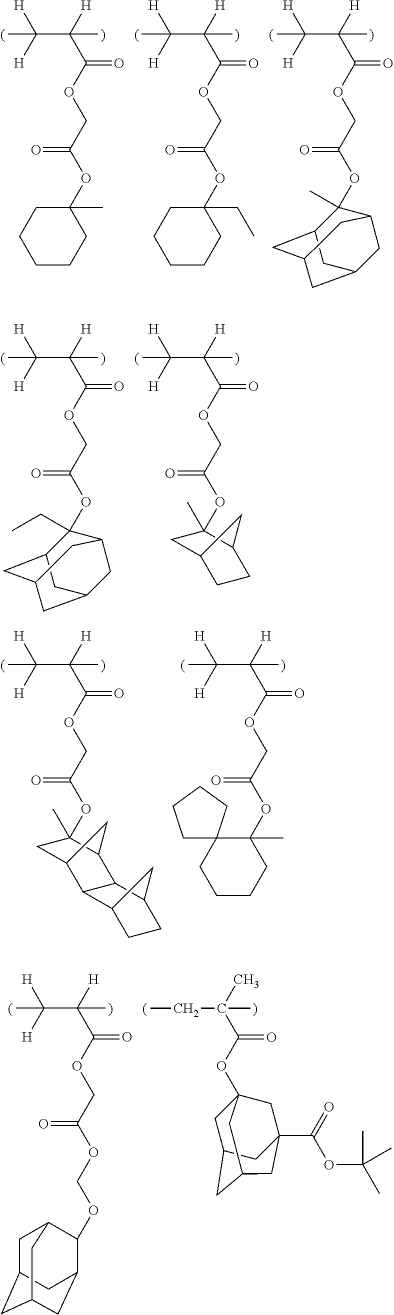

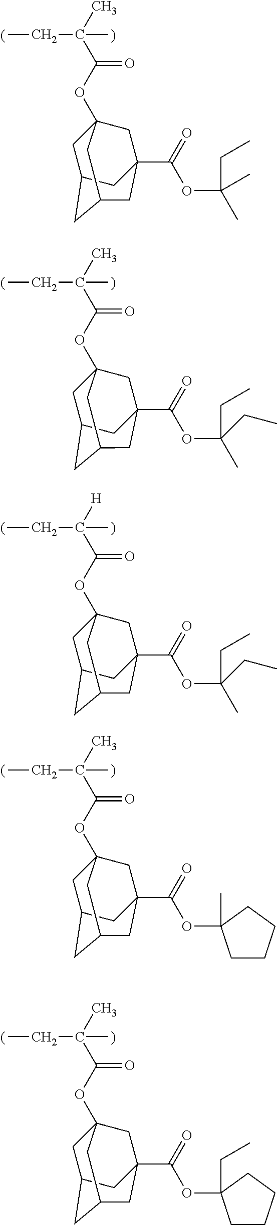

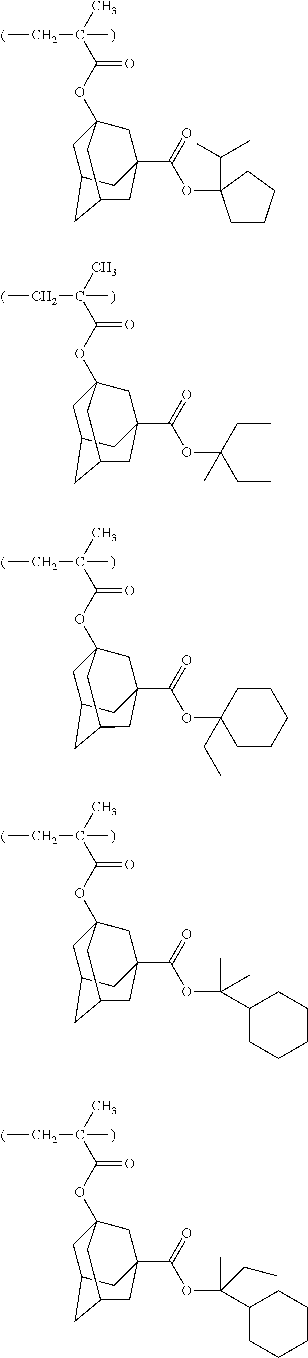

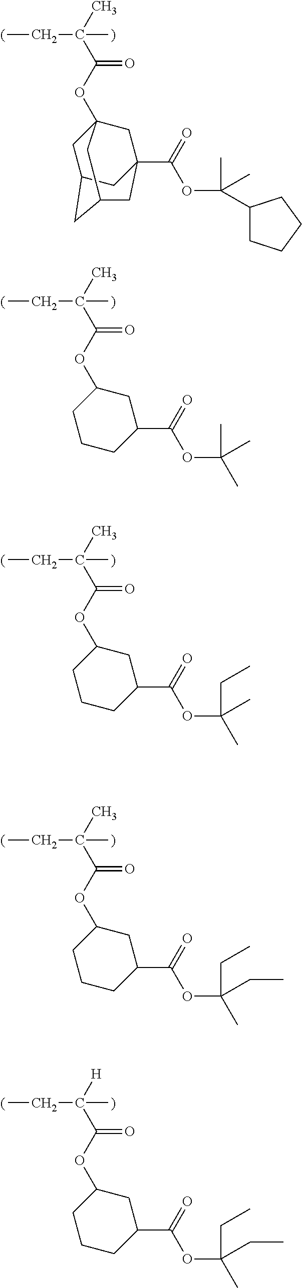

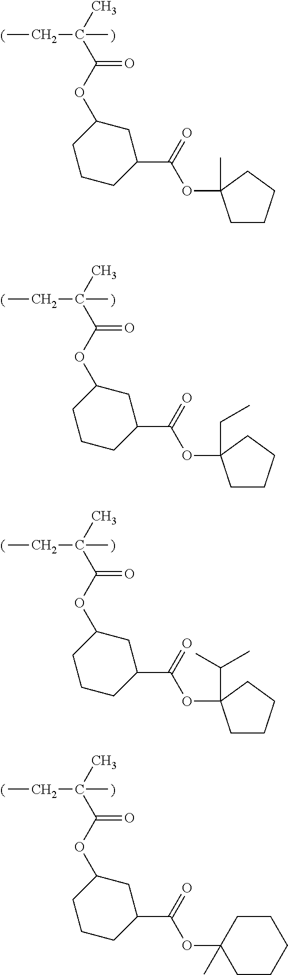

In addition to the acid labile group-bearing units (a1), the polymer (A) essentially comprises recurring units (a2) having a cyclic hydrocarbon group containing at least one of ester, ether, carbonate, and sulfonate radicals within the ring. Notably, the recurring units (a2) of more than one type may be contained in the polymer. Illustrative, non-limiting examples of the recurring unit (a2) are given below.

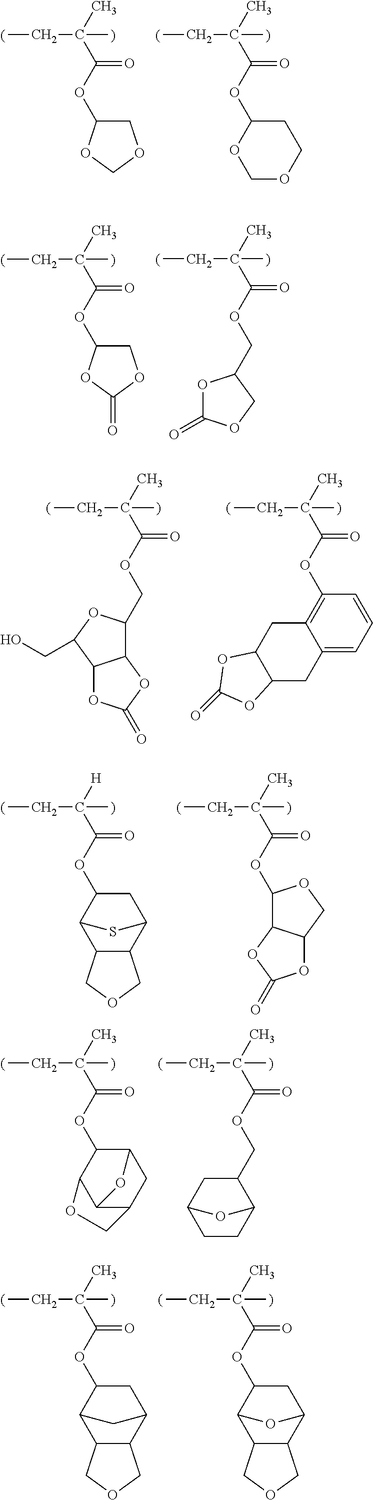

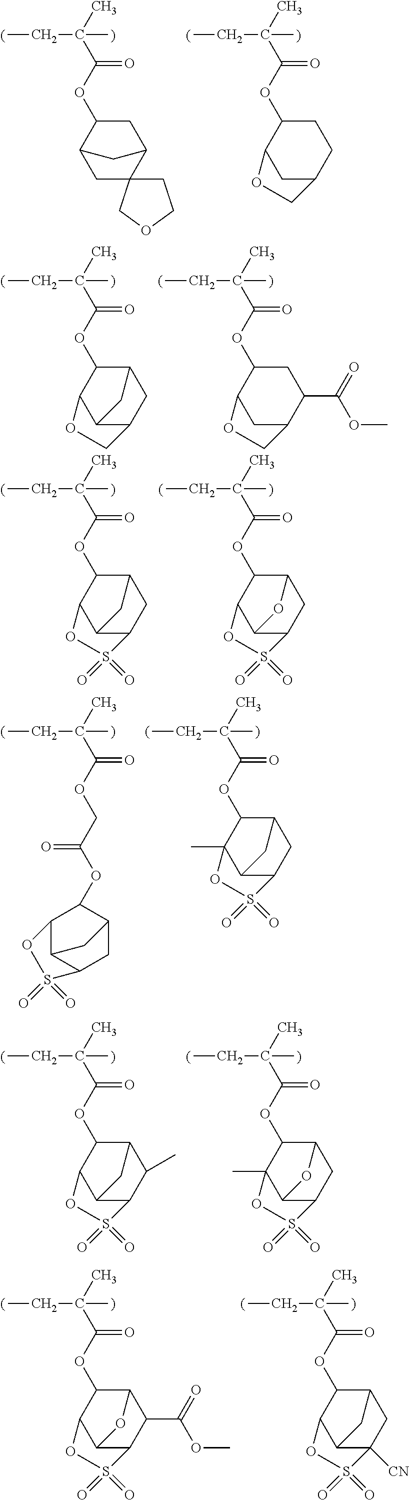

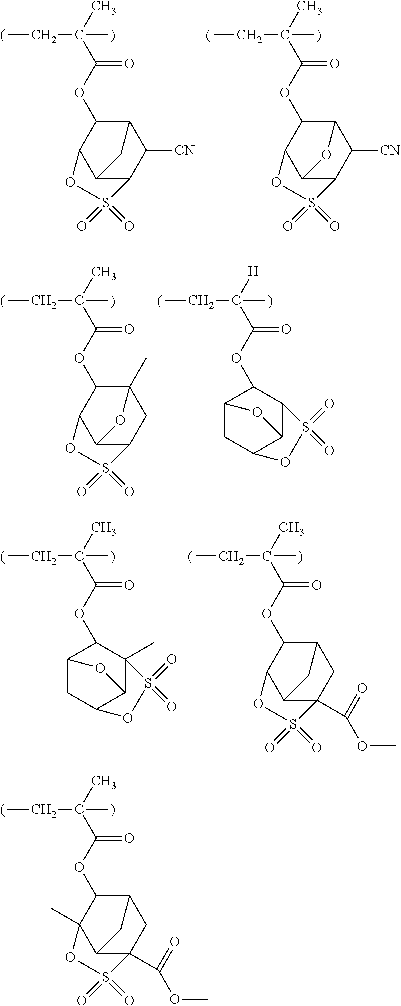

The preferred recurring unit (a2) is a recurring unit having a lactone ring. Illustrative, non-limiting examples of the lactone-bearing recurring unit (a2) are given below.

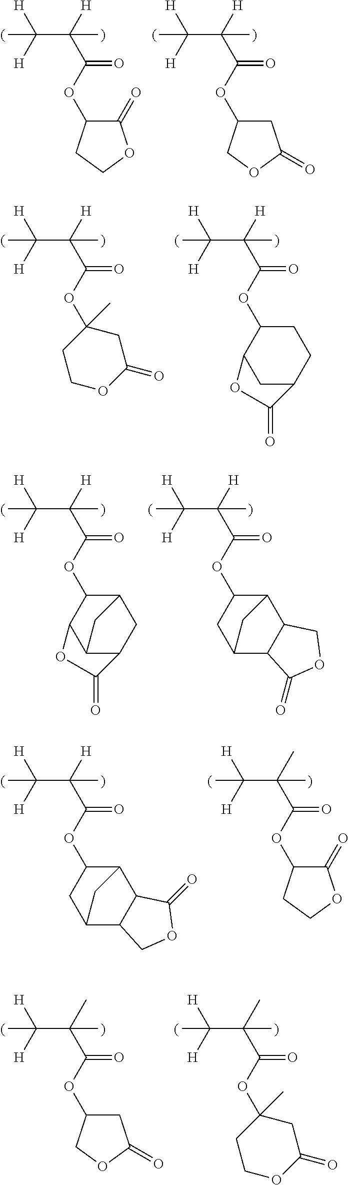

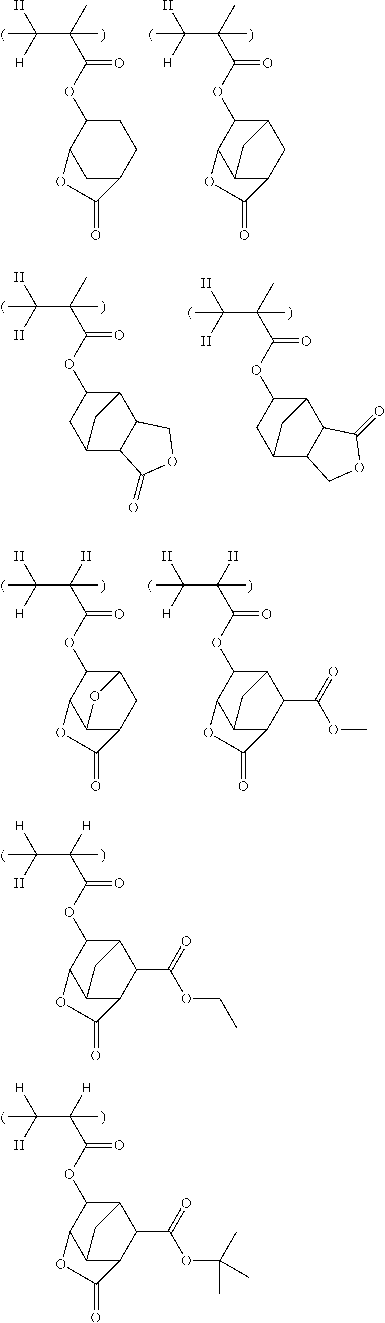

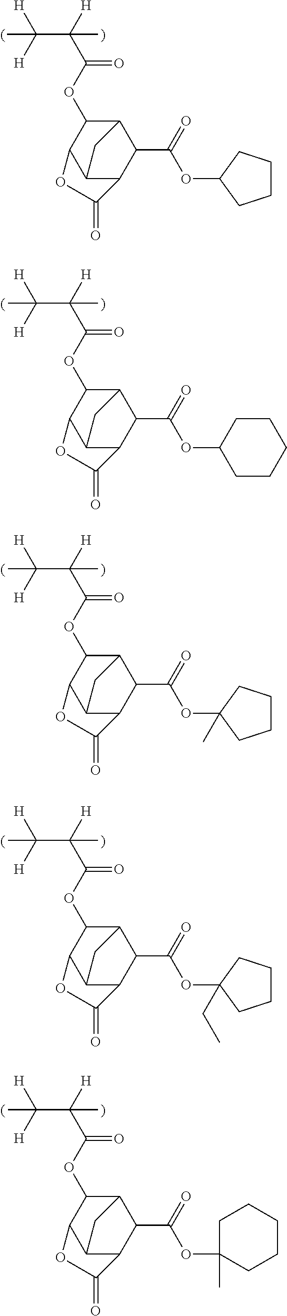

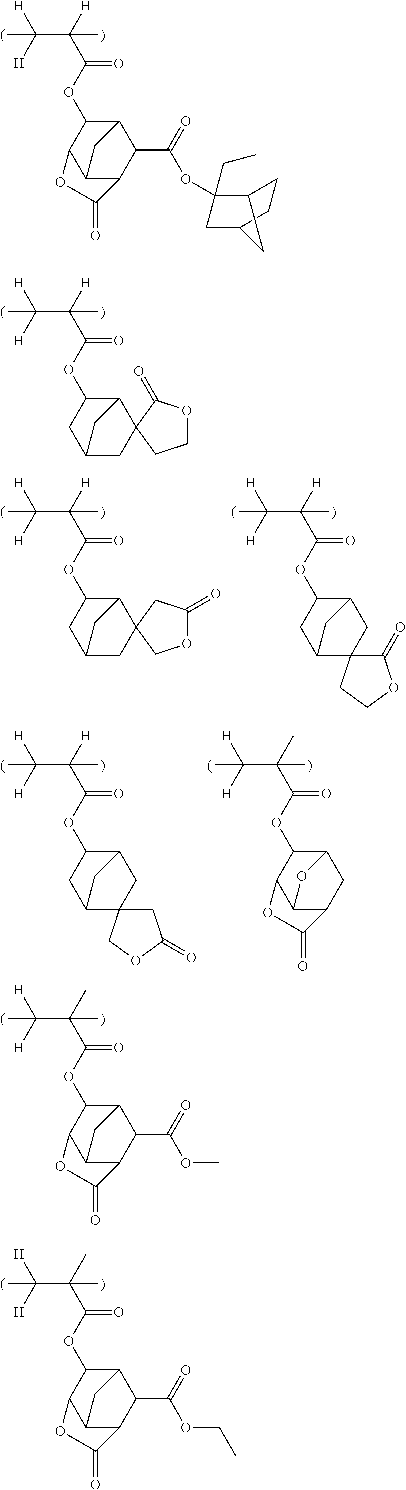

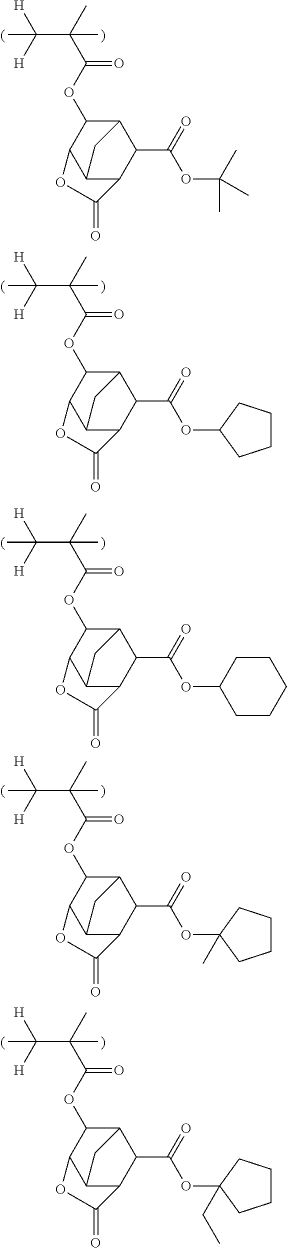

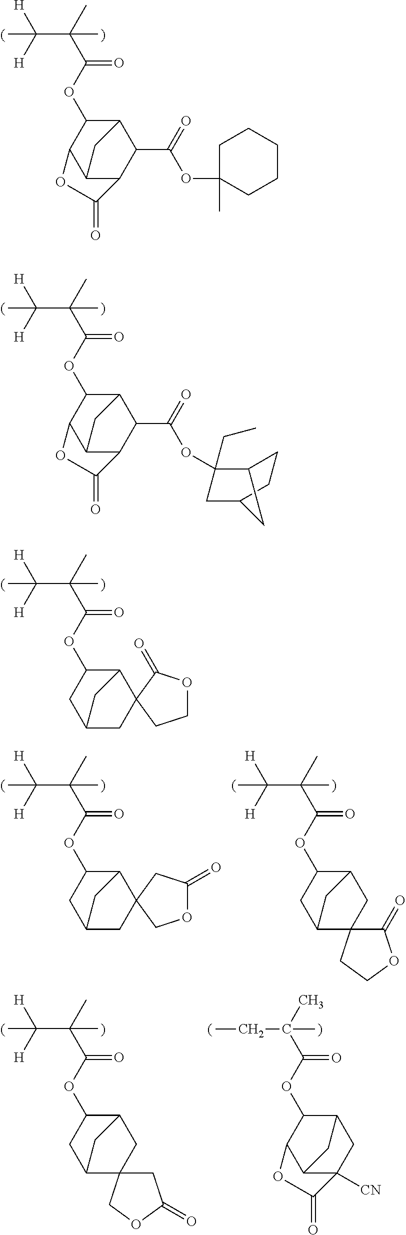

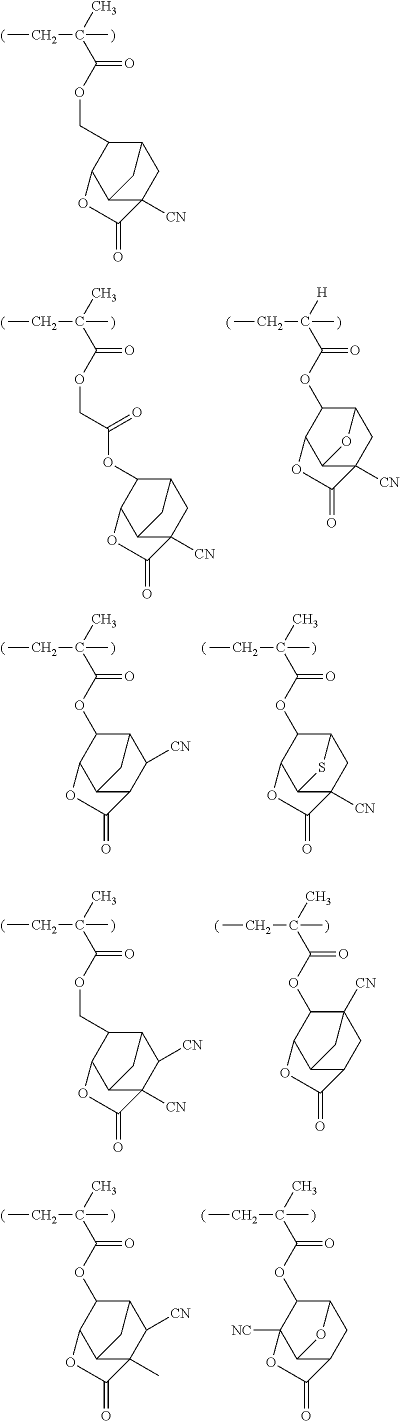

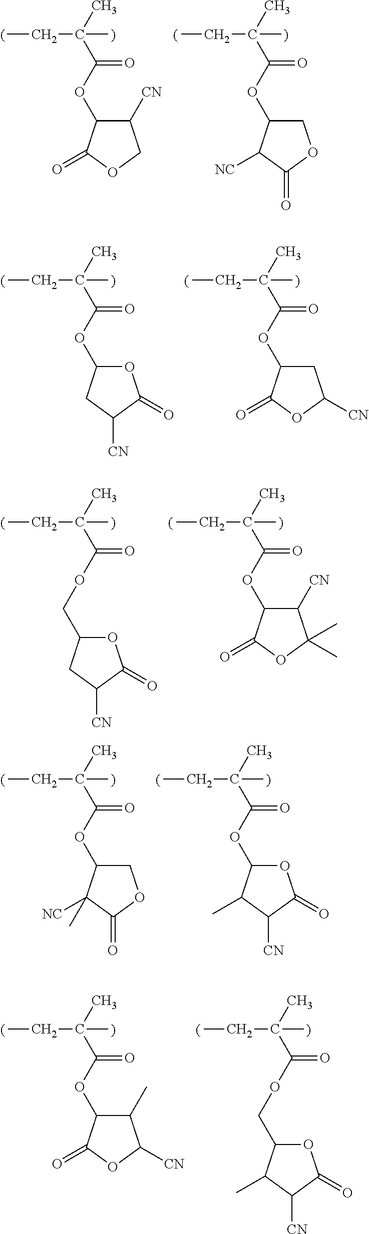

In addition to the recurring units (a1) and (a2), the polymer (A) essentially comprises recurring units (a3) having an oxirane ring. Notably, the recurring units (a3) of more than one type may be contained in the polymer. Illustrative, non-limiting examples of the recurring unit (a3) are given below.

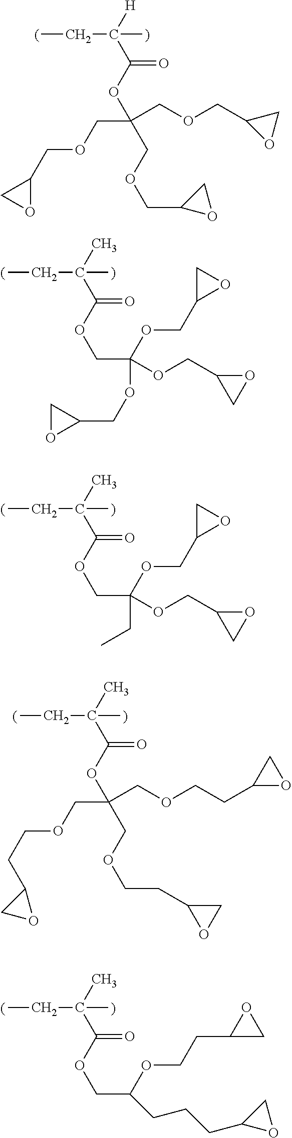

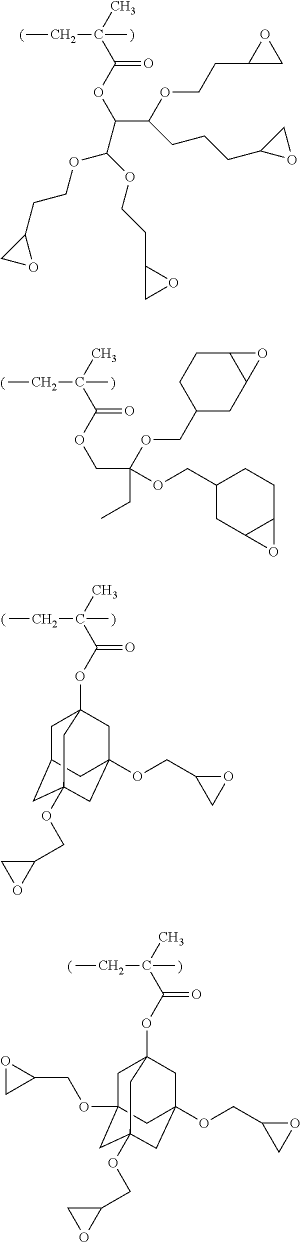

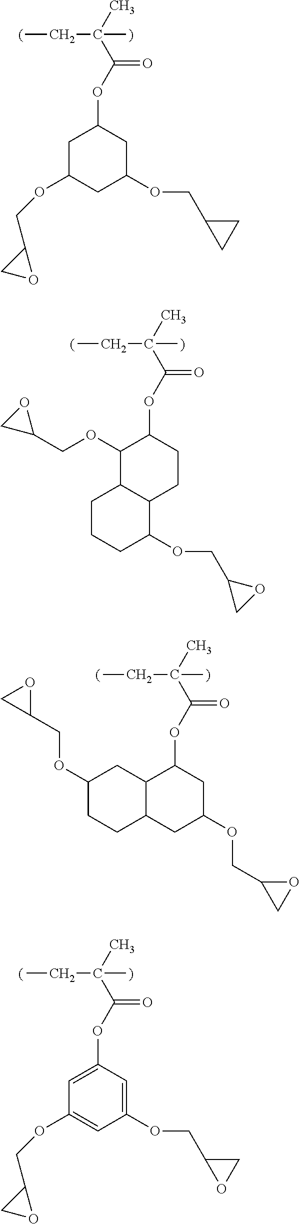

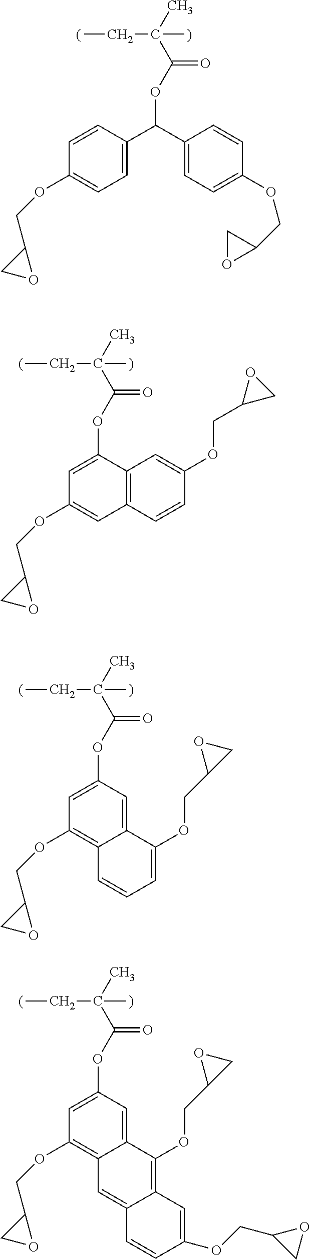

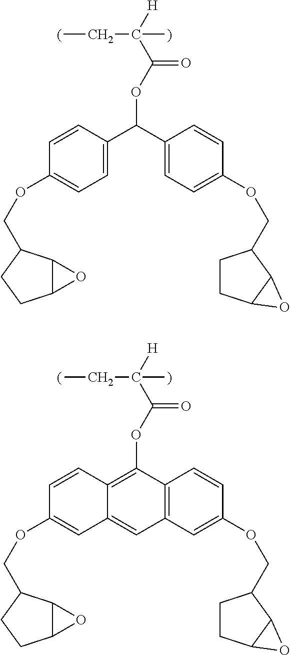

Preferably, the oxirane ring-bearing recurring unit (a3) is a recurring unit having the general formula (2) or (3).

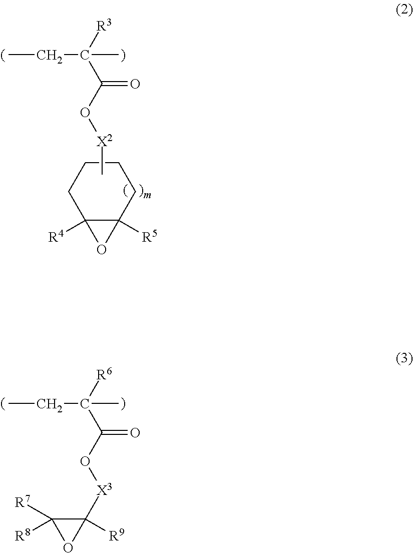

Herein R³ and R⁶ each are hydrogen or methyl, X² and X³ each are a single bond or a divalent hydrocarbon group which may contain an ester or ether bond, R⁴, R⁵, R⁷ to R⁹ each are hydrogen or a straight or branched C₁-C₅ alkyl group, and m is 0 or 1.

Illustrative, non-limiting examples of the recurring unit having formula (2) or (3) are given below.

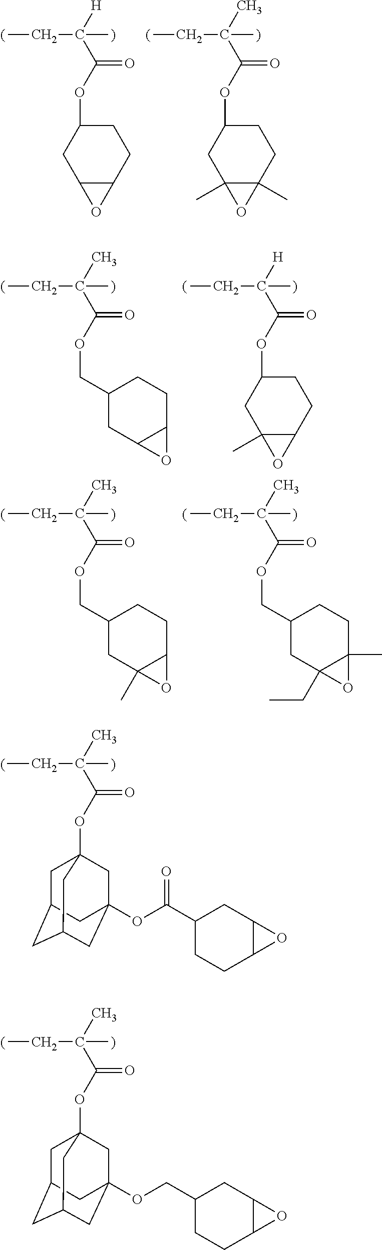

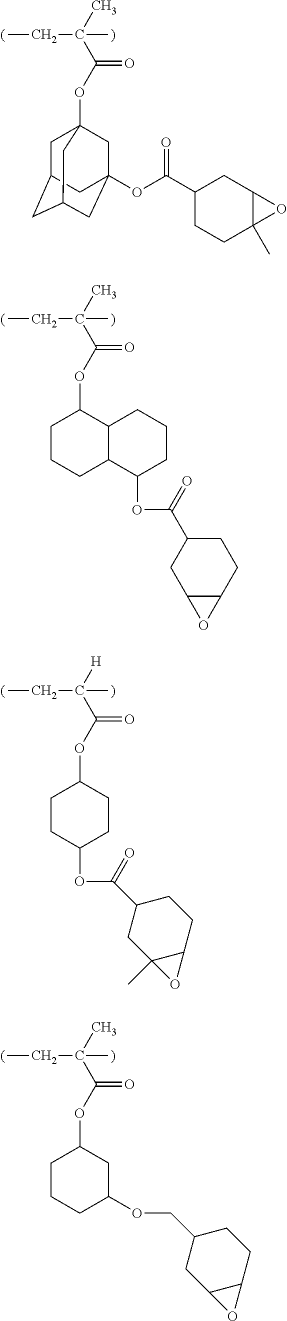

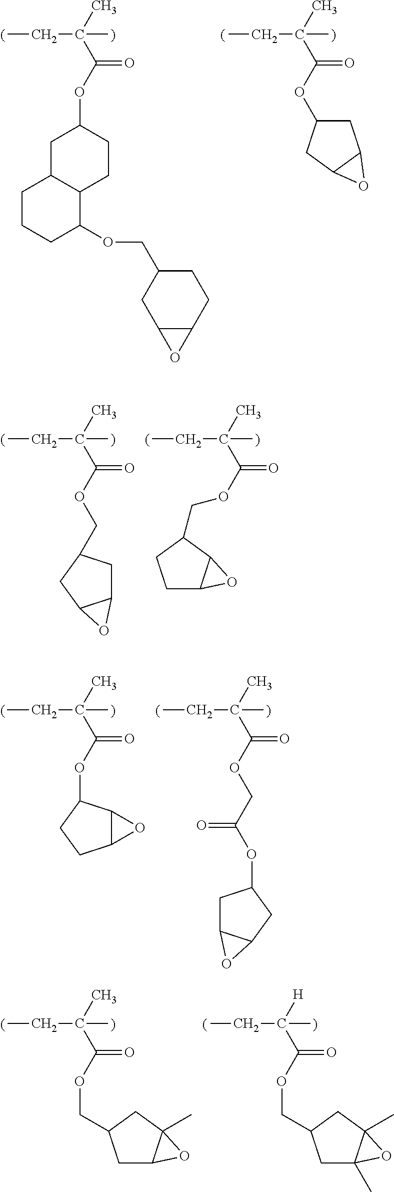

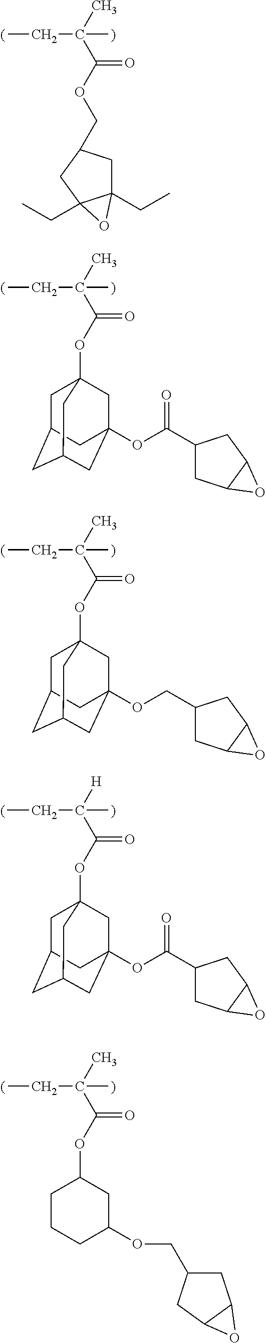

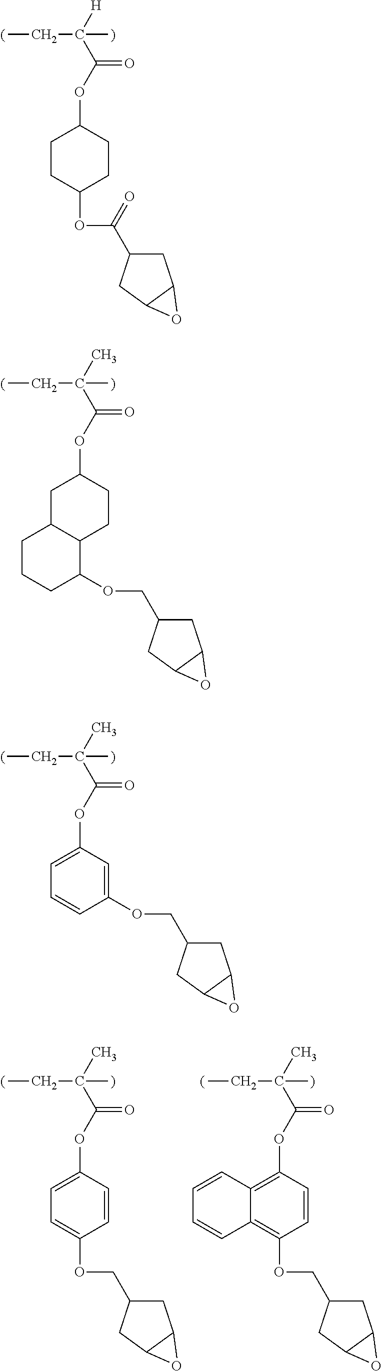

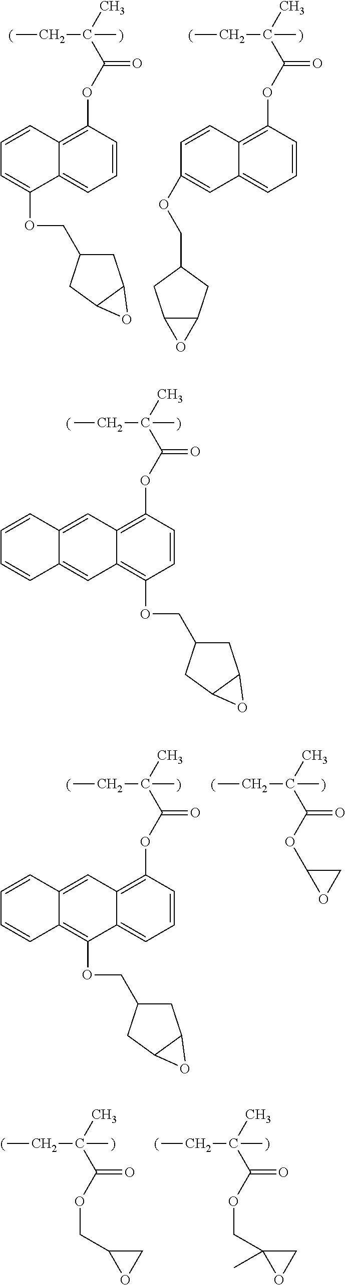

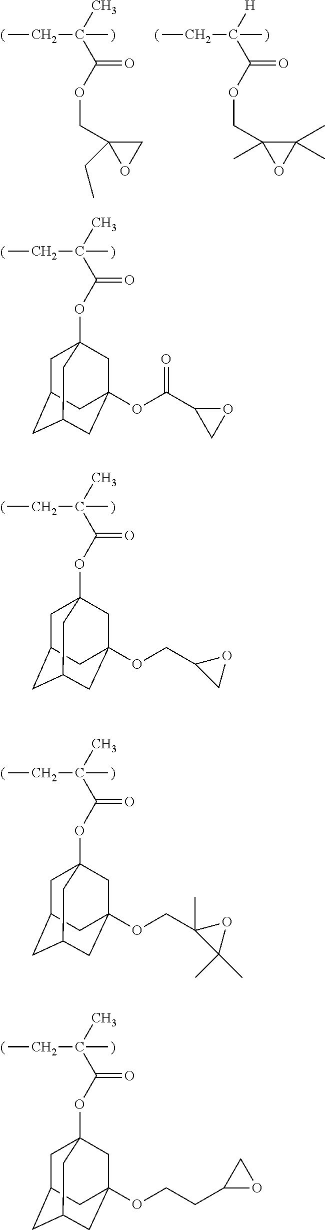

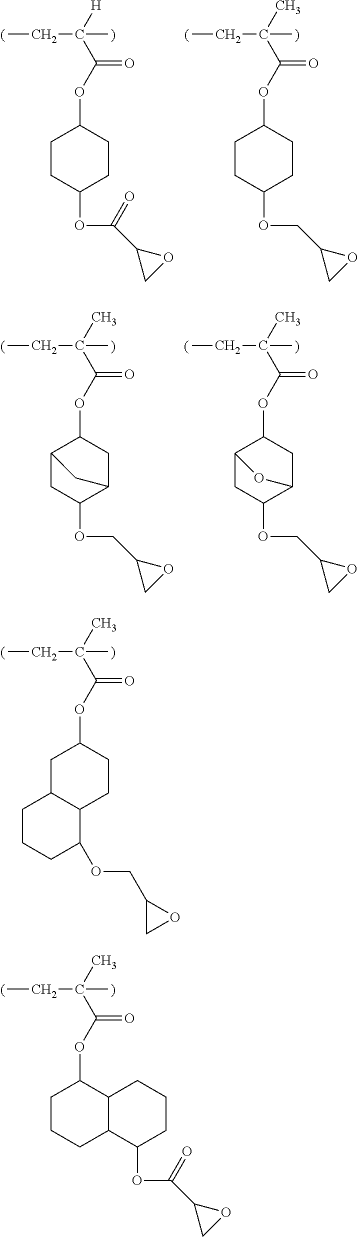

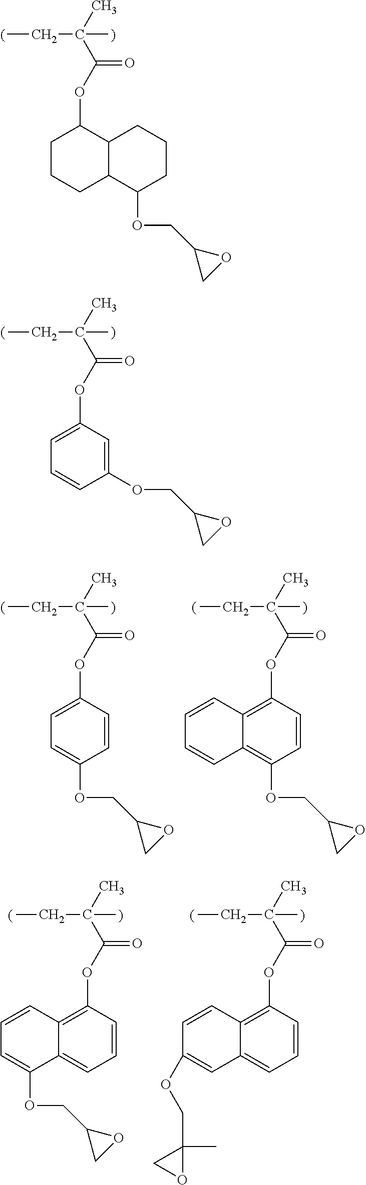

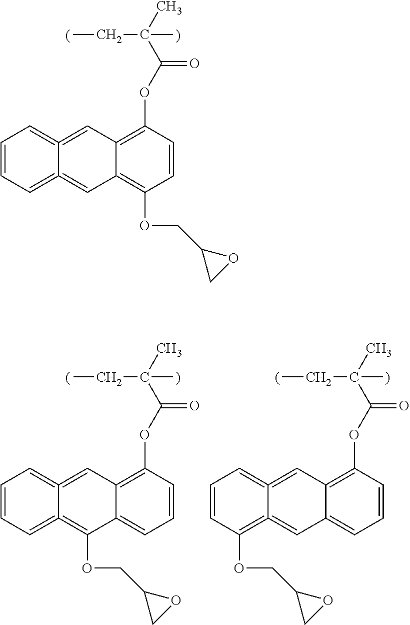

In addition to the recurring units (a1), (a2) and (a3), the polymer (A) may optionally comprise recurring units (a4) of an onium salt having the general formula (10).

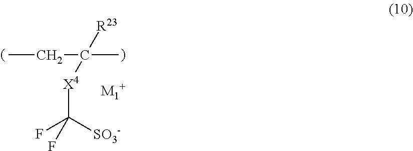

Herein R²³ is hydrogen or methyl. X⁴ is a straight or branched C₁-C₂₀ alkylene group, —O—R²⁴—, or —C(═O)—X⁵—R²⁴—. The hydrogen atom bonded to a carbon atom in the alkylene group of X⁴ is optionally substituted by fluorine. X⁵ is oxygen or NH, and R²⁴ is a straight, branched or cyclic C₁-C₂₅ alkylene group which may contain a carbonyl, ester or ether radical and in which a carbon-bonded hydrogen atom may be substituted by fluorine. M₁⁺ is a sulfonium or iodonium cation having a substituent group.

Inclusion of the onium salt recurring unit (a4) having formula (10) is effective for restraining acid diffusion and obtaining satisfactory LWR.

Illustrative, non-limiting structures exemplary of the formula (10) are given below.

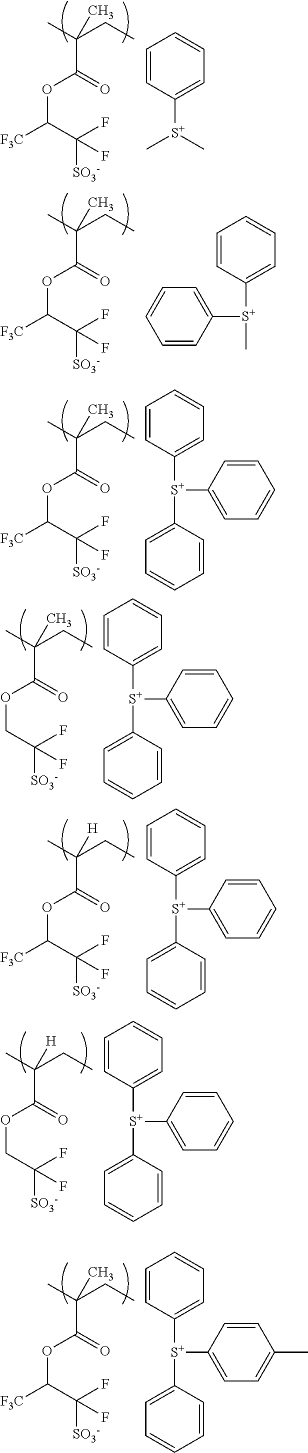

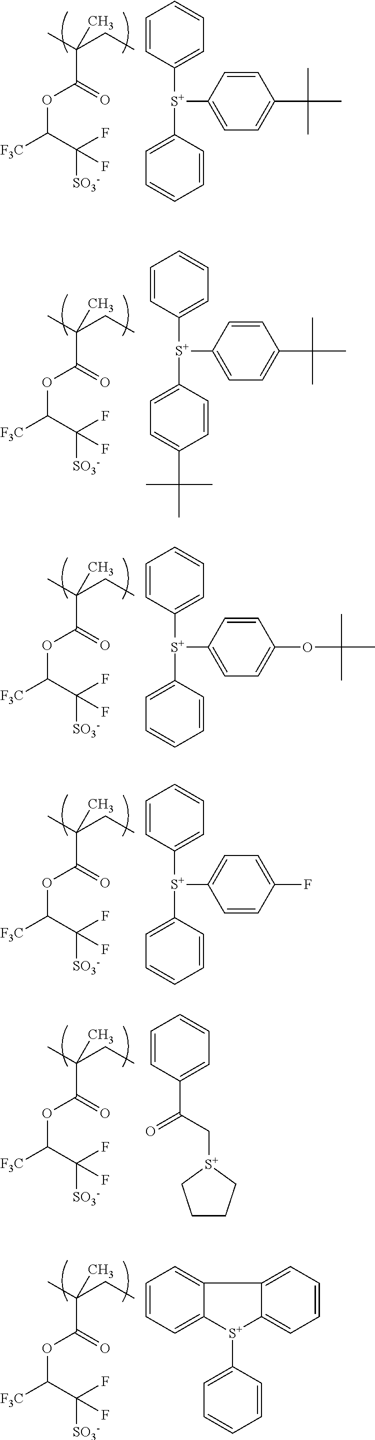

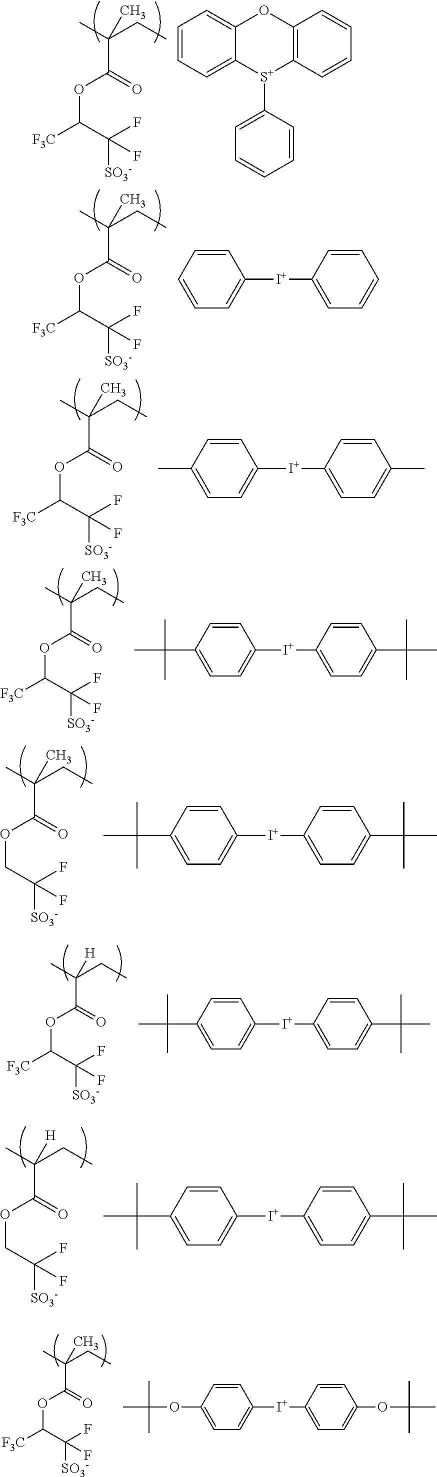

Optionally, the polymer (A) may further comprise additional recurring units of one or more type, for example, units having a hydroxyl, carboxyl, fluoroalkyl or α-trifluoromethyl alcohol group. Examples of the additional units are given below, but not limited thereto.

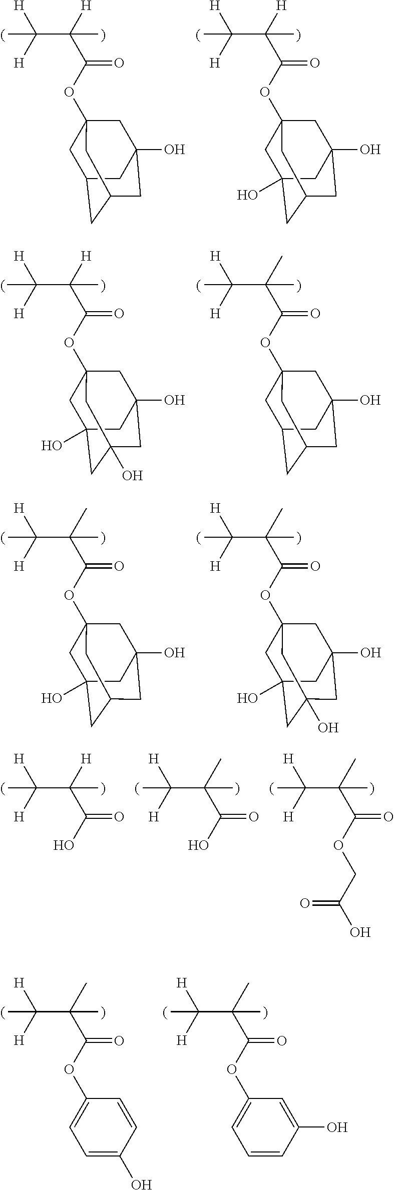

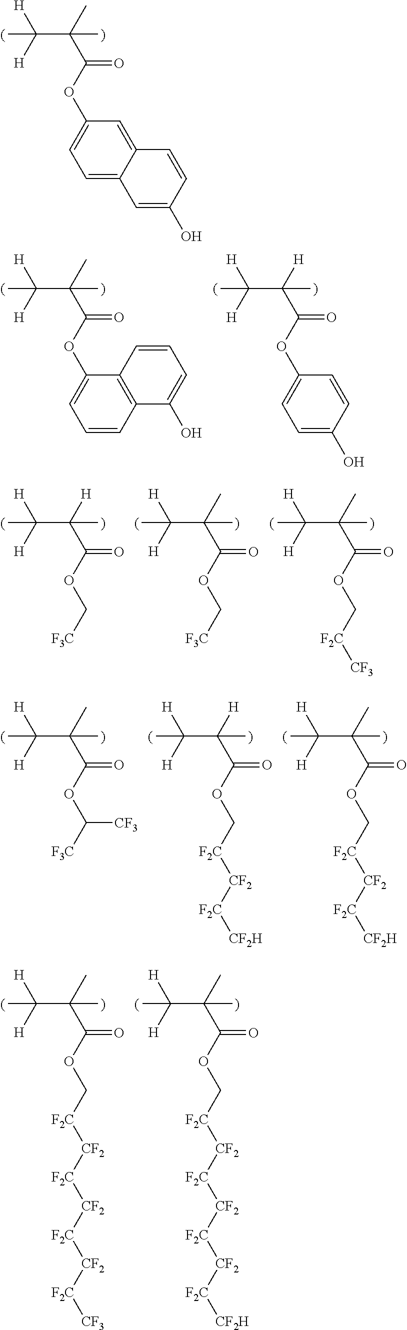

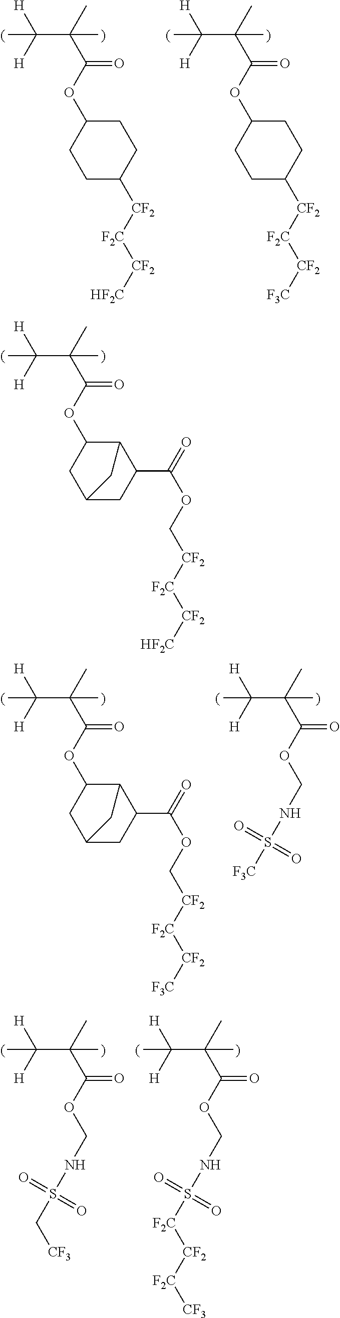

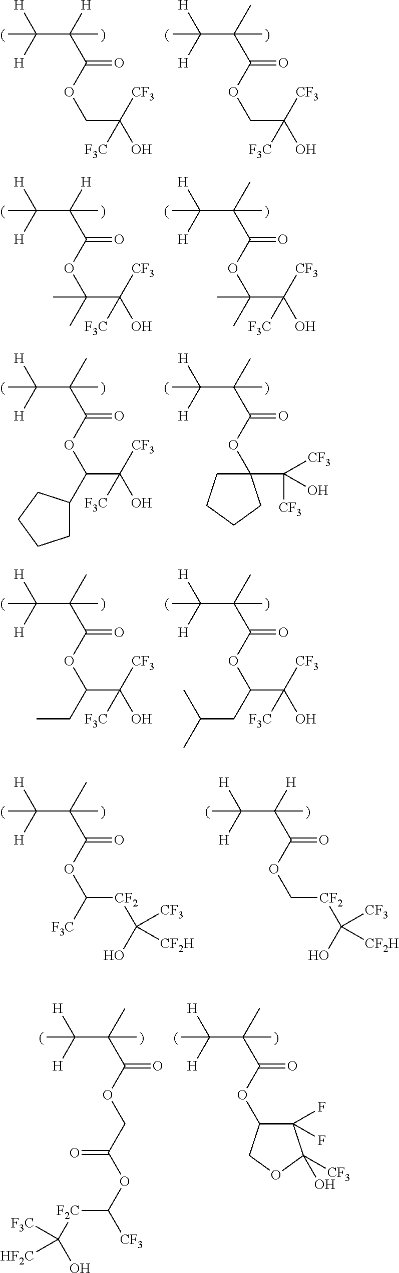

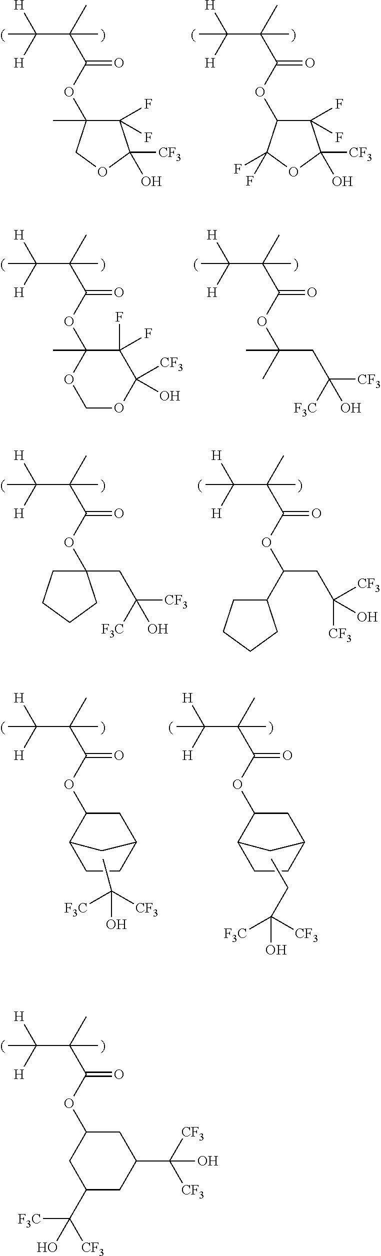

The compositional ratio (or molar fraction) of recurring units of which the polymer (A) is constructed is preferably in the following range. Provided that a total content of units (a1) is “a” mol %, a total content of units (a2) is “b” mol %, a total content of units (a3) is “c” mol %, a total content of units (a4) is “d” mol %, a total content of other recurring units is “e” mol %, and a+b+c+d+e=100 mol %, the compositional ratio is preferably in the range:

0<a≦70, 0<b≦70, 0<c≦20, 0≦d≦20, and 0≦e≦30, and more preferably
30≦a≦70, 20≦b≦60, 1≦c≦10, 0≦d≦10, and 0≦e≦20.

The polymer preferably has a weight average molecular weight (Mw) of 1,000 to 500,000, and more preferably 2,000 to 30,000 as measured versus polystyrene standards by gel permeation chromatography (GPC) using tetrahydrofuran solvent.

Also, the positive resist composition comprises (B) a photoacid generator. A mixture of two or more PAGs is acceptable.

Preferably PAG (B) is a compound capable of generating an α-position fluorinated sulfonic acid having the general formula (4) upon light exposure.

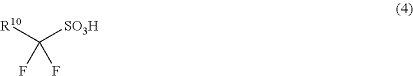

Herein R¹⁰ is a monovalent, straight, branched or cyclic C₁-C₃₅ hydrocarbon group which may contain a heteroatom and in which at least one carbon-bonded hydrogen atom may be substituted by fluorine.

Examples of the sulfonic acid having formula (4) include compounds of the following structures, but are not limited thereto.

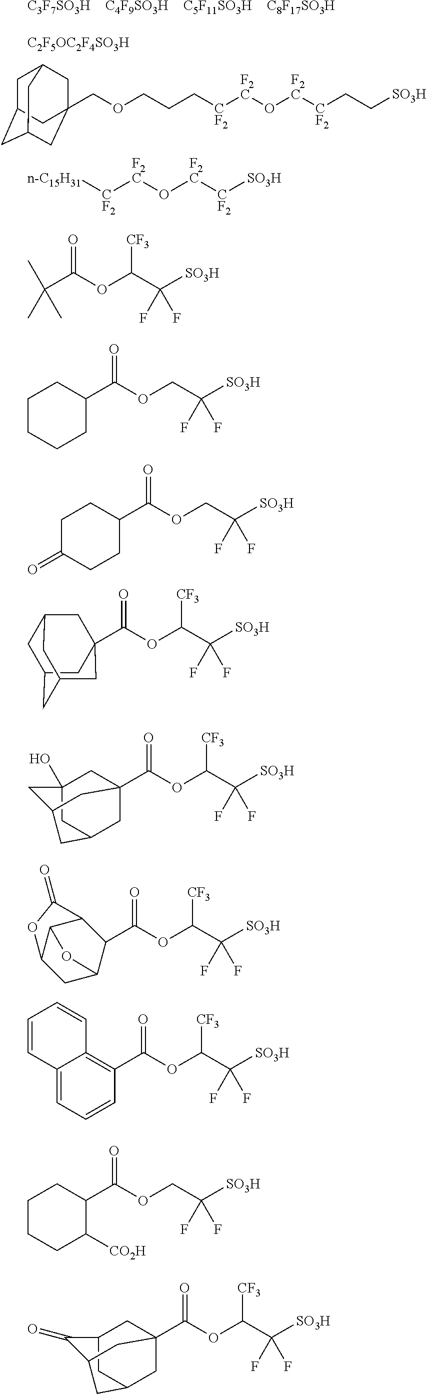

More preferably PAG (B) is a sulfonium salt having the general formula (5).

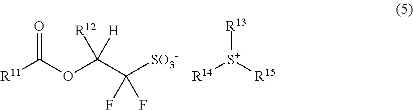

Herein R¹¹ is a substituted or unsubstituted, straight, branched or cyclic C₁-C₃₀ alkyl group which may contain a heteroatom, or a substituted or unsubstituted C₆-C₃₀ aryl group. R¹² is hydrogen or trifluoromethyl. R¹³, R¹⁴, and R¹⁵ are each independently a substituted or unsubstituted, straight or branched C₁-C₁₀ alkyl, alkenyl or oxoalkyl group, or a substituted or unsubstituted C₆-C₁₈ aryl, aralkyl or aryloxoalkyl group, or at least two of R¹³, R¹⁴, and R¹⁵ may bond together to form a ring with the sulfur atom in the formula.

Suitable alkyl and alkenyl groups include methyl, ethyl, n-propyl, isopropyl, n-butyl, tert-butyl, cyclopropyl, cyclopentyl, cyclohexyl, cyclopropylmethyl, 4-methylcyclohexyl, cyclohexylmethyl, norbornyl, adamantyl, vinyl, allyl, propenyl, butenyl, hexenyl, and cyclohexenyl, and substituted forms of the foregoing in which some hydrogen atoms are substituted by fluorine atoms, hydroxyl radicals or the like.

Suitable oxoalkyl groups include 2-oxocyclopentyl, 2-oxocyclohexyl, 2-oxopropyl, 2-oxoethyl, 2-cyclopentyl-2-oxoethyl, 2-cyclohexyl-2-oxoethyl, and 2-(4-methylcyclohexyl)-2-oxoethyl, and substituted forms of the foregoing in which some hydrogen atoms are substituted by fluorine atoms, hydroxyl radicals or the like.

Suitable aryl groups include phenyl, naphthyl and thienyl, as well as hydroxyphenyl groups such as 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, and 3-tert-butoxyphenyl, alkylphenyl groups such as 2-methylphenyl, 3-methylphenyl, 4-methylphenyl, 4-ethylphenyl, 4-tert-butylphenyl, 4-n-butylphenyl, and 2,4-dimethylphenyl, alkylnaphthyl groups such as methylnaphthyl and ethylnaphthyl, alkoxynaphthyl groups such as methoxynaphthyl and ethoxynaphthyl, dialkylnaphthyl groups such as dimethylnaphthyl and diethylnaphthyl, and dialkoxynaphthyl groups such as dimethoxynaphthyl and diethoxynaphthyl. In the foregoing groups, some hydrogen atoms may be substituted by fluorine atoms, hydroxyl radicals or the like.

Suitable aralkyl groups include benzyl, 1-phenylethyl, and 2-phenylethyl. Suitable aryloxoalkyl groups include 2-aryl-2-oxoethyl groups such as 2-phenyl-2-oxoethyl, 2-(1-naphthyl)-2-oxoethyl, and 2-(2-naphthyl)-2-oxoethyl. In these groups, some hydrogen atoms may be substituted by fluorine atoms, hydroxyl radicals or the like.

Examples of the group R¹¹ are shown below, but not limited thereto.

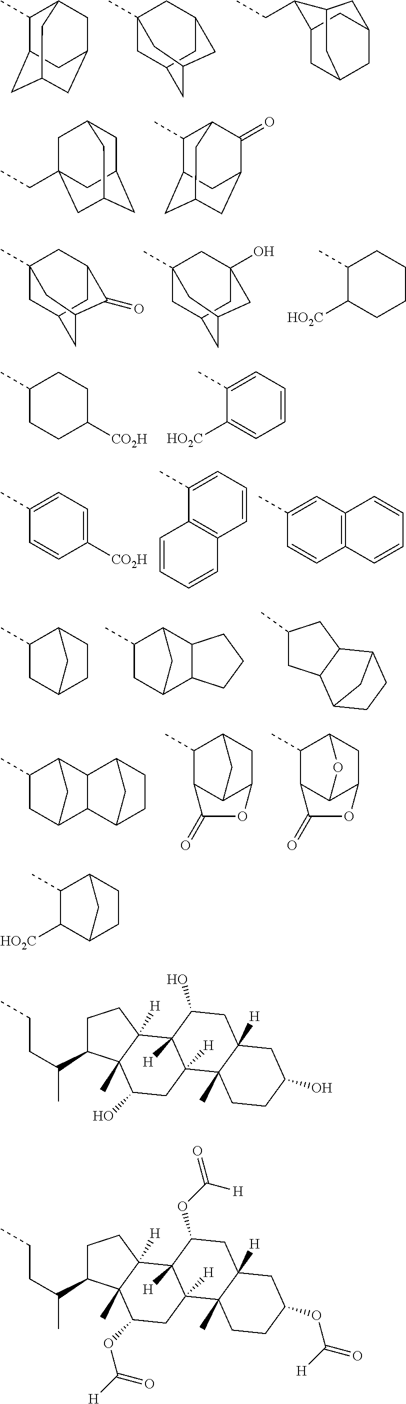

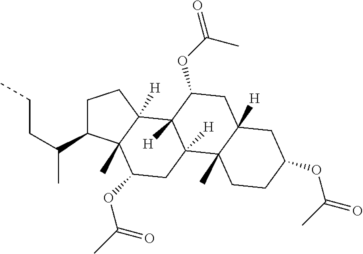

Examples of PAG (B) are illustrated by the following structures, but not limited thereto.

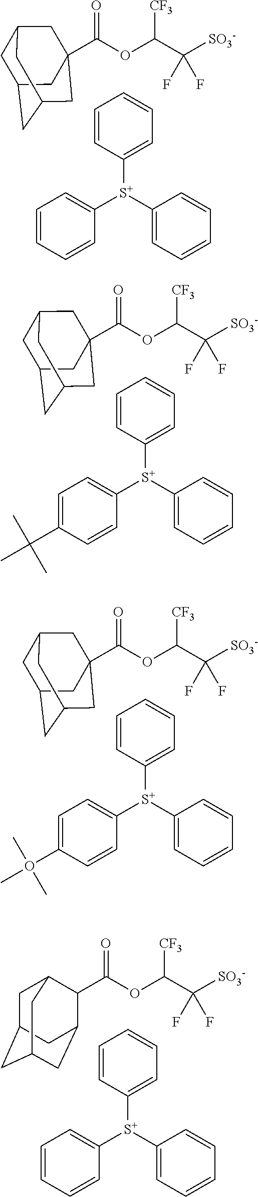

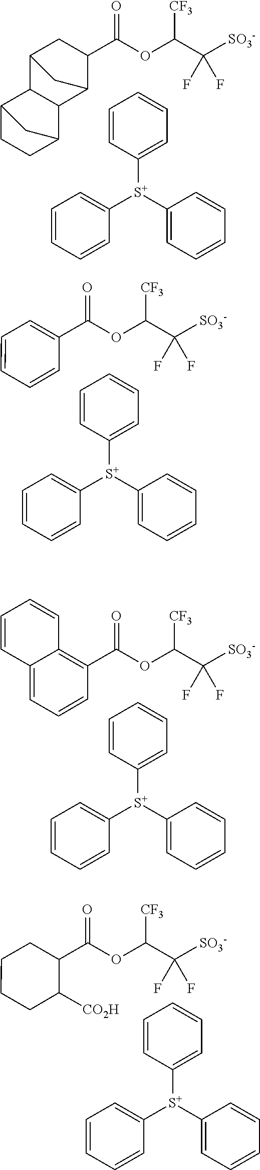

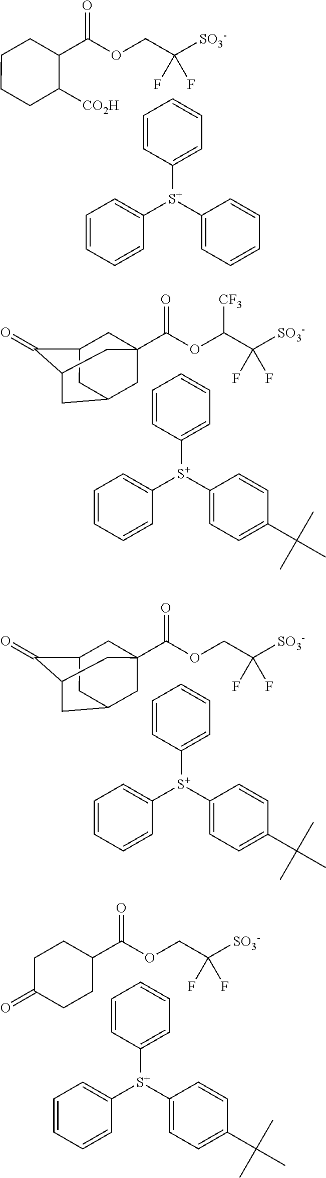

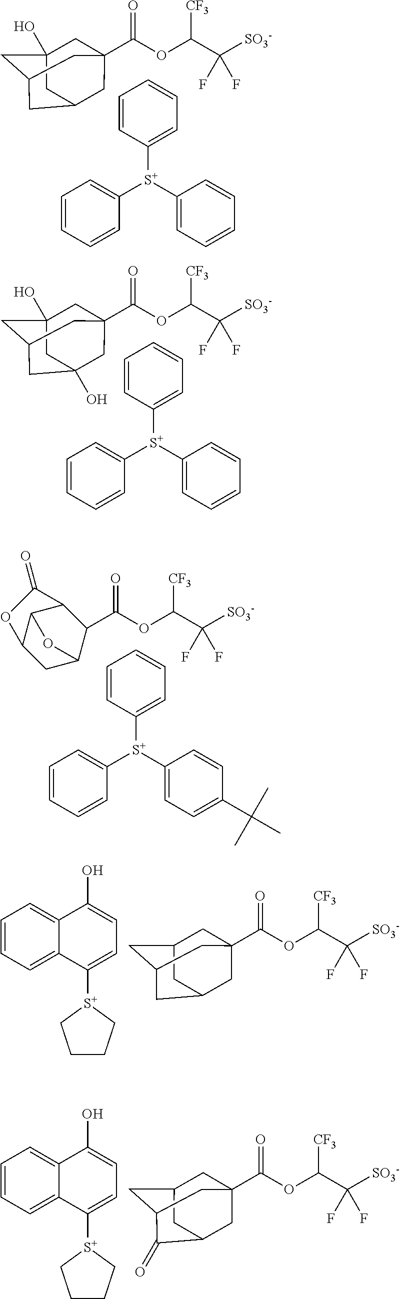

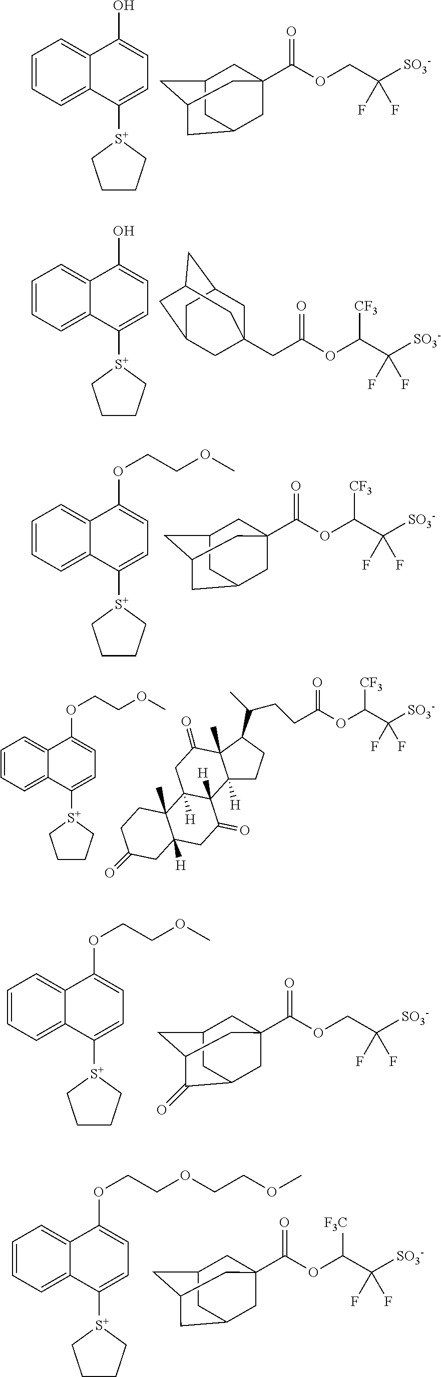

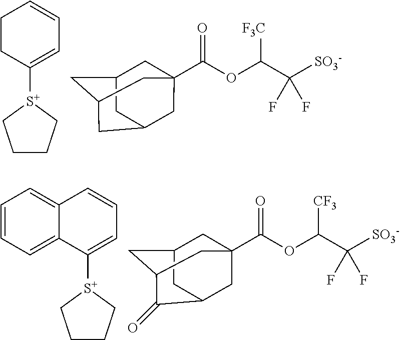

An appropriate amount of PAG (B) is 3 to 25 parts by weight per 100 parts by weight of the polymer or base resin (A).

In a preferred embodiment, the resist composition may further comprise (D) an onium salt of sulfonic acid or carboxylic acid having the general formula (6) or (7).

R¹⁶—SO₃⁻M₂⁺ (6)

R¹⁷—COO⁻M₂⁺ (7)

Herein R¹⁶ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of sulfonic acid. R¹⁷ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of carboxylic acid. M₂⁺ is a counter cation having a substituent group, which is a sulfonium, iodonium or ammonium cation.

Preferably component (D) is an onium salt having the general formula (8) or (9).

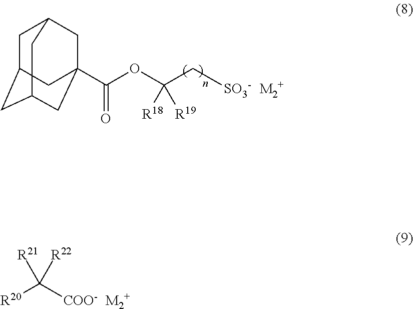

Herein R¹⁸, R¹⁹, R²¹, and R²² each are hydrogen or trifluoromethyl. R²⁰ is hydrogen, hydroxyl, a substituted or unsubstituted, straight, branched or cyclic C₁-C₂₀ alkyl group, or a substituted or unsubstituted C₆-C₃₀ aryl group. The subscript n is an integer of 1 to 3. M₂⁺ is a counter cation having a substituent group, which is a sulfonium, iodonium or ammonium cation.

Illustrative, non-limiting examples of the onium salt (D) are given below.

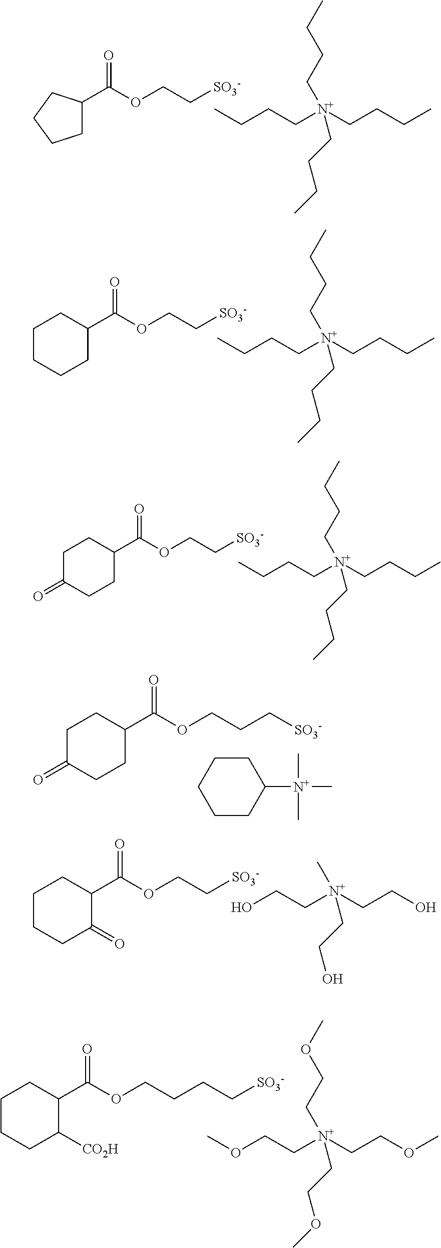

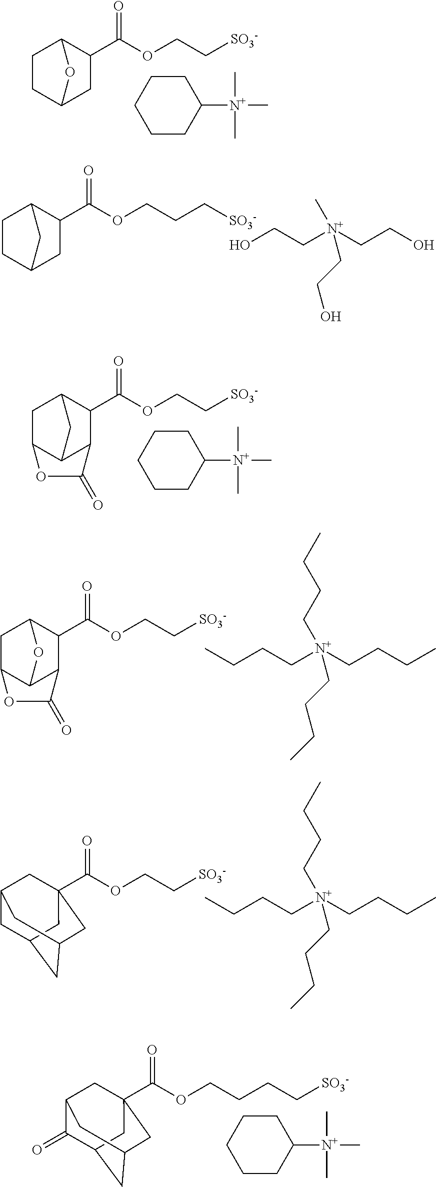

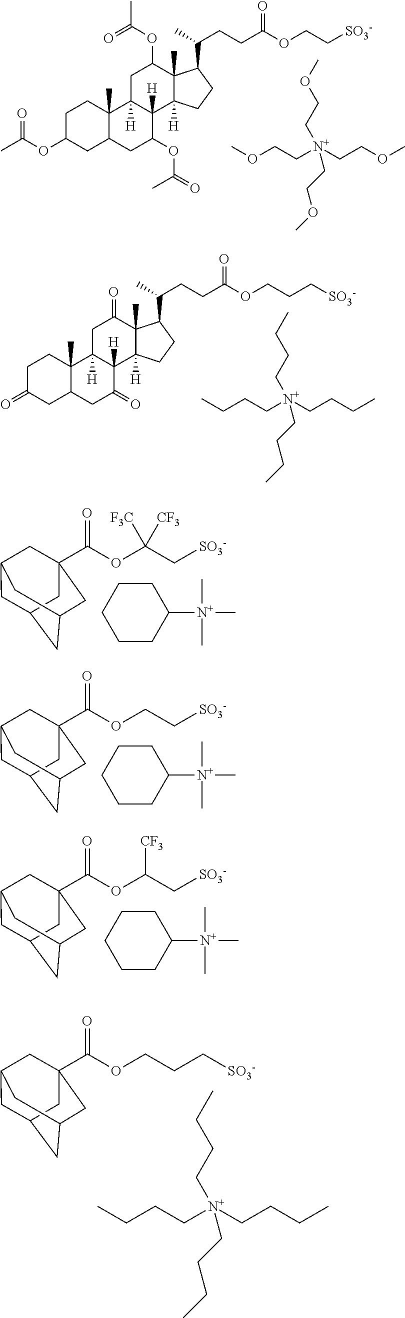

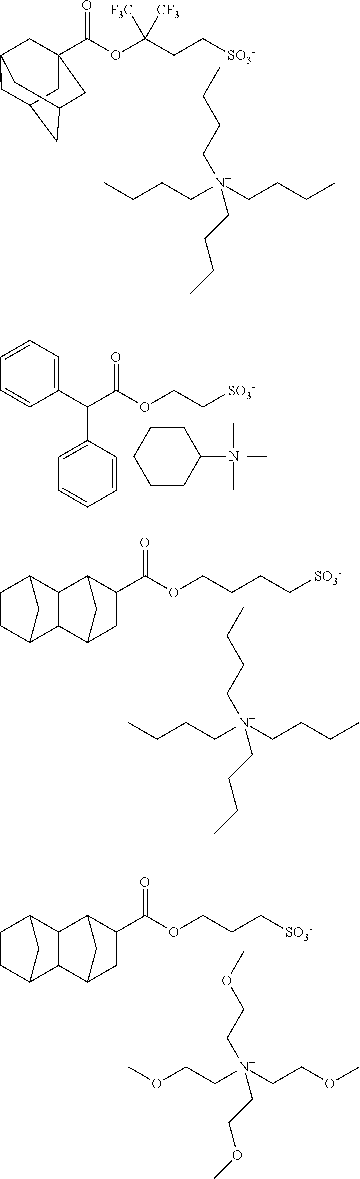

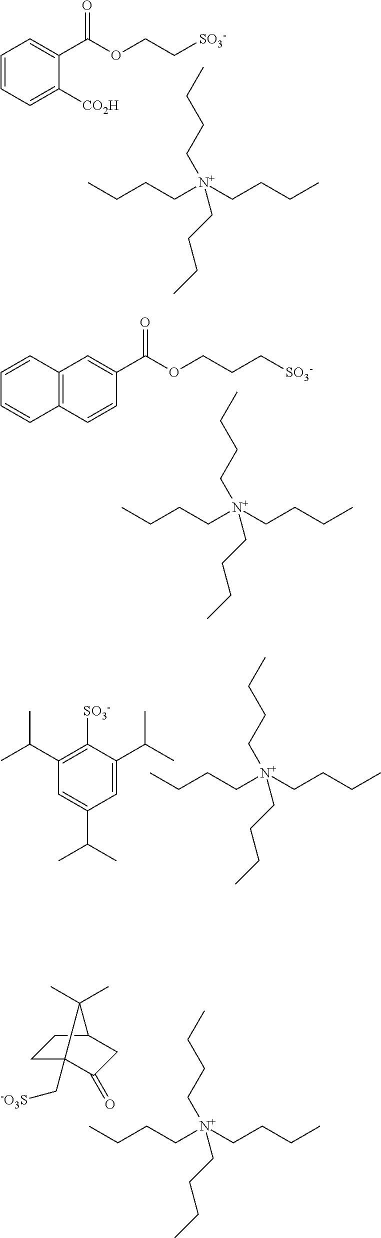

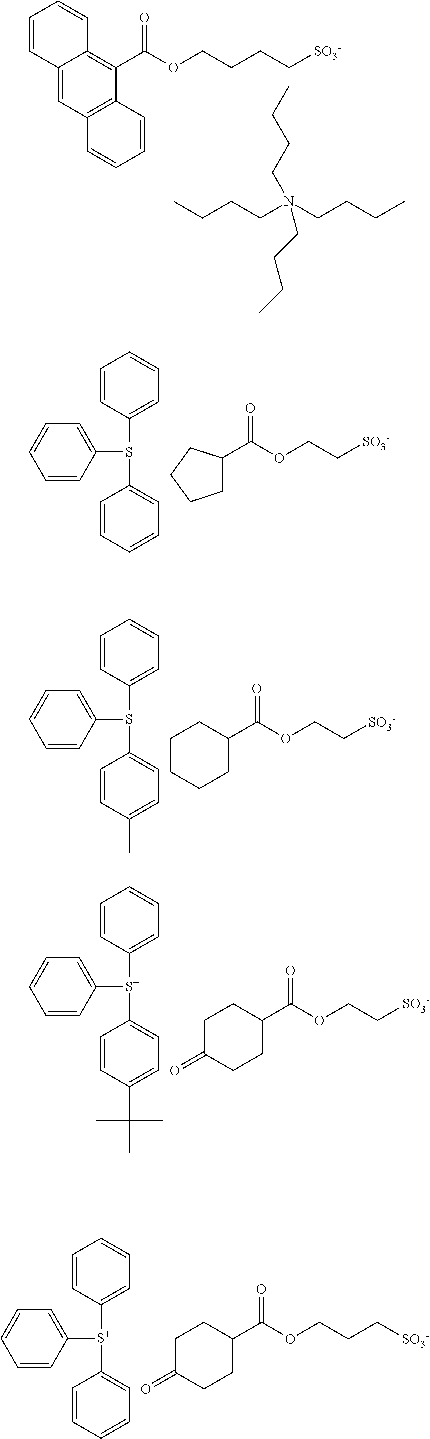

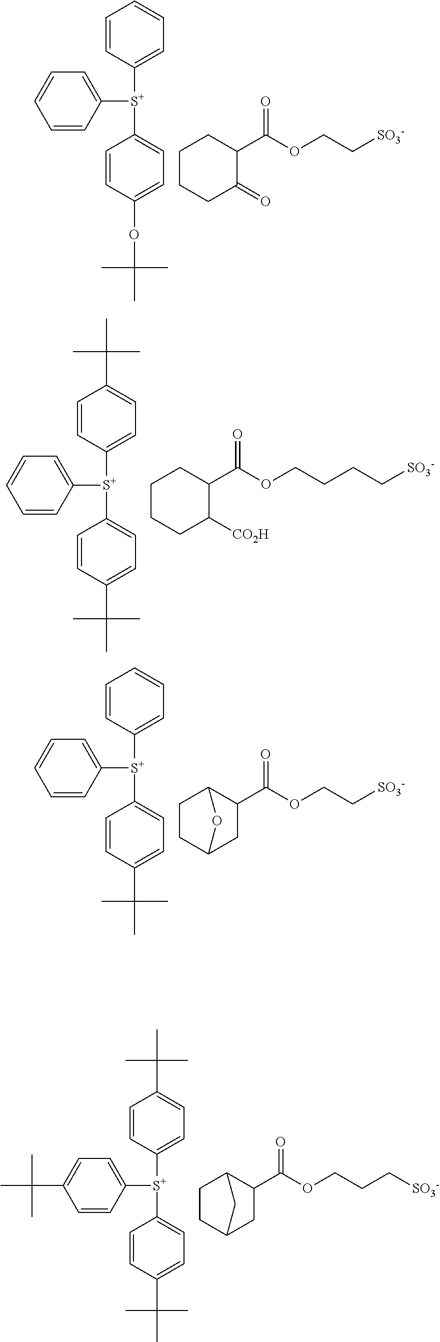

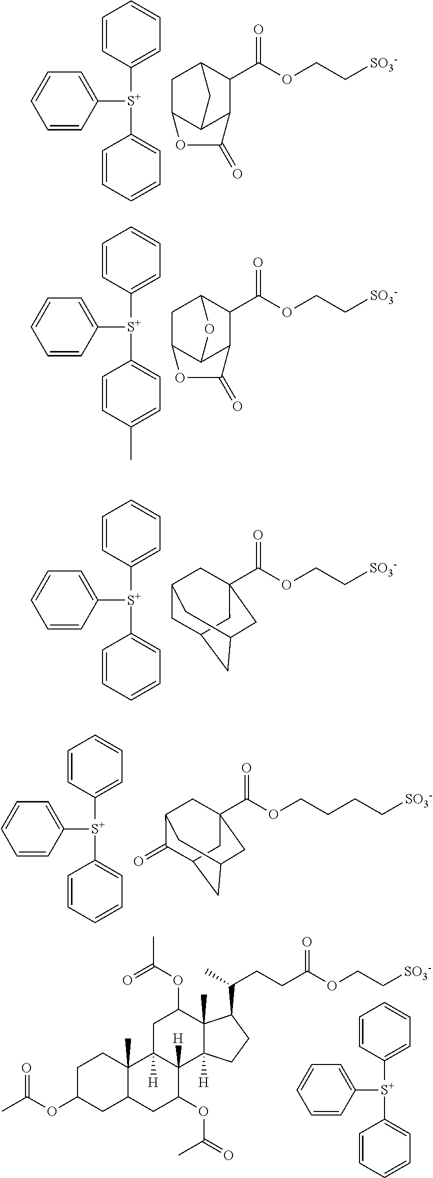

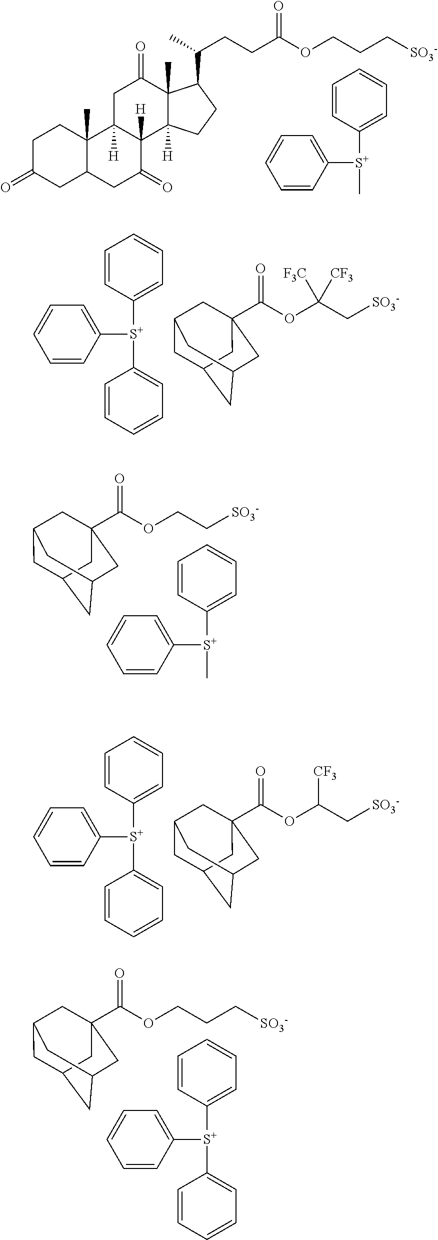

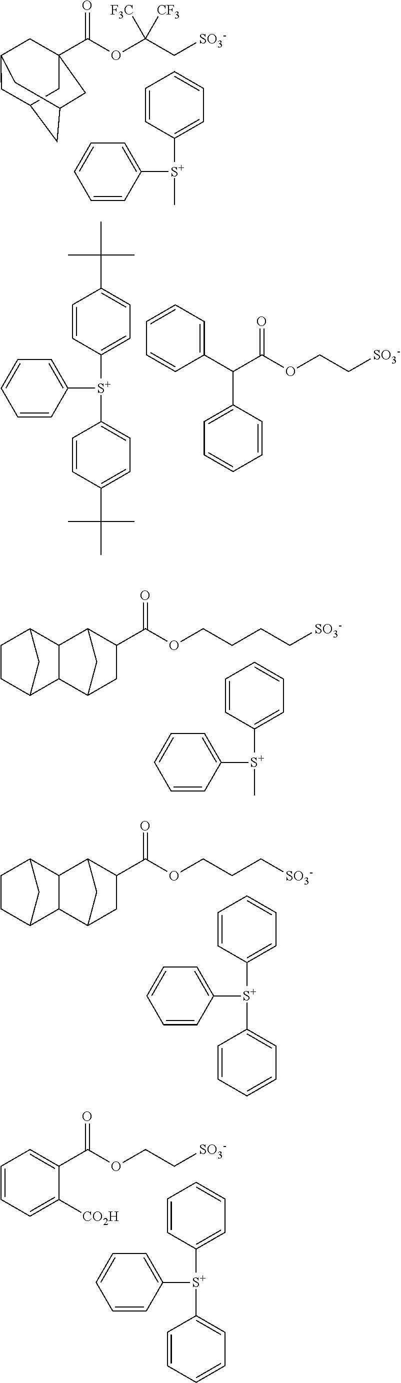

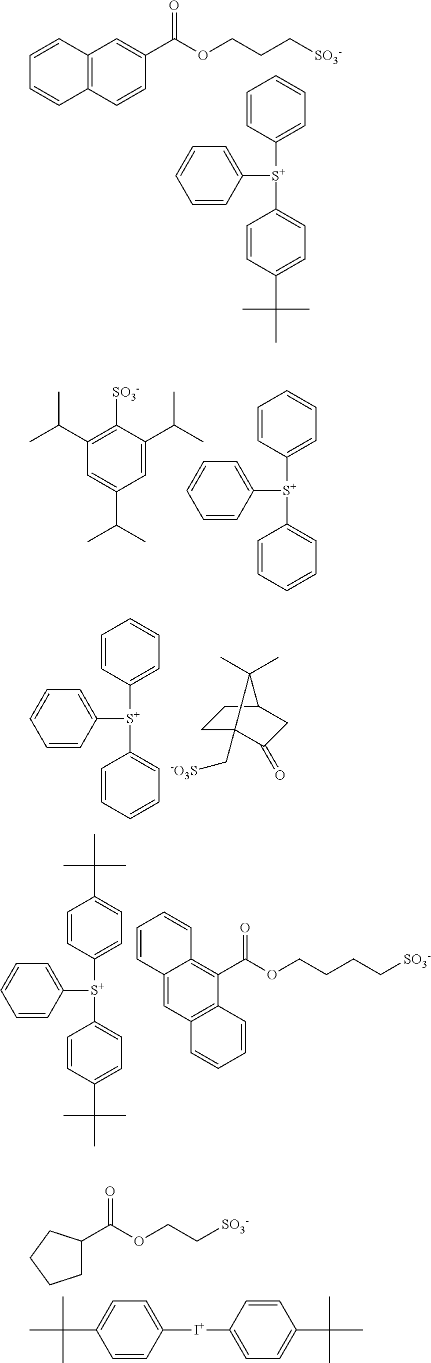

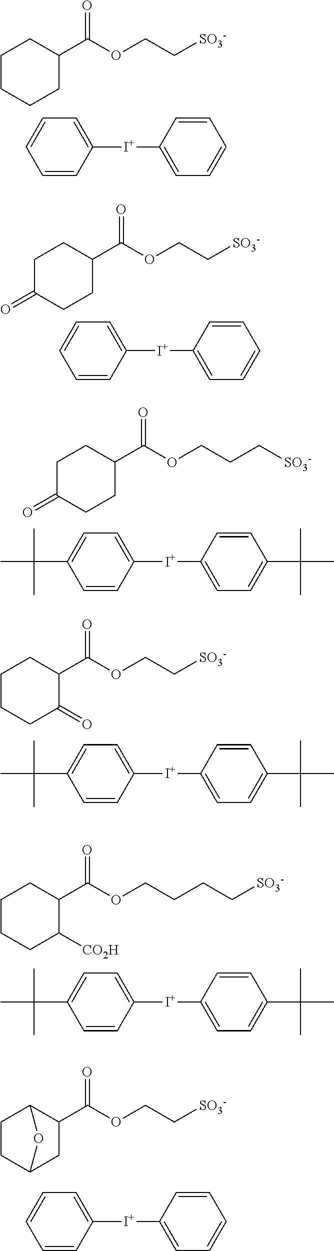

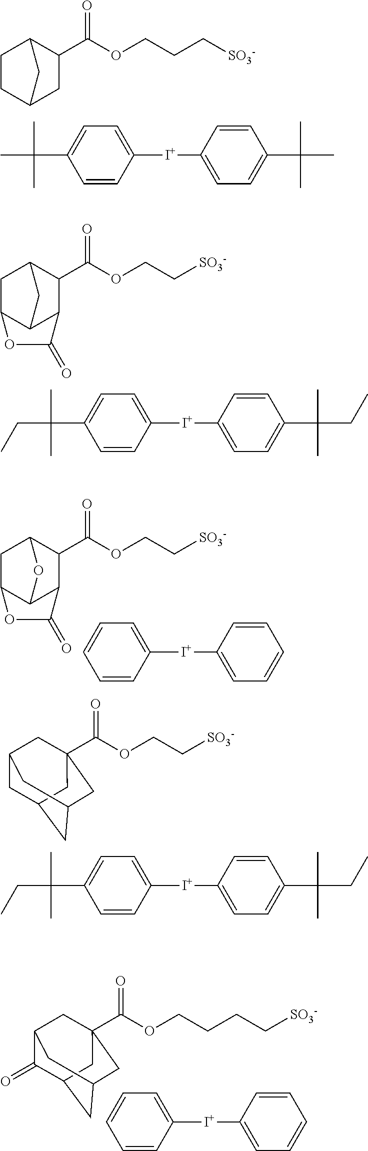

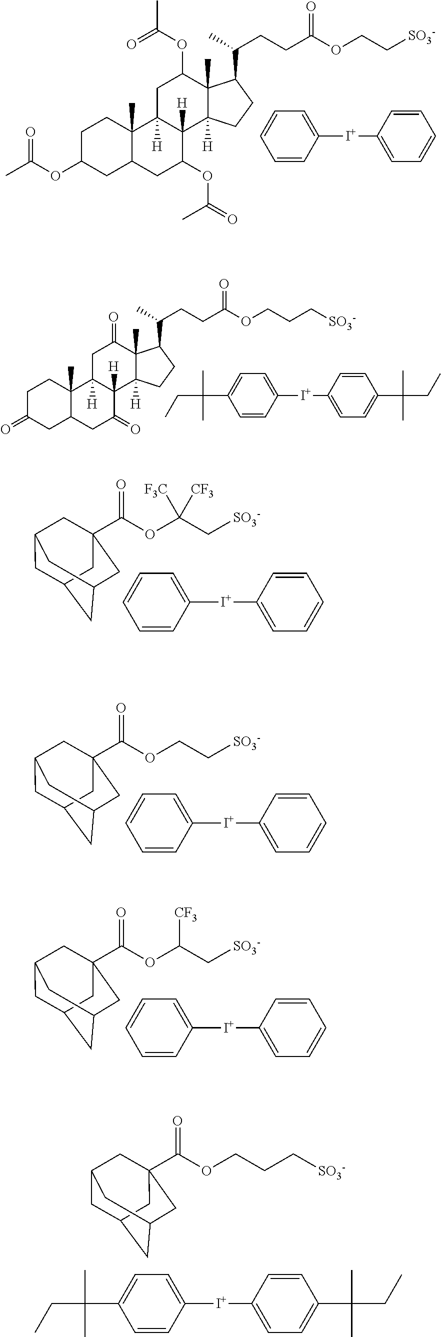

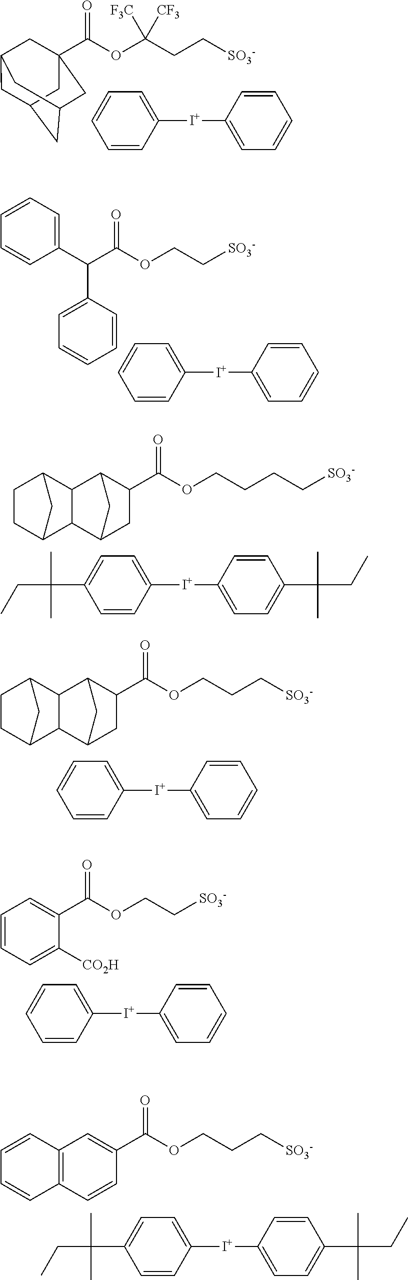

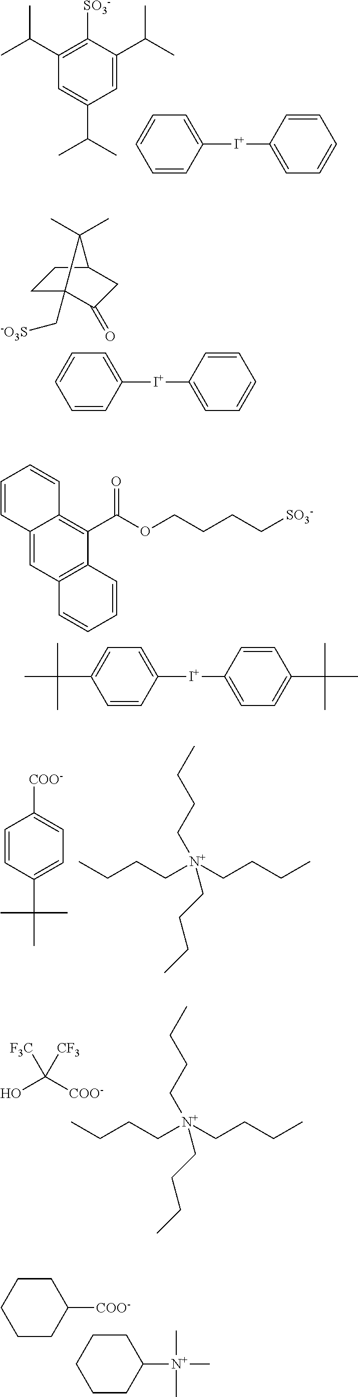

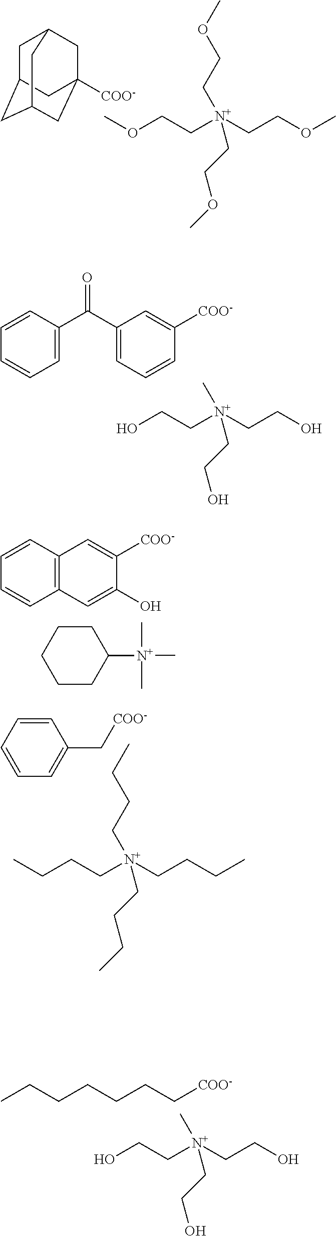

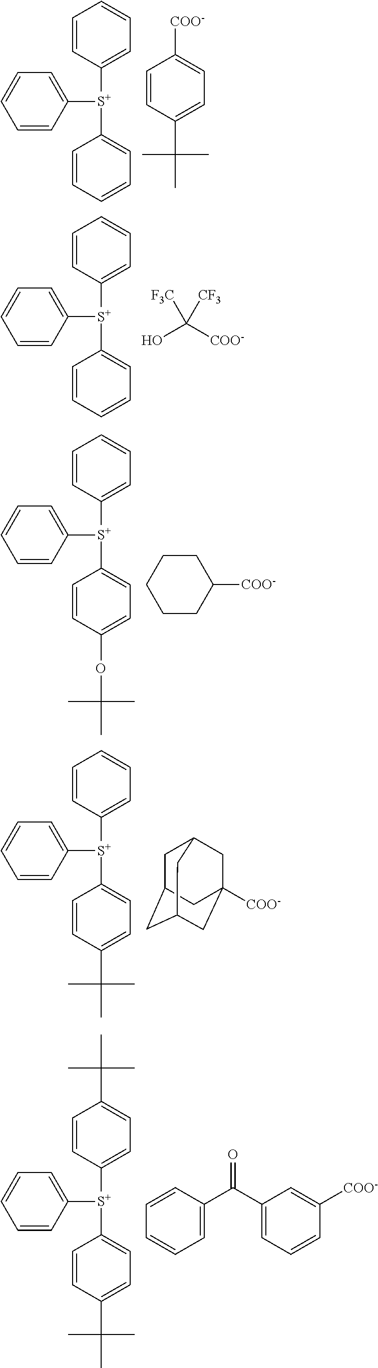

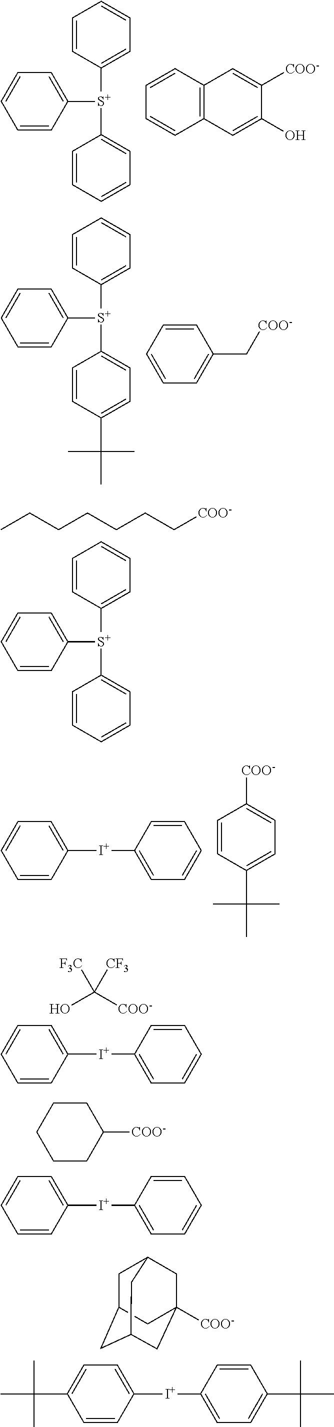

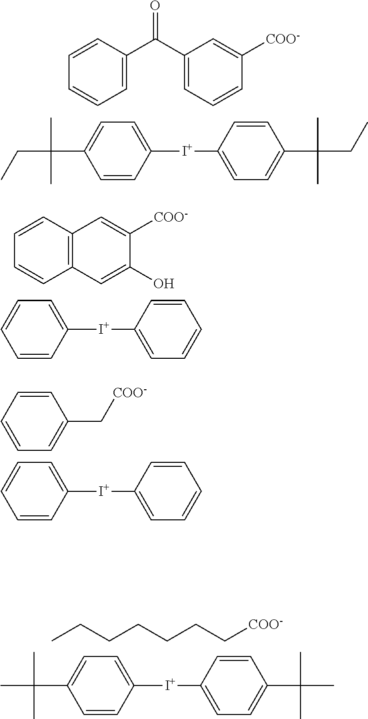

An appropriate amount of the onium salt (D) is 0.5 to 15 parts by weight per 100 parts by weight of the polymer or base resin (A).

Optionally a basic compound may be added to the resist composition. The basic compound is preferably a compound capable of suppressing the rate of diffusion when the acid generated by the acid generator diffuses within the resist film. The inclusion of basic compound holds down the rate of acid diffusion within the resist film, resulting in better resolution. In addition, it suppresses changes in sensitivity following exposure and reduces substrate and environment dependence, as well as improving the exposure latitude and the pattern profile.

Examples of suitable basic compounds include primary, secondary, and tertiary amine compounds, specifically amine compounds having a hydroxyl, ether, ester, lactone ring, cyano or sulfonic acid ester group as described in JP-A 2008-111103, paragraphs [0146] to [0164] (U.S. Pat. No. 7,537,880), and compounds having a carbamate group as described in JP-A 2001-166476. An appropriate amount of the basic compound added is 0 to 3 parts by weight per 100 parts by weight of the polymer (A).

Further the positive resist composition essentially comprises (C) an organic solvent. The organic solvent (C) used herein may be any organic solvent in which the polymer (A), PAG (B), and other components are soluble. Illustrative, non-limiting, examples of the organic solvent include ketones such as cyclohexanone and methyl-2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone. These solvents may be used alone or in combinations of two or more. Of the above organic solvents, it is recommended to use diethylene glycol dimethyl ether, 1-ethoxy-2-propanol, PGMEA, and mixtures thereof because the acid generator is most soluble therein.

An appropriate amount of the organic solvent used is 200 to 4,000 parts, especially 400 to 3,000 parts by weight per 100 parts by weight of the base resin (polymer (A) plus optional other polymer).

Optionally, the resist composition may further comprise a surfactant and/or a dissolution regulator. Suitable surfactants are exemplified in JP-A 2008-111103, paragraphs [0165] to [0166] (U.S. Pat. No. 7,537,880), and suitable dissolution regulators described in JP-A 2008-122932, paragraphs [0155] to [0178] (US 20080090172). An appropriate amount of the surfactant used is 0.0001 to 10 parts by weight, and an appropriate amount of the dissolution regulator used is 0 to 40 parts by weight, per 100 parts by weight of the base resin.

### Process

A second embodiment is a pattern forming process using the resist composition described above. Pattern formation using the resist composition of the invention may be performed by well-known lithography processes. The process generally involves coating, prebaking, exposure, optional PEB, and development. If necessary, any additional steps may be added.

First the resist composition is applied onto a substrate for integrated circuitry fabrication (e.g., Si, SiO₂, SiN, SiON, TiN, WSi, BPSG, SOG, organic antireflective film, etc.) or a substrate for mask circuitry fabrication (e.g., Cr, CrO, CrON, MoSi, etc.) by a suitable coating technique such as spin coating. The coating is prebaked on a hot plate at a temperature of 60 to 150° C. for 1 to 10 minutes, preferably 80 to 140° C. for 1 to 5 minutes. The resulting resist film is generally 0.05 to 2.0 μm thick. Through a photomask having a desired pattern disposed over the substrate, the resist film is then exposed to high-energy radiation such as deep-UV, excimer laser or x-ray, or electron beam in an exposure dose preferably in the range of 1 to 200 mJ/cm², more preferably 10 to 100 mJ/cm². Alternatively, pattern formation may be performed by writing with an electron beam directly (not through a mask). Light exposure may be done by a conventional lithography process or in some cases, by an immersion lithography process of providing liquid impregnation, typically water, between the projection lens and the resist film. In the case of immersion lithography, a protective film which is insoluble in water may be used. The resist film is then baked (PEB) on a hot plate at 60 to 150° C. for 1 to 5 minutes, and preferably at 80 to 140° C. for 1 to 3 minutes. Finally, development is carried out using as the developer an aqueous alkaline solution, such as a 0.1 to 5 wt %, preferably 2 to 3 wt %, aqueous solution of tetramethylammonium hydroxide (TMAH), this being done by a conventional method such as dip, puddle, or spray development for a period of 0.1 to 3 minutes, and preferably 0.5 to 2 minutes. In this way the desired pattern is formed on the substrate. Of the various types of high-energy radiation that may be used, the resist composition of the invention is best suited to fine pattern formation with, in particular, deep-UV or excimer laser having a wavelength of 250 to 180 nm, x-ray, or electron beam. The desired pattern may not be obtainable outside the upper and lower limits of the above range.

The water-insoluble protective film which is used in the immersion lithography is to prevent the resist film from being leached and to improve water slippage at the film surface and is generally divided into two types. The first type is an organic solvent-strippable protective coating which must be stripped, prior to alkaline development, with an organic solvent in which the resist film is not dissolvable. The second type is an alkali-soluble protective coating which is soluble in an alkaline developer so that it can be removed simultaneously with the removal of solubilized areas of the resist film. The protective coating of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a solution, from which the protective film of the second type is formed.

The pattern forming process may involve any additional steps. For example, after formation of the resist film, deionized water rinsing (or post-soaking) may be carried out for extracting the acid generator and the like from the film surface or washing away particles, or after exposure, rinsing (or post-soaking) may be carried out for removing water droplets left on the resist film after exposure.

In the case of the immersion lithography involving holding water between the projection lens and the resist film, a polymeric additive which is effective for making the surface of coated resist more water repellent may be added to the resist composition. This water repellency enhancer may be used in the topcoatless immersion lithography. Typical water repellency enhancers have a unique structure, 1,1,1,3,3,3-hexafluoro-2-propanol residue, as exemplified in JP-A 2007-297590, JP-A 2008-111103, and JP-A 2008-122932.

### Example

Examples and Comparative Examples are given below by way of illustration and not by way of limitation. Weight average molecular weight (Mw) and number average molecular weight (Mn) are measured by gel permeation chromatography (GPC), and a dispersity (Mw/Mn) is computed therefrom. All parts are by weight (pbw). Me stands for methyl.

### Examples and Comparative Examples

### Polymers' Molar Fraction, Mw, and Mw/Mn

A series of polymers were used as component (A) in positive resist compositions. The molar fraction (MF, mol %) of recurring units of which each polymer is composed is reported in Table 1 together with its Mw and dispersity (Mw/Mn). The structure of each recurring unit is shown in Tables 2 to 5. ALU-1 to ALU-12 in Table 2 designate essential recurring units (a1) having an acid labile group. Unit-1 to Unit-11 in Table 3 designate essential recurring units (a2) having a cyclic hydrocarbon group containing an ester, ether, carbonate or sulfonate radical within the ring. Unit-12 to Unit-17 in Table 4 designate recurring units having a hydroxyl group. Unit-18 to Unit-21 in Table 5 designate essential recurring units (a3) having an oxirane ring. Unit 22 and Unit 23 in Table 5 designate sulfonium units (a4). Polymer-1 to Polymer-39 fall within the scope of the invention whereas Polymer-40 to Polymer-43 are comparative polymers.

TABLE 1

| | | Unit 1 | MF | Unit 2 | MF | Unit 3 | MF | Unit 4 | MF | Unit 5 | MF | Unit 6 | MF | Mw | Mw/Mn |
|---|---|---|---|---|---|---|---|---|---|---|---|---|---|---|---|
| Polymer | 1 | ALU-1 | 50 | Unit-9 | 45 | Unit-18 | 5 | | | | | | | 8,300 | 1.70 |
| | 2 | ALU-1 | 50 | Unit-10 | 45 | Unit-18 | 5 | | | | | | | 8,200 | 1.88 |
| | 3 | ALU-1 | 50 | Unit-10 | 45 | Unit-19 | 5 | | | | | | | 8,150 | 1.80 |
| | 4 | ALU-2 | 50 | Unit-3 | 45 | Unit-19 | 5 | | | | | | | 8,220 | 1.75 |
| | 5 | ALU-3 | 50 | Unit-11 | 45 | Unit-19 | 5 | | | | | | | 8,300 | 1.66 |
| | 6 | ALU-5 | 50 | Unit-6 | 45 | Unit-19 | 5 | | | | | | | 7,610 | 1.75 |
| | 7 | ALU-6 | 50 | Unit-6 | 45 | Unit-19 | 5 | | | | | | | 7,700 | 1.93 |
| | 8 | ALU-7 | 50 | Unit-6 | 45 | Unit-19 | 5 | | | | | | | 8,140 | 1.71 |
| | 9 | ALU-8 | 50 | Unit-6 | 45 | Unit-19 | 5 | | | | | | | 8,500 | 2.10 |
| | 10 | ALU-9 | 50 | Unit-6 | 45 | Unit-19 | 5 | | | | | | | 8,550 | 1.60 |
| | 11 | ALU-9 | 50 | Unit-7 | 45 | Unit-19 | 5 | | | | | | | 6,960 | 1.77 |
| | 12 | ALU-9 | 50 | Unit-4 | 45 | Unit-19 | 5 | | | | | | | 7,520 | 1.65 |
| | 13 | ALU-9 | 50 | Unit-5 | 45 | Unit-19 | 5 | | | | | | | 8,800 | 1.72 |
| | 14 | ALU-9 | 50 | Unit-5 | 45 | Unit-20 | 5 | | | | | | | 7,980 | 1.66 |
| | 15 | ALU-9 | 50 | Unit-8 | 45 | Unit-19 | 5 | | | | | | | 8,100 | 1.90 |
| | 16 | ALU-4 | 50 | Unit-9 | 45 | Unit-19 | 5 | | | | | | | 7,780 | 1.71 |
| | 17 | ALU-4 | 50 | Unit-9 | 35 | Unit-19 | 15 | | | | | | | 8,100 | 1.88 |
| | 18 | ALU-4 | 50 | Unit-11 | 45 | Unit-19 | 5 | | | | | | | 8,230 | 1.79 |
| | 19 | ALU-4 | 50 | Unit-1 | 45 | Unit-19 | 5 | | | | | | | 7,170 | 1.75 |
| | 20 | ALU-4 | 50 | Unit-2 | 45 | Unit-19 | 5 | | | | | | | 8,190 | 1.90 |
| | 21 | ALU-4 | 25 | Unit-2 | 70 | Unit-19 | 5 | | | | | | | 6,830 | 1.80 |
| | 22 | ALU-1 | 10 | ALU-5 | 40 | Unit-6 | 25 | Unit-9 | 20 | Unit-19 | 5 | | | 7,700 | 1.76 |
| | 23 | ALU-1 | 10 | ALU-4 | 40 | Unit-6 | 25 | Unit-9 | 20 | Unit-20 | 5 | | | 8,220 | 1.69 |
| | 24 | ALU-1 | 10 | ALU-4 | 40 | Unit-6 | 25 | Unit-9 | 20 | Unit-21 | 5 | | | 8,300 | 1.72 |
| | 25 | ALU-10 | 10 | ALU-4 | 40 | Unit-6 | 25 | Unit-9 | 20 | Unit-20 | 5 | | | 7,440 | 1.80 |
| | 26 | ALU-11 | 10 | ALU-4 | 40 | Unit-6 | 25 | Unit-9 | 20 | Unit-20 | 5 | | | 8,540 | 1.74 |
| | 27 | ALU-1 | 10 | ALU-7 | 40 | Unit-6 | 25 | Unit-9 | 20 | Unit-20 | 5 | | | 8,600 | 1.68 |
| | 28 | ALU-1 | 10 | ALU-7 | 40 | Unit-6 | 25 | Unit-11 | 20 | Unit-20 | 5 | | | 9,200 | 1.78 |
| | 29 | ALU-1 | 5 | ALU-7 | 55 | Unit-6 | 20 | Unit-11 | 15 | Unit-20 | 5 | | | 7,680 | 1.61 |
| | 30 | ALU-9 | 5 | ALU-7 | 55 | Unit-6 | 20 | Unit-11 | 15 | Unit-20 | 5 | | | 8,270 | 1.92 |
| | 31 | ALU-9 | 5 | ALU-12 | 55 | Unit-6 | 20 | Unit-11 | 15 | Unit-19 | 5 | | | 8,390 | 1.83 |
| | 32 | Unit-22 | 5 | ALU-9 | 5 | ALU-12 | 55 | Unit-6 | 20 | Unit-11 | 10 | Unit-19 | 5 | 8,100 | 1.83 |
| | 33 | Unit-23 | 5 | ALU-9 | 5 | ALU-12 | 55 | Unit-6 | 20 | Unit-11 | 10 | Unit-19 | 5 | 7,700 | 1.83 |
| | 34 | ALU-1 | 10 | ALU-4 | 40 | Unit-12 | 10 | Unit-6 | 20 | Unit-9 | 15 | Unit-21 | 5 | 9,250 | 1.90 |
| | 35 | ALU-1 | 10 | ALU-4 | 40 | Unit-13 | 10 | Unit-6 | 20 | Unit-9 | 15 | Unit-21 | 5 | 6,220 | 1.65 |
| | 36 | ALU-1 | 10 | ALU-4 | 40 | Unit-6 | 20 | Unit-11 | 20 | Unit-14 | 5 | Unit-21 | 5 | 6,650 | 1.67 |
| | 37 | ALU-1 | 10 | ALU-4 | 40 | Unit-6 | 20 | Unit-11 | 20 | Unit-15 | 5 | Unit-21 | 5 | 7,820 | 1.78 |
| | 38 | ALU-1 | 10 | ALU-4 | 40 | Unit-6 | 20 | Unit-11 | 20 | Unit-16 | 5 | Unit-21 | 5 | 8,360 | 1.80 |
| | 39 | ALU-1 | 10 | ALU-4 | 40 | Unit-6 | 20 | Unit-11 | 20 | Unit-17 | 5 | Unit-21 | 5 | 8,100 | 1.67 |
| | 40 | ALU-5 | 70 | Unit-6 | 30 | | | | | | | | | 8,450 | 1.74 |
| | 41 | ALU-5 | 70 | Unit-12 | 20 | Unit-20 | 10 | | | | | | | 8,200 | 1.82 |
| | 42 | Unit-22 | 5 | ALU-5 | 70 | Unit-6 | 25 | | | | | | | 8,550 | 1.70 |
| | 43 | Unit-22 | 5 | ALU-5 | 70 | Unit-12 | 15 | Unit-20 | 10 | | | | | 7,900 | 1.69 |

TABLE 2
ALU-1

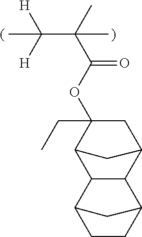 [SMILES: CCC(C)(C)C(=O)OC1(CC)CC2CC1C1C3CCC(C3)C21]

ALU-2

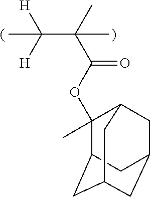 [SMILES: CCC(C)(C)C(=O)OC1(C)C2CC3CC(C2)CC1C3]

ALU-3

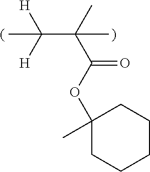

ALU-4

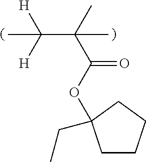

ALU-5

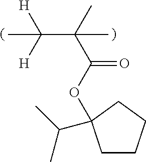 [SMILES: CCC(C)(C)C(=O)OC1(C(C)C)CCCC1]

ALU-6

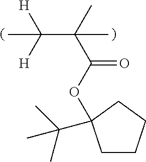 [SMILES: CCC(C)(C)C(=O)OC1(C(C)(C)C)CCCC1]

ALU-7

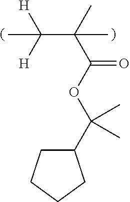 [SMILES: CCC(C)(C)C(=O)OC(C)(C)C1CCCC1]

ALU-8

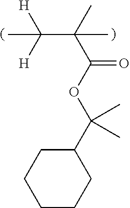 [SMILES: CCC(C)(C)C(=O)OC(C)(C)C1CCCCC1]

ALU-9

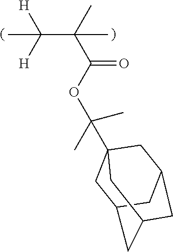 [SMILES: CCC(C)(C)C(=O)OC(C)(C)C12CC3CC(CC(C3)C1)C2]

ALU-10

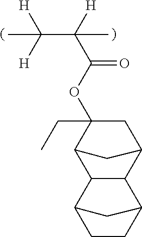 [SMILES: CCC(C)C(=O)OC1(CC)CC2CC1C1C3CCC(C3)C21]

ALU-11

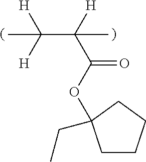

ALU-12

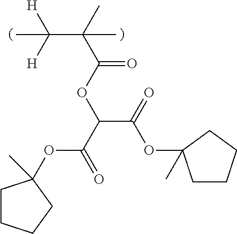 [SMILES: CCC(C)(C)C(=O)OC(C(=O)OC1(C)CCCC1)C(=O)OC1(C)CCCC1]

TABLE 3
Unit-1

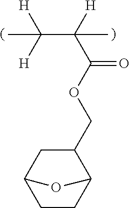

Unit-2

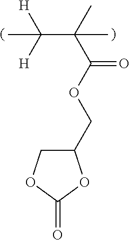

Unit-3

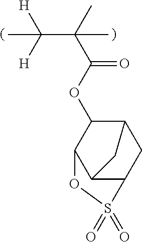 [SMILES: CCC(C)(C)C(=O)OC1C2CC3C1OS(=O)(=O)C3C2]

Unit-4

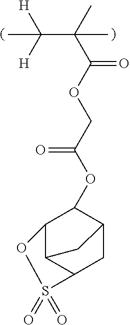 [SMILES: CCC(C)(C)C(=O)OCC(=O)OC1C2CC3C1OS(=O)(=O)C3C2]

Unit-5

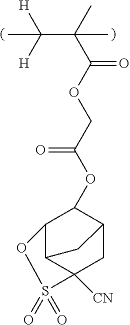 [SMILES: CCC(C)(C)C(=O)OCC(=O)OC1C2CC3C1OS(=O)(=O)C3(C#N)C2]

Unit-6

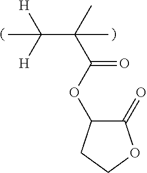

Unit-7

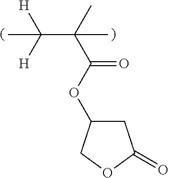

Unit-8

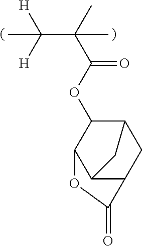 [SMILES: CCC(C)(C)C(=O)OC1C2CC3C(=O)OC1C3C2]

Unit-9

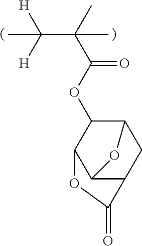 [SMILES: CCC(C)(C)C(=O)OC1C2CC3C(=O)OC1C3O2]

Unit-10

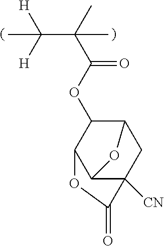 [SMILES: CCC(C)(C)C(=O)OC1C2CC3(C#N)C(=O)OC1C3O2]

Unit-11

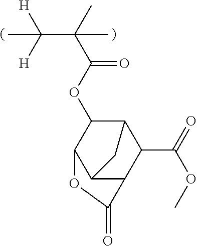 [SMILES: CCC(C)(C)C(=O)OC1C2CC3C1OC(=O)C3C2C(=O)OC]

TABLE 4
Unit-12

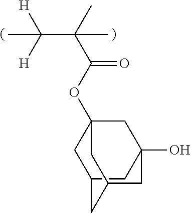 [SMILES: CCC(C)(C)C(=O)OC12CC3CC(CC(O)(C3)C1)C2]

Unit-13

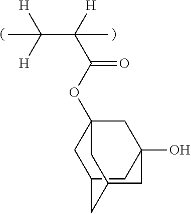 [SMILES: CCC(C)C(=O)OC12CC3CC(CC(O)(C3)C1)C2]

Unit-14

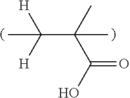

Unit-15

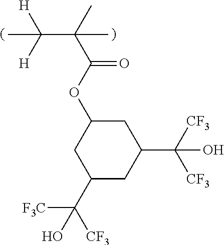 [SMILES: CCC(C)(C)C(=O)OC1CC(C(O)(C(F)(F)F)C(F)(F)F)CC(C(O)(C(F)(F)F)C(F)(F)F)C1]

Unit-16

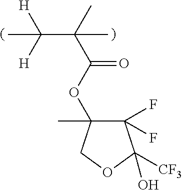 [SMILES: CCC(C)(C)C(=O)OC1(C)COC(O)(C(F)(F)F)C1(F)F]

Unit-17

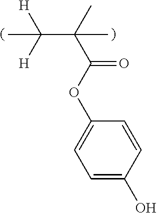

TABLE 5
Unit-18

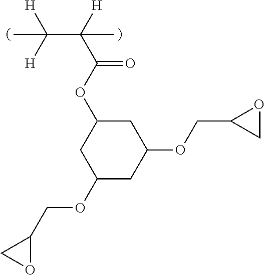 [SMILES: CCC(C)C(=O)OC1CC(OCC2CO2)CC(OCC2CO2)C1]

Unit-19

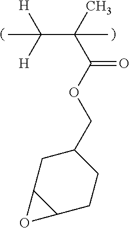 [SMILES: CCC(C)(C)C(=O)OCC1CCC2OC2C1]

Unit-20

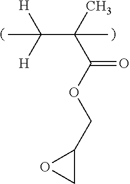

Unit-21

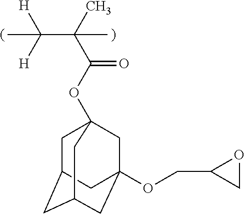 [SMILES: CCC(C)(C)C(=O)OC12CC3CC(CC(OCC4CO4)(C3)C1)C2]

Unit-22

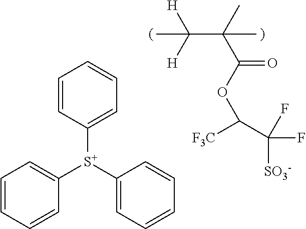

Unit-23

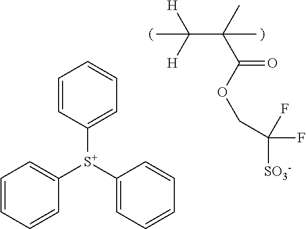

### Preparation of Resist Compositions

Resist compositions as formulated in Tables 6 and 7 were prepared by dissolving the polymer, PAG and quencher in a solvent, and filtering through a Teflon® filter having a pore size of 0.2 μm. Comparative Resist compositions as formulated in Table 8 were similarly prepared. The PAGs in Tables 6 to 8 have the structure shown in Table 9; the onium salts have the structure shown in Table 10; and the basic compounds A1 to A4 as the quencher have the structure shown in Table 11. PAG-1 to PAG-8 in Table 9 correspond to the photoacid generator (B) which is essential in the inventive resist composition. Salt-1 to Salt-13 in Table 10 correspond to the onium salt (D) which is optional in the inventive resist composition.

TABLE 6

| | | | Polymer | PAG | Onium salt | Basic compound | Solvent |
|---|---|---|---|---|---|---|---|
| | | Resist | (pbw) | (pbw) | (pbw) | (pbw) | (pbw) |
| Example | 1 | PR-1 | Polymer-1(80) | PAG-1(8.7) | Salt-1(2.6) | | PGMEA(2,700) |
| | | | | | | | GBL(300) |
| | 2 | PR-2 | Polymer-2(80) | PAG-2(5.5) | Salt-2(3.8) | | PGMEA(2,700) |
| | | | | | | | GBL(300) |
| | 3 | PR-3 | Polymer-3(80) | PAG-3(5.9) | Salt-3(5.1) | | PGMEA(2,700) |
| | | | | | | | GBL(300) |
| | 4 | PR-4 | Polymer-3(80) | PAG-4(10.1) | Salt-4(1.9) | | PGMEA(2,700) |
| | | | | | | | GBL(300) |
| | 5 | PR-5 | Polymer-4(80) | PAG-5(6.4) | Salt-5(4.0) | | PGMEA(2,700) |
| | | | | | | | GBL(300) |
| | 6 | PR-6 | Polymer-5(80) | PAG-4(7.6) | Salt-6(3.4) | | PGMEA(2,700) |
| | | | | | | | GBL(300) |
| | 7 | PR-7 | Polymer-6(80) | PAG-5(6.4) | Salt-7(3.9) | | PGMEA(2,700) |
| | | | | | | | GBL(300) |
| | 8 | PR-8 | Polymer-7(80) | PAG-4(7.6) | Salt-8(4.3) | | PGMEA(2,700) |
| | | | | | | | GBL(300) |
| | 9 | PR-9 | Polymer-8(80) | PAG-6(7.6) | Salt-8(4.3) | | PGMEA(2,700) |
| | | | | | | | GBL(300) |
| | 10 | PR-10 | Polymer-9(80) | PAG-4(7.6) | Salt-8(4.3) | | PGMEA(2,700) |
| | | | | | | | GBL(300) |
| | 11 | PR-11 | Polymer-10(80) | PAG-7(9.7) | | A-2(0.9) | PGMEA(2,700) |
| | | | | | | | GBL(300) |
| | 12 | PR-12 | Polymer-11(80) | PAG-8(10.6) | | A-4(1.0) | PGMEA(2,700) |
| | | | | | | | GBL(300) |
| | 13 | PR-13 | Polymer-12(80) | PAG-7(9.7) | | A-2(0.9) | PGMEA(2,700) |
| | | | | | | | GBL(300) |
| | 14 | PR-14 | Polymer-13(80) | PAG-7(9.7) | | A-2(0.9) | PGMEA(2,700) |
| | | | | | | | GBL(300) |
| | 15 | PR-15 | Polymer-14(80) | PAG-7(9.7) | | A-2(0.9) | PGMEA(2,700) |
| | | | | | | | GBL(300) |
| | 16 | PR-16 | Polymer-15(80) | PAG-7(9.7) | | A-2(0.9) | PGMEA(2,700) |
| | | | | | | | GBL(300) |
| | 17 | PR-17 | Polymer-16(80) | PAG-4(7.6) | Salt-7(3.9) | A-2(0.3) | PGMEA(2,700) |
| | | | | | | | GBL(300) |
| | 18 | PR-18 | Polymer-17(80) | PAG-4(7.6) | Salt-7(3.9) | A-2(0.3) | PGMEA(2,700) |
| | | | | | | | GBL(300) |
| | 19 | PR-19 | Polymer-18(80) | PAG-5(8.5) | | A-1(1.5) | PGMEA(2,700) |
| | | | | | | | GBL(300) |
| | 20 | PR-20 | Polymer-19(80) | PAG-4(7.6) | Salt-9(5.3) | | PGMEA(2,700) |
| | | | | | | | GBL(300) |
| | 21 | PR-21 | Polymer-20(80) | PAG-4(10.1) | Salt-10(2.7) | | PGMEA(2,700) |
| | | | | | | | GBL(300) |
| | 22 | PR-22 | Polymer-21(80) | PAG-4(10.1) | Salt-10(2.7) | | PGMEA(2,700) |
| | | | | | | | GBL(300) |
| | 23 | PR-23 | Polymer-22(80) | PAG-6(7.6) | Salt-11(3.5) | | PGMEA(2,700) |
| | | | | | | | GBL(300) |
| | 24 | PR-24 | Polymer-23(80) | PAG-6(7.6) | Salt-11(3.5) | | PGMEA(2,700) |
| | | | | | | | GBL(300) |
| | 25 | PR-25 | Polymer-24(80) | PAG-6(7.6) | Salt-11(3.5) | | PGMEA(2,700) |
| | | | | | | | GBL(300) |
| | 26 | PR-26 | Polymer-25(80) | PAG-1(6.5) | Salt-11(3.5) | | PGMEA(2,700) |
| | | | | | | | GBL(300) |
| | 27 | PR-27 | Polymer-26(80) | PAG-7(9.7) | | A-3(1.2) | PGMEA(2,700) |
| | | | | | | | GBL(300) |
| | 28 | PR-28 | Polymer-27(80) | PAG-4(7.6) | Salt-13(3.7) | | PGMEA(2,700) |
| | | | | | | | GBL(300) |
| | 29 | PR-29 | Polymer-28(80) | PAG-4(7.6) | Salt-12(3.1) | | PGMEA(2,700) |
| | | | | | | | GBL(300) |
| | 30 | PR-30 | Polymer-29(80) | PAG-4(7.6) | Salt-8(4.3) | | PGMEA(2,700) |
| | | | | | | | GBL(300) |

TABLE 7

| | | | Polymer | PAG | Onium salt | Basic compound | Solvent |
|---|---|---|---|---|---|---|---|
| | | Resist | (pbw) | (pbw) | (pbw) | (pbw) | (pbw) |
| Example | 31 | PR-31 | Polymer-29(80) | PAG-40(3.8) | Salt-8(4.3) | | PGMEA(2,700) |
| | | | | PAG-5(3.2) | | | GBL(300) |
| | 32 | PR-32 | Polymer-30(80) | PAG-4(7.6) | Salt-8(4.3) | | PGMEA(2,700) |
| | | | | | | | GBL(300) |
| | 33 | PR-33 | Polymer-30(80) | PAG-2(5.5) | Salt-8(4.3) | | PGMEA(2,700) |
| | | | | | | | GBL(300) |
| | 34 | PR-34 | Polymer-31(80) | PAG-4(7.6) | Salt-8(4.3) | | PGMEA(2,700) |
| | | | | | | | GBL(300) |
| | 35 | PR-35 | Polymer-32(80) | PAG-4(7.6) | Salt-8(4.3) | | PGMEA(2,700) |
| | | | | | | | GBL(300) |
| | 36 | PR-36 | Polymer-33(80) | PAG-4(7.6) | Salt-8(4.3) | | PGMEA(2,700) |
| | | | | | | | GBL(300) |
| | 37 | PR-37 | Polymer-34(80) | PAG-2(5.5) | Salt-2(3.8) | | PGMEA(2,700) |
| | | | | | | | GBL(300) |
| | 38 | PR-38 | Polymer-35(80) | PAG-7(7.2) | Salt-8(4.3) | | PGMEA(2,700) |
| | | | | | | | GBL(300) |
| | 39 | PR-39 | Polymer-36(80) | PAG-8(7.9) | Salt-7(3.9) | | PGMEA(2,700) |
| | | | | | | | GBL(300) |
| | 40 | PR-40 | Polymer-37(80) | PAG-8(7.9) | Salt-7(3.9) | | PGMEA(2,700) |
| | | | | | | | GBL(300) |
| | 41 | PR-41 | Polymer-38(80) | PAG-8(7.9) | Salt-7(3.9) | | PGMEA(2,700) |
| | | | | | | | GBL(300) |
| | 42 | PR-42 | Polymer-39(80) | PAG-8(7.9) | Salt-7(3.9) | | PGMEA(2,700) |
| | | | | | | | GBL(300) |
| | 43 | PR-43 | Polymer-39(80) | PAG-8(7.9) | | A-1(1.5) | PGMEA(2,700) |
| | | | | | | | GBL(300) |
| | 44 | PR-44 | Polymer-39(80) | PAG-8(7.9) | | A-3(1.2) | PGMEA(2,700) |
| | | | | | | | GBL(300) |
| | 45 | PR-45 | Polymer-39(80) | PAG-8(7.9) | Salt-9(5.3) | A-2(0.3) | PGMEA(2,700) |
| | | | | | | | GBL(300) |

TABLE 8

| | | | Polymer | PAG | Onium salt | Basic compound | Solvent |
|---|---|---|---|---|---|---|---|
| | | Resist | (pbw) | (pbw) | (pbw) | (pbw) | (pbw) |
| Comparative | 1 | PR-46 | Polymer-40(80) | PAG-4(7.6) | Salt-7(3.9) | | PGMEA(2,700) |
| Example | | | | | | | GBL(300) |
| | 2 | PR-47 | Polymer-41(80) | PAG-4(7.6) | Salt-7(3.9) | | PGMEA(2,700) |
| | | | | | | | GBL(300) |
| | 3 | PR-48 | Polymer-42(80) | PAG-4(10.1) | | A-1(1.5) | PGMEA(2,700) |
| | | | | | | | GBL(300) |
| | 4 | PR-49 | Polymer-43(80) | PAG-4(10.1) | | A-1(1.5) | PGMEA(2,700) |
| | | | | | | | GBL(300) |

TABLE 9
PAG-1

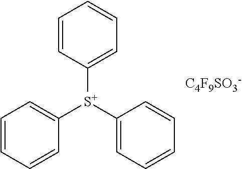

PAG-2

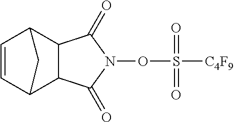

PAG-3

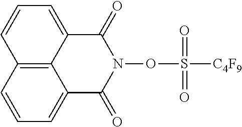

PAG-4

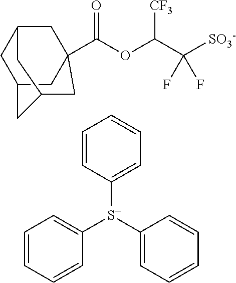

PAG-5

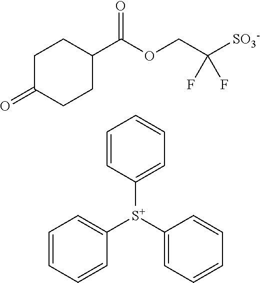

PAG-6

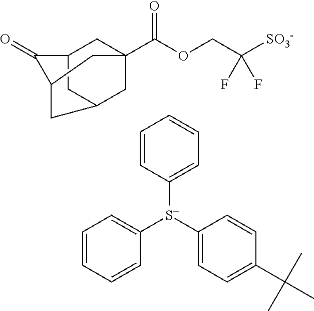

PAG-7

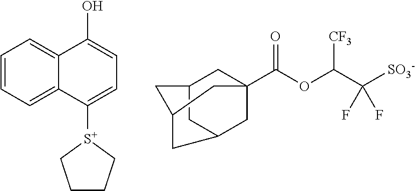

PAG-8

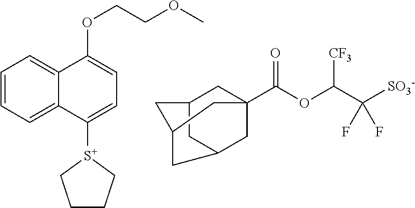

TABLE 10
Salt-1

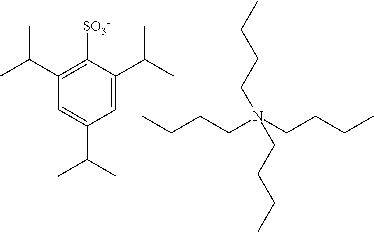

Salt-2

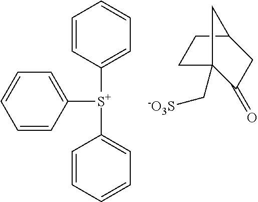

Salt-3

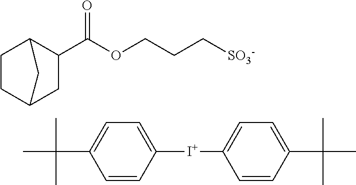

Salt-4

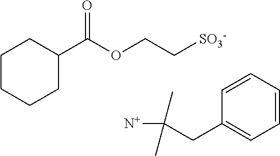

Salt-5

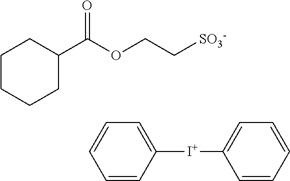

Salt-6

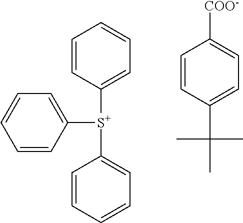

Salt-7

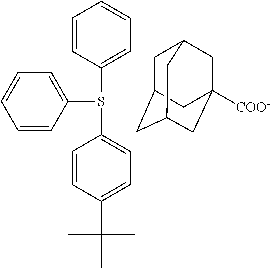

Salt-8

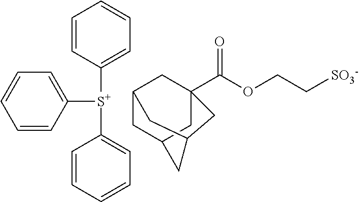

Salt-9

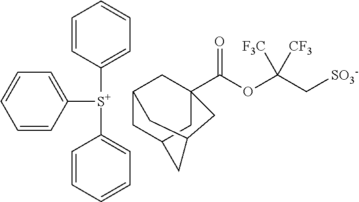

Salt-10

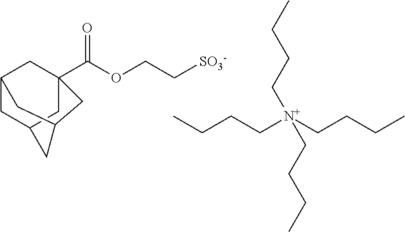

Salt-11

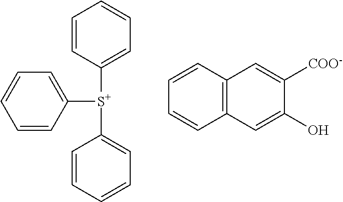

Salt-12

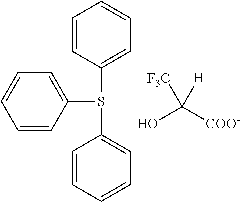

Salt-13

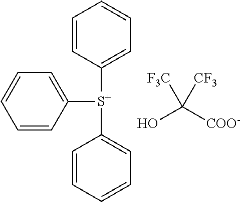

TABLE 11
A-1

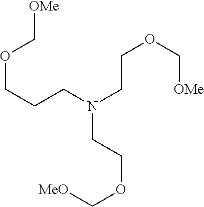 [SMILES: COCOCCCN(CCOCOC)CCOCOC]

A-2

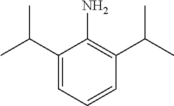

A-3

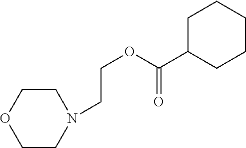 [SMILES: O=C(OCCN1CCOCC1)C1CCCCC1]

A-4

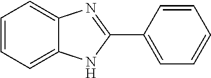 [SMILES: c1ccc(-c2nc3ccccc3[nH]2)cc1]

It is noted that the solvents in Tables 6 to 8 are identified below.

PGMEA: propylene glycol monomethyl ether acetate
GBL: γ-butyrolactone

All the resist compositions in Tables 6 to 8 contained 5.0 parts by weight of an alkali-soluble surfactant SF-1 and 0.1 part by weight of surfactant A, which are identified below.

Alkali-soluble surfactant SF-1:
poly(3,3,3-trifluoro-2-hydroxy-1,1-dimethyl-2-trifluoromethylpropyl methacrylate/1,1,1-trifluoro-2-hydroxy-6-methyl-2-trifluoromethylhept-4-yl methacrylate) (described in JP-A 2008-122932)

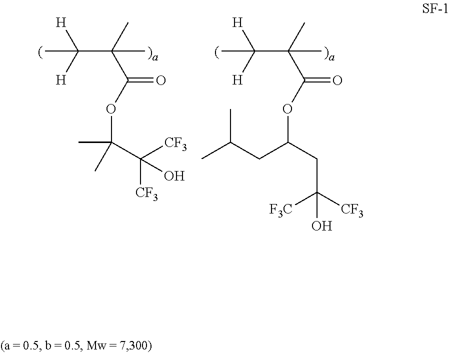

Surfactant A: 3-methyl-3-(2,2,2-trifluoroethoxymethyl)-oxetane/tetrahydrofuran/2,2-dimethyl-1,3-propane diol (Omnova Solutions, Inc.)

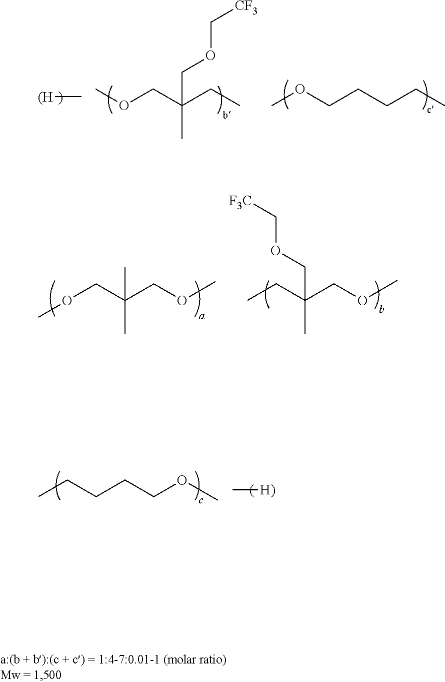

### Test Methods

An antireflective coating solution (ARC-29A by Nissan Chemical Industries Co., Ltd.) was coated onto a silicon substrate and baked at 200° C. for 60 seconds to form an ARC film of 100 nm thick. The resist solution was spin coated onto the ARC film and baked on a hot plate at 100° C. for 60 seconds to form a resist film of 80 nm thick. The resist film was exposed according to the ArF immersion lithography on an ArF excimer laser scanner NSR-S610C (Nikon Corp., NA 1.30, dipole illumination, 6% halftone phase shift mask) using water. The resist film was baked (PEB) at an arbitrary temperature for 60 seconds and developed in a 2.38 wt % aqueous solution of tetramethylammonium hydroxide for 60 seconds.

The resist was evaluated by observing a 40-nm 1:1 line-and-space pattern under an electron microscope. The optimum dose (Eop) was a dose (mJ/cm²) which provided a line width of 40 nm. The profile of a L/S pattern at the optimum dose was compared and evaluated according to the following criterion.
Rectangular: perpendicular line pattern of satisfactory profile
Rounded top: line pattern of unsatisfactory profile having a reduced height due to excess dissolution
Tapered: line pattern of unsatisfactory profile having an increased line size near substrate

The roughness of the sidewall of the line pattern at the optimum dose was determined by computing a variation of line width (measured at 30 points, 3σ value computed), with the data reported as LWR (nm) in Tables 12 to 14.

Patterns having lines of gradually narrowing width were formed by increasing the exposure dose from the optimum dose (Eop). The dose range in which the lines could be resolved without collapse was determined and reported as collapse margin (%), with larger values being better. Computation is according to the following equation.

Collapse margin (%)=(collapse limit dose−Eop)/Eop×100

Exposure was made through a mask having a fixed pitch of 80 nm and a varying line width in a range from 38 nm to 42 nm by an increment of 1 nm, scaled as on-wafer size at the optimum dose. The size of the pattern transferred to the wafer was measured. With respect to the line width, the size of the transferred pattern is plotted relative to the mask design size, and a gradient is computed by linear approximation, and reported as mask error factor (MEF). A smaller MEF value, indicative of reduced influence of a finish error of the mask pattern, is better.

### Test Results

The PEB temperature and evaluation results of the resist compositions in Tables 6 and 7 are tabulated in Tables 12 and 13. The PEB temperature and evaluation results of the comparative resist compositions in Table 8 are tabulated in Table 14.

TABLE 12

| | | | PEB temp. | Eop | | LWR | | Collapse margin |
|---|---|---|---|---|---|---|---|---|
| | | Resist | (° C.) | (mJ/cm²) | Profile | (nm) | MEF | (%) |
| Example | 1 | PR-10 | 105 | 26 | rectangular | 3.2 | 3.15 | 21 |
| | 2 | PR-2 | 105 | 27 | rectangular | 3.2 | 3.2 | 23 |
| | 3 | PR-3 | 95 | 28 | rectangular | 3.5 | 3.03 | 26 |
| | 4 | PR-4 | 95 | 34 | rectangular | 2.8 | 2.77 | 31 |
| | 5 | PR-5 | 110 | 39 | rectangular | 2.9 | 2.81 | 33 |
| | 6 | PR-6 | 100 | 35 | rectangular | 2.6 | 2.78 | 30 |
| | 7 | PR-7 | 90 | 37 | rectangular | 2.8 | 2.7 | 29 |
| | 8 | PR-8 | 90 | 35 | rectangular | 2.1 | 1.91 | 33 |
| | 9 | PR-9 | 105 | 40 | rectangular | 2.2 | 2.23 | 35 |
| | 10 | PR-10 | 105 | 42 | rectangular | 2.0 | 2.35 | 36 |
| | 11 | PR-11 | 115 | 37 | rectangular | 3.4 | 3.1 | 32 |
| | 12 | PR-12 | 110 | 38 | rectangular | 3.3 | 3.05 | 31 |
| | 13 | PR-13 | 105 | 37 | rectangular | 3.1 | 2.99 | 27 |
| | 14 | PR-14 | 105 | 38 | rectangular | 3.1 | 3.12 | 26 |
| | 15 | PR-15 | 105 | 38 | rectangular | 3.2 | 2.95 | 29 |
| | 16 | PR-16 | 110 | 40 | rectangular | 3.3 | 2.71 | 34 |
| | 17 | PR-17 | 95 | 34 | rectangular | 2.8 | 2.23 | 37 |
| | 18 | PR-18 | 115 | 66 | rectangular | 2.6 | 2.39 | 31 |
| | 19 | PR-19 | 95 | 43 | rectangular | 3.4 | 2.8 | 37 |
| | 20 | PR-20 | 95 | 35 | rectangular | 2.6 | 2.39 | 28 |
| | 21 | PR-21 | 95 | 36 | rectangular | 2.6 | 2.45 | 29 |
| | 22 | PR-22 | 95 | 37 | rectangular | 2.8 | 2.5 | 30 |
| | 23 | PR-23 | 95 | 35 | rectangular | 2.0 | 1.91 | 38 |
| | 24 | PR-24 | 95 | 40 | rectangular | 2.3 | 1.88 | 42 |
| | 25 | PR-25 | 95 | 43 | rectangular | 2.3 | 2.08 | 45 |
| | 26 | PR-26 | 90 | 35 | rectangular | 3.5 | 3.3 | 25 |
| | 27 | PR-27 | 90 | 38 | rectangular | 3.6 | 2.97 | 42 |
| | 28 | PR-28 | 100 | 42 | rectangular | 2.2 | 1.89 | 41 |
| | 29 | PR-29 | 100 | 43 | rectangular | 2.3 | 2.11 | 43 |
| | 30 | PR-30 | 100 | 45 | rectangular | 2.4 | 1.95 | 37 |

TABLE 13

| | | | PEB temp. | Eop | | LWR | | Collapse margin |
|---|---|---|---|---|---|---|---|---|
| | | Resist | (° C.) | (mJ/cm²) | Profile | (nm) | MEF | (%) |
| Example | 31 | PR-31 | 100 | 37 | rectangular | 2.3 | 1.82 | 38 |
| | 32 | PR-32 | 100 | 36 | rectangular | 2.3 | 2.26 | 36 |
| | 33 | PR-33 | 100 | 37 | rectangular | 2.8 | 2.73 | 31 |
| | 34 | PR-34 | 95 | 33 | rectangular | 2.6 | 2.71 | 33 |
| | 35 | PR-35 | 95 | 26 | rectangular | 2.4 | 1.99 | 38 |
| | 36 | PR-36 | 95 | 28 | rectangular | 2.4 | 1.78 | 38 |
| | 37 | PR-37 | 105 | 40 | rectangular | 3.4 | 3.32 | 33 |
| | 38 | PR-38 | 100 | 36 | rectangular | 2.9 | 2.67 | 30 |
| | 39 | PR-39 | 95 | 34 | rectangular | 2.3 | 2.78 | 22 |
| | 40 | PR-40 | 95 | 36 | rectangular | 2.7 | 2.7 | 25 |
| | 41 | PR-41 | 95 | 33 | rectangular | 2.5 | 2.59 | 27 |
| | 42 | PR-42 | 95 | 34 | rectangular | 2.3 | 2.4 | 23 |
| | 43 | PR-43 | 95 | 35 | rectangular | 3.5 | 3.15 | 30 |
| | 44 | PR-44 | 95 | 36 | rectangular | 3.4 | 3.03 | 31 |
| | 45 | PR-45 | 95 | 44 | rectangular | 2.7 | 2.6 | 25 |

TABLE 14

| | | | PEB temp. | Eop | | LWR | | Collapse margin |
|---|---|---|---|---|---|---|---|---|
| | | Resist | (° C.) | (mJ/cm²) | Profile | (nm) | MEF | (%) |
| Comparative | 1 | PR-46 | 95 | 33 | rounded top | 4.3 | 4.1 | 11 |
| Example | 2 | PR-47 | 105 | pattern collapsed | | | | 0 |
| | 3 | PR-48 | 100 | 32 | tapered | 4.8 | 3.66 | 13 |

| | | | | |
|---|---|---|---|---|
| 4 | PR-49 | 100 | pattern collapsed | 0 |

As seen from Tables 12, 13 and 14, positive resist compositions comprising (A) a polymer comprising recurring units (a1) containing an acid labile group, recurring units (a2) having a cyclic hydrocarbon group containing an ester, ether, carbonate or sulfonate radical within the ring, and recurring units (a3) having an oxirane ring, the polymer being adapted to increase alkaline dissolution under the action of an acid, (B) a photoacid generator, and (C) a solvent according to the invention (Examples 1 to 45) display favorable results with respect to all line pattern profile, LWR, MEF, and collapse margin.

While the invention has been illustrated and described in typical embodiments, it is not intended to be limited to the details shown. Any modified embodiments having substantially the same features and achieving substantially the same results as the technical idea disclosed herein are within the spirit and scope of the invention.

Japanese Patent Application No. 2011-233564 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A positive resist composition comprising
(A) a polymer comprising recurring units (a1) containing an acid labile group, recurring units (a2) having a cyclic hydrocarbon group containing at least one of ester, ether, carbonate, and sulfonate radicals within the ring, and recurring units (a3) having an oxirane ring, the polymer being adapted to increase alkaline dissolution under the action of an acid,
(B) a photoacid generator, and
(C) a solvent.

2. The resist composition of claim 1 wherein the recurring unit (a1) has the general formula (1): 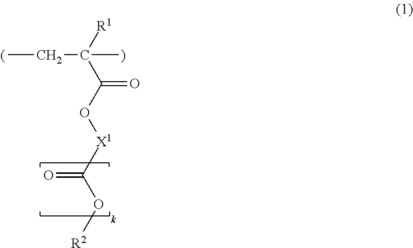
wherein R¹ is hydrogen or methyl, R² is an acid labile group, k is 0 or 1, X¹ is a single bond when k is 0, and X¹ is a divalent, straight, branched or cyclic C₁-C₁₅ hydrocarbon group which may contain a heteroatom when k is 1.

3. The resist composition of claim 1 wherein the recurring unit (a2) has a lactone ring.

4. The resist composition of claim 1 wherein the recurring unit (a3) has the general formula (2) or (3): 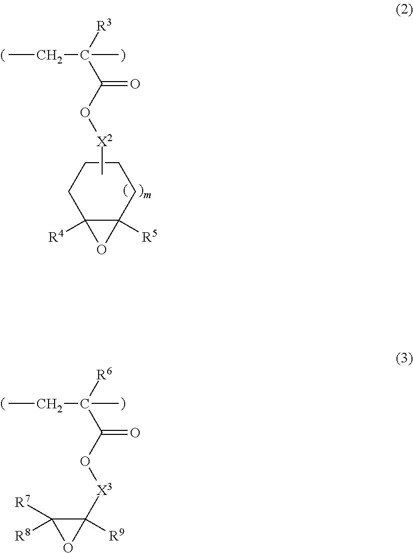
wherein R³ and R⁶ each are hydrogen or methyl, X² and X³ each are a single bond or a divalent hydrocarbon group which may contain an ester or ether bond, R⁴, R⁵, R⁷ to R⁹ each are hydrogen or a straight or branched C₁-C₅ alkyl group, and m is 0 or 1.

5. The resist composition of claim 1 wherein the polymer (A) further comprises recurring units (a4) having the general formula (10): 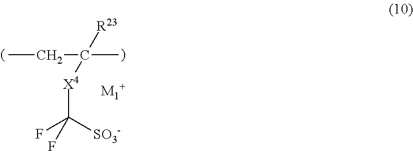
wherein R²³ is hydrogen or methyl, X⁴ is a straight or branched C₁-C₂₀ alkylene group, —O—R²⁴—, or —C(═O)—X⁵—R²⁴—, the hydrogen atom bonded to a carbon atom in the alkylene group being optionally substituted by fluorine, X⁵ is oxygen or NH, R²⁴ is a straight, branched or cyclic C₁-C₂₅ alkylene group which may contain a carbonyl, ester or ether radical and in which a carbon-bonded hydrogen atom may be substituted by fluorine, and M₁⁺ is a sulfonium or iodonium cation having a substituent group.

6. The resist composition of claim 1 wherein the polymer (A) further comprises recurring units having a hydroxyl, carboxyl, fluoroalkyl or α-trifluoromethyl alcohol group.

7. The resist composition of claim 1 wherein the photoacid generator (B) is a compound capable of generating an α-position fluorinated sulfonic acid having the general formula (4) upon light exposure, 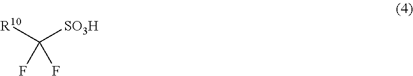
wherein R¹⁰ is a monovalent, straight, branched or cyclic C₁-C₃₅ hydrocarbon group which may contain a heteroatom and in which at least one carbon-bonded hydrogen atom may be substituted by fluorine.

8. The resist composition of claim 7 wherein the photoacid generator (B) is a sulfonium salt having the general formula (5): 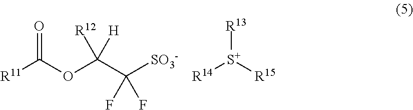
wherein R¹¹ is a substituted or unsubstituted, straight, branched or cyclic C₁-C₃₀ alkyl group which may contain a heteroatom, or a substituted or unsubstituted C₆-C₃₀ aryl group, R¹² is hydrogen or trifluoromethyl, R¹³, R¹⁴, and R¹⁵ are each independently a substituted or unsubstituted, straight or branched C₁-C₁₀ alkyl, alkenyl or oxoalkyl group, or a substituted or unsubstituted C₆-C₁₈ aryl, aralkyl or aryloxoalkyl group, or at least two of R¹³, R¹⁴, and R¹⁵ may bond together to form a ring with the sulfur atom.

9. The resist composition of claim 1, further comprising (D) an onium salt of sulfonic acid or carboxylic acid having the general formula (6) or (7):
R¹⁶—SO₃⁻M₂⁺ (6)
R¹⁷—COO⁻M₂⁺ (7)
wherein R¹⁶ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of sulfonic acid,
R¹⁷ is a monovalent, straight, branched or cyclic C₁-C₃₅ hydrocarbon group which may contain an oxygen atom and in which at least one carbon-bonded hydrogen atom may be substituted by fluorine, with the proviso that no fluorine is bonded to the carbon atom at α-position of carboxylic acid, and
M₂⁺ is a counter cation having a substituent group, which is a sulfonium, iodonium or ammonium cation.

10. The resist composition of claim 9 wherein component (D) has the general formula (8) or (9): 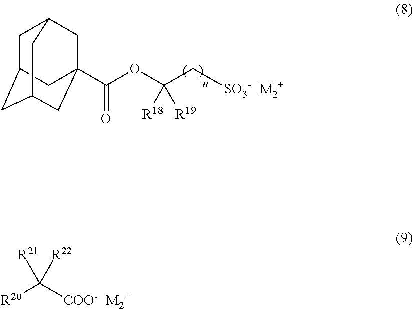
wherein R¹⁸, R¹⁹, R²¹, and R²² each are hydrogen or trifluoromethyl, R²⁰ is hydrogen, hydroxyl, a substituted or unsubstituted, straight, branched or cyclic C₁-C₂₀ alkyl group, or a substituted or unsubstituted C₆-C₃₀ aryl group, n is an integer of 1 to 3, and M₂⁺ is a counter cation having a substituent group, which is a sulfonium, iodonium or ammonium cation.

11. The resist composition of claim 9 wherein component (D) is present in an amount of 0.5 to 15 parts by weight per 100 parts by weight of component (A).

12. The resist composition of claim 1 wherein component (B) is present in an amount of 3 to 25 parts by weight per 100 parts by weight of component (A).

13. The resist composition of claim 1, further comprising a basic compound.

14. The resist composition of claim 13 wherein the basic compound is present in an amount of 0.1 to 3 parts by weight per 100 parts by weight of component (A).

15. A pattern forming process comprising the steps of coating the positive resist composition of claim 1 onto a substrate, baking, exposing the resulting resist film to high-energy radiation, and developing in a developer.

16. The process of claim 15 wherein the high-energy radiation has a wavelength in the range of 180 to 250 nm.

17. The process of claim 16 wherein the exposing step includes exposing the resist film to radiation via water according to the immersion lithography.
